(19) United States
(12) Patent Application Publication
(10) Pub. No.: US 2015/0171066 A1
(43) Pub. Date: Jun. 18, 2015

(54) SEMICONDUCTOR DEVICE

(71) Applicant: Renesas Electronics Corporation, Kawasaki-shi (JP)

(72) Inventors: Shintaro YAMAMICHI, Kanagawa (JP); Atsushi NAKAMURA, Kanagawa (JP); Masayuki ITO, Kanagawa (JP); Naoto TAOKA, Kanagawa (JP); Kentaro MORI, Kanagawa (JP)

(73) Assignee: Renesas Electronics Corporation

(21) Appl. No.: 14/574,662

(22) Filed: Dec. 18, 2014

(30) Foreign Application Priority Data
Dec. 18, 2013 (JP) 2013-261419

(51) Int. Cl. H01L 25/18; H01L 27/02; H01L 23/31; H01L 23/34; H01L 29/49; H01L 29/51

(52) U.S. Cl. CPC H01L 25/18; H01L 29/4916; H01L 29/517; H01L 23/3142; H01L 23/34; H01L 27/0207

(57) ABSTRACT

This invention is to improve performance of a semiconductor integrated circuit device. A semiconductor device has a peripheral circuit chip and a logic chip mounted over a wiring substrate. The wiring substrate and the peripheral circuit chip are electrically connected, and the peripheral circuit chip and the logic chip are electrically connected. The peripheral circuit chip includes a first peripheral circuit, a power supply controller, a temperature sensor and a first RAM. The logic chip includes a CPU, a second peripheral circuit and a second RAM. The first peripheral circuit and the first RAM are manufactured based on a first process rule. The CPU, the second peripheral circuit and the second RAM are manufactured based on a second process rule finer than the first process rule.

### CROSS-REFERENCE TO RELATED APPLICATIONS

The disclosure of Japanese Patent Application No. 2013-261419 filed on Dec. 18, 2013 including the specification, drawings and abstract is incorporated herein by reference in its entirety.

### BACKGROUND

The present invention relates to a technology of a semiconductor device, and particularly to a technology effective if applied to a semiconductor device mounted with a semiconductor chip within a package.

There has been described in a Japanese Unexamined Patent Application Publication No. 2007-227537 (Patent Document 1), a technology which separates a memory unit and a controller unit formed in different processes from each other and forms them in separate chips, and integrates them into one semiconductor device by a multi chip package (MCP) technology of a laminated structure.

Further, there has been described in a Japanese Unexamined Patent Application Publication No. 2010-62328 (Patent Document 2), a semiconductor device called CoC (Chip on Chip) with semiconductor chips laminated three-dimensionally or a stack type MCP or the like. In the Patent Document 2, a second semiconductor chip smaller than a first semiconductor chip fixed to a die pad or a film-like substrate in plan view is electrically connected with the first semiconductor chip in a state in which they are arranged opposite to each other. Also, in the Patent Document 2, signal terminal parts for performing the transfer of signals between the second semiconductor chip and the outside of the semiconductor device are formed over the first semiconductor chip placed in the side position of the second semiconductor chip.

### RELATED ART DOCUMENTS

### Patent Document

[Patent Document 1] Japanese Unexamined Patent Application Publication No. 2007-227537

[Patent Document 2] Japanese Unexamined Patent Application Publication No. 2010-62328

### SUMMARY

A problem arises in that current leaks through a location or path insulated and where it should not be made to originally flow on each electronic circuit (also hereinafter simply called “circuit”) of a semiconductor device, i.e., a leak current is generated. This leak current increases with a rise in ambient temperature (environmental temperature) at the time of the operation of the semiconductor device. Further, when the leak current occurs (increases), the amount of heat generated by a semiconductor chip itself increases. Then, the temperature of the semiconductor device continues to rise, thus causing a risk of the semiconductor device being not operated normally.

The inventors of the present application have predicted that with micronization of a process rule at the time of manufacture of the semiconductor device from 90 nm to 65 nm, 40 nm and 28 nm, for example, the above leak current more increases, and further the temperature of the semiconductor device continues to more increase.

Further, according to the examinations of the inventors of the present application, the inventors have found that the factors that cause the above problems reside even in the following points.

One semiconductor chip having a central processing unit (CPU) is formed, inclusive of the above CPU, with a plurality of circuits such as a local RAM controller, a memory such as a RAM and a flash memory or the like, a CAN module, an external interface circuit, and power supply controller, etc.

Further, in order to realize high integration, speed-up or low power consumption or the like of the semiconductor device, at least the CPU of the above circuits is required to be manufactured based on a relatively fine (small) process rule, i.e., a high-end process (advanced process). However, of those other than the CPU in the above circuits, there also exist the circuits that can be manufactured based on a process rule not finer (rougher) than a process rule in a high-end process, i.e., by a low-end process (legacy process).

It is however difficult to manufacture one semiconductor chip by a plurality of manufacturing processes different in process rule from each other.

It is therefore considered that the circuits other than the CPU in the above circuits and capable of being manufactured by the so-called low-end process are manufactured based on the same process rule as the process rule at the time of manufacture of the CPU, i.e., the high-end process.

However, as described above, the inventors of the present application have found that manufacturing all circuits included in the semiconductor chip by the high-end process as a measure taken against the manufacture of the circuits by the plural manufacturing processes different from each other being difficult is one factor that causes the above problem of the leak current.

Other objects and novel features will become apparent from the description of the present specification and the accompanying drawings.

A semiconductor device according to one embodiment has a first semiconductor chip and a second semiconductor chip mounted over a base material. The base material and the first semiconductor chip are electrically connected by first conductive members. The first semiconductor chip and the second semiconductor chip are electrically connected by second conductive members. The first semiconductor chip includes a first peripheral circuit, a power supply controller, a temperature sensor and a first RAM. The second semiconductor chip includes a CPU, a second peripheral circuit and a second RAM. The first peripheral circuit and the first RAM are respectively manufactured based on a first process rule. The CPU, the second peripheral circuit and the second RAM are respectively manufactured based on a second process rule finer than the first process rule.

Further, a semiconductor device according to another embodiment has a first semiconductor chip and a second semiconductor chip mounted over a base material. The base material and the first semiconductor chip are electrically connected by first conductive members. The first semiconductor chip and the second semiconductor chip are electrically connected by second conductive members. The first semiconductor chip includes a first peripheral circuit, a power supply controller, a temperature sensor and a first RAM. The second semiconductor chip includes a CPU, a second peripheral circuit and a second RAM. A first minimum wiring space in a wiring layer of the first semiconductor chip is larger than a second minimum wiring space in a wring layer of the second semiconductor chip.

According to one embodiment, it is possible to realize high integration, speed up or low power consumption of a semiconductor device.

### BRIEF DESCRIPTION OF THE DRAWINGS

FIG. 1 is a perspective diagram of a semiconductor device of an embodiment 1;

FIG. 2 is a bottom diagram of the semiconductor device of the embodiment 1;

FIG. 3 is a perspective plan diagram of the semiconductor device of the embodiment 1;

FIG. 4 is a sectional diagram of the semiconductor device of the embodiment 1;

FIG. 5 is a block diagram illustrating a circuit configuration example of the semiconductor device of the embodiment 1;

FIG. 6 is a perspective diagram typically showing a circuit arrangement in the semiconductor device of the embodiment 1;

FIG. 7 is a perspective plan diagram of a system equipped with the semiconductor device of the embodiment 1 and a memory device;

FIG. 8 is a sectional diagram of the system equipped with the semiconductor device of the embodiment 1 and the memory device;

FIG. 9 is a sectional diagram showing an example of a structure of a wiring layer in a peripheral circuit chip of the semiconductor device of the embodiment 1;

FIG. 10 is a sectional diagram illustrating an example of a structure of a wiring layer in a logic chip of the semiconductor device of the embodiment 1;

FIG. 11 is a sectional diagram depicting an example of a structure of a MISFET in the peripheral circuit chip of the semiconductor device of the embodiment 1;

FIG. 12 is a sectional diagram showing an example of a structure of a MISFET in the logic chip of the semiconductor device of the embodiment 1;

FIG. 13 is a graph showing a result obtained by simulating a relation between the operating time and temperature of a semiconductor chip in a comparative example;

FIG. 14 is a graph illustrating a relation between the operating time and temperature of the semiconductor chip where power shutdown accompanying a temperature rise of the semiconductor chip is performed in the comparative example;

FIG. 15 is a manufacturing process flow diagram showing a part of a manufacturing process of the semiconductor device of the embodiment 1;

FIG. 16 is a plan diagram showing a manufacturing step of the semiconductor device of the embodiment 1;

FIG. 17 is a sectional diagram showing a manufacturing step of the semiconductor device of the embodiment 1;

FIG. 18 is a plan diagram showing a manufacturing step of the semiconductor device of the embodiment 1;

FIG. 19 is a sectional diagram showing a manufacturing step of the semiconductor device of the embodiment 1;

FIG. 20 is a plan diagram showing a manufacturing step of the semiconductor device of the embodiment 1;

FIG. 21 is a sectional diagram showing a manufacturing step of the semiconductor device of the embodiment 1;

FIG. 22 is a sectional diagram showing a manufacturing step of the semiconductor device of the embodiment 1;

FIG. 23 is a sectional diagram showing a manufacturing step of the semiconductor device of the embodiment 1;

FIG. 24 is a sectional diagram showing a manufacturing step of the semiconductor device of the embodiment 1;

FIG. 25 is a sectional diagram showing a manufacturing step of the semiconductor device of the embodiment 1;

FIG. 26 is a sectional diagram showing a manufacturing step of the semiconductor device of the embodiment 1;

FIG. 27 is a sectional diagram showing a manufacturing step of the semiconductor device of the embodiment 1;

FIG. 28 is a sectional diagram showing a manufacturing step of the semiconductor device of the embodiment 1;

FIG. 29 is a plan diagram of a semiconductor device of an embodiment 2;

FIG. 30 is a sectional diagram of the semiconductor device of the embodiment 2;

FIG. 31 is a plan diagram of a semiconductor device of an embodiment 3;

FIG. 32 is a sectional diagram of the semiconductor device of the embodiment 3;

FIG. 33 is a plan diagram of a semiconductor device of an embodiment 4;

FIG. 34 is a sectional diagram of the semiconductor device of the embodiment 4;

FIG. 35 is a sectional diagram showing a structure of another example of the semiconductor device of the embodiment 4;

FIG. 36 is a perspective plan diagram of a semiconductor device of a modification 2;

FIG. 37 is a sectional diagram of the semiconductor device of the modification 2; and

FIG. 38 is a perspective plan diagram of a semiconductor device of a modification 3.

### DETAILED DESCRIPTION

### Description of Description Form, Basic Terms and Usage in the Present Application

In the present application, if necessary for the sake of convenience, each of the following embodiments will be described by being divided into a plurality of sections, etc. However, unless shown particularly explicitly, they are by no means independently separate from each other. Regardless of before and after the description, each part of a single example, one of which is a partial detail of the other or a modification or the like of some or all of the other. Further, as a general rule, a repeated description of like parts will be omitted. Respective components in the embodiments are not essential unless shown particularly explicitly, except for the case where the number of the components is limited theoretically and unless otherwise apparent from the context.

Similarly, when a material, composition or the like is taken up in the description of each embodiment or the like, the expression of “X comprising A” or the like does not exclude one including a component other than A unless shown particularly explicitly and unless exclusion of another component is obvious from the context. For example, if the expression concerns a component, it means “X including A as a main component”, etc. It is needless to say that for example, a “silicon member” or the like is not limited to pure silicon, but also includes a member made of a multi-component alloy which contains SiGe alloy or another type of silicon as a main component and other additives or the like. Further, gold plating, a Cu layer, nickel plating, etc. include not only a pure member but also members including gold, Cu, nickel, etc. as main components respectively unless otherwise stated, particularly except as expressly stated.

Further, even when reference is made to a specific numerical value or quantity, it may be a numerical value exceeding the specific numerical value or a numerical value less than the specific numerical value unless shown particularly explicitly and theoretically limited to the specific numerical value, and unless otherwise expressly stated from the context.

In the respective drawings of the embodiments, the same or like parts are denoted by the same or like symbols or reference numerals, and their description will not repeated in principle.

Further, in the accompanying drawings, rather, when they become complex or distinction with voids is clear, there is a case where hatching or the like may be omitted even in sectional diagrams. In connection with this, if apparent from the description or the like, for example, the outline of the background may be omitted even in the case of a hole closed in a plane. Furthermore, even without a cross-section, hatching or dot patterns may be applied to clearly show non-voids or to clearly indicate the boundary of the region.

Further, in the following embodiments, when the range is indicated as A to B, it is taken to be indicative of A or greater and B or less except as otherwise expressly stated.

In the embodiments to be described below, as an example of a SiP (System in Package) type semiconductor device, a semiconductor package equipped within a package with one semiconductor chip being divided into a plurality of semiconductor chips will be taken up and described.

### Embodiment 1

<Semiconductor Device>

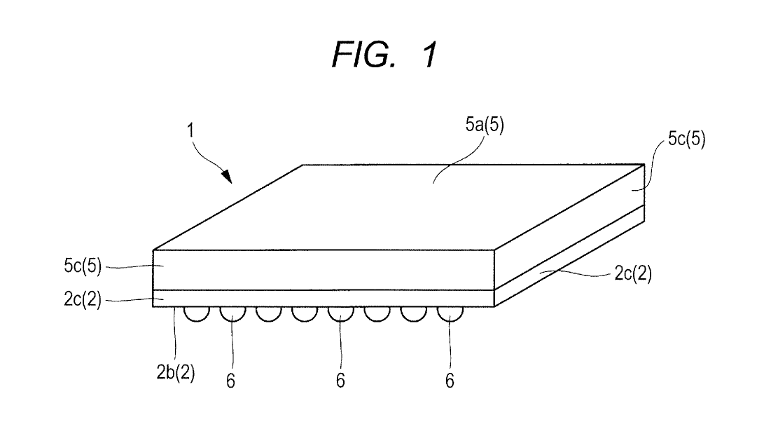

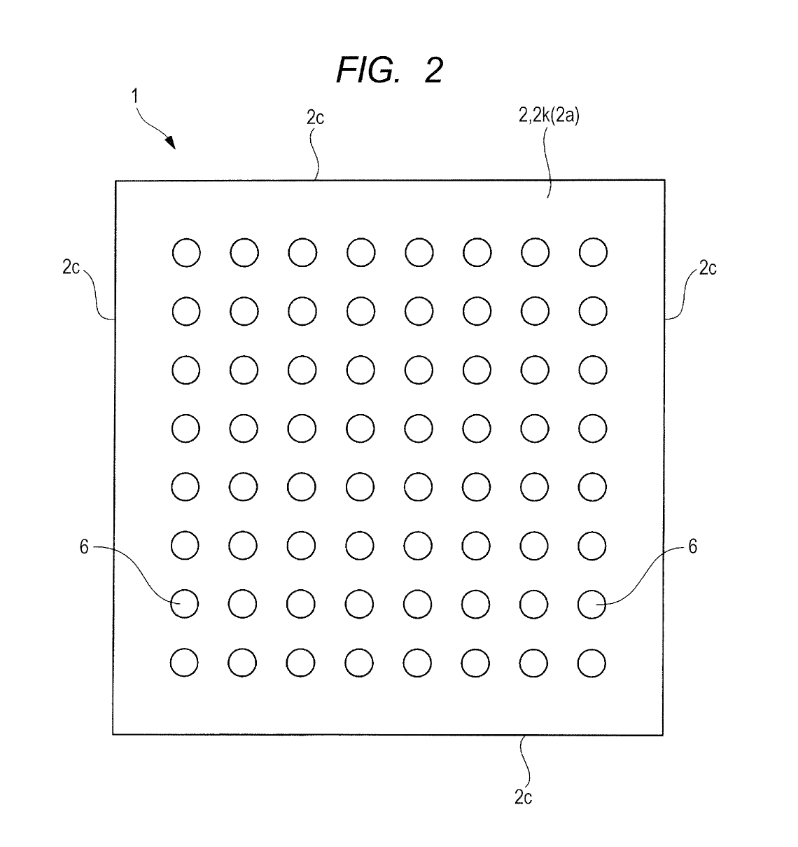

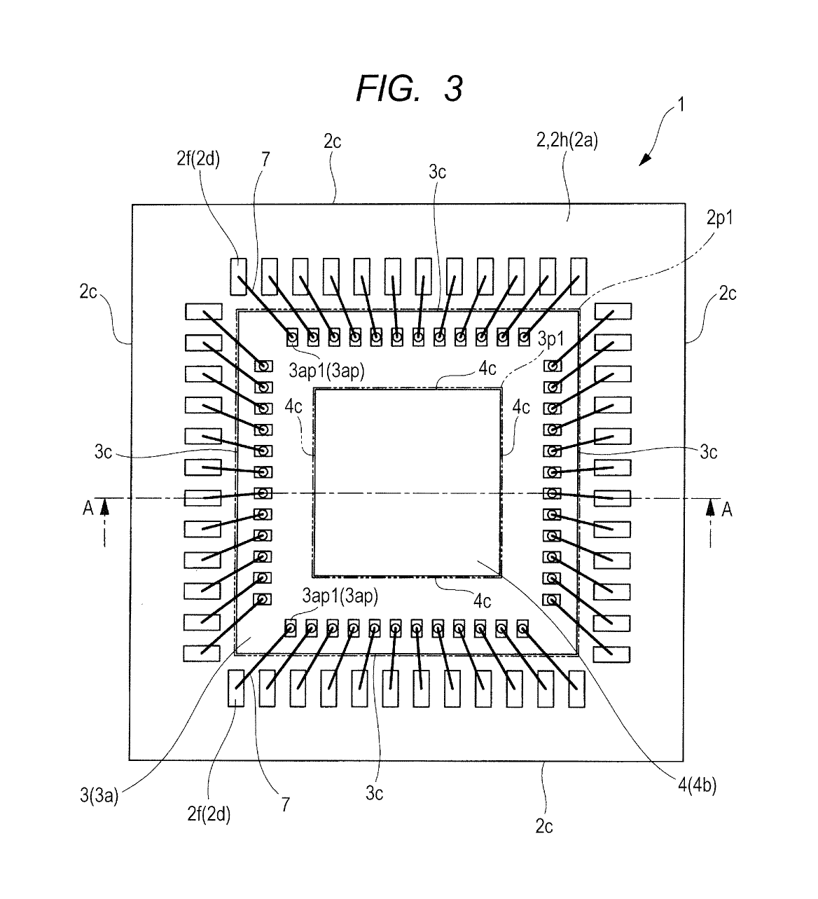

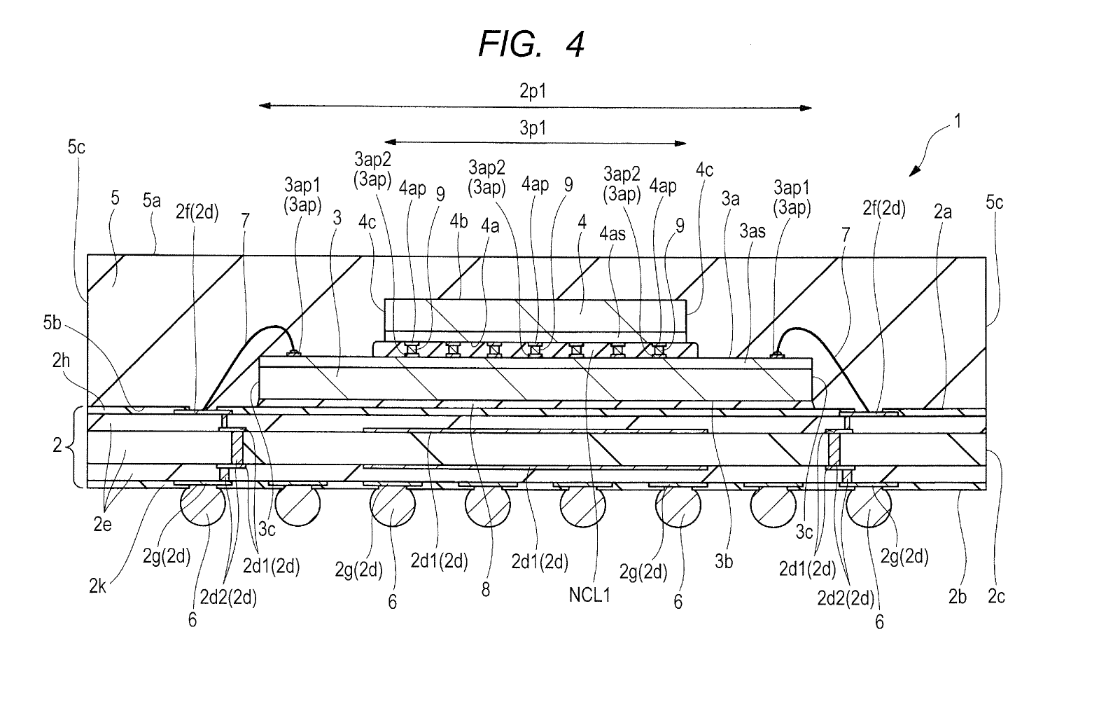

An outline structure of a semiconductor device (semiconductor package) 1 of the present embodiment 1 will first be described using FIGS. 1 to 4. FIG. 1 is a perspective diagram of the semiconductor device of the embodiment 1. FIG. 2 is a bottom diagram of the semiconductor device of the embodiment 1. FIG. 3 is a perspective plan diagram of the semiconductor device of the embodiment 1. FIG. 3 shows an internal structure of the semiconductor device over a wiring substrate in a removed state of a sealing body. FIG. 4 is a sectional diagram of the semiconductor device of the embodiment 1. FIG. 4 is a sectional diagram taken along line A-A of FIG. 3. Incidentally, while terminals are shown in FIGS. 1 to 4 with being reduced in number to make it easier to see them, the number of the terminals (bonding leads 2f, lands 2g, solder balls 6 and surface electrodes 3ap and 4ap, etc.) is not limited to the forms shown in FIGS. 1 to 4.

The semiconductor device (semiconductor package) 1 of the present embodiment 1 is provided with a wiring substrate (base material) 2, a peripheral circuit chip (semiconductor chip) 3 and a logic chip (semiconductor chip) 4 both mounted over the wiring substrate 2, and a sealing body (sealing member, resin) 5 that seals the peripheral circuit chip 3 and the logic chip 4.

As shown in FIG. 4, the wiring substrate (base material) 2 has an upper surface (surface, main surface, chip mounting surface) 2a with the peripheral circuit chip 3 mounted thereover, a lower surface (surface, main surface, mounting surface) 2b opposite to the upper surface 2a, and a side surface 2c arranged between the upper surface 2a and the lower surface 2b. As shown in FIGS. 2 and 3, the wiring substrate 2 has an outer shape square in plan view. In the example shown in FIGS. 2 and 3, as the plane size (dimensions in plan view, dimensions of the upper surface 2a and the lower surface 2b, outline size) of the wiring substrate 2, for example, the length of one side is about 14 mm. The wiring substrate 2 has a square shape in plan view. Further, the thickness (height) of the wiring board 2, i.e., the distance from the upper surface 2a to the lower surface 2b shown in FIG. 4 is for example, about 0.3 mm to 0.5 mm.

Incidentally, in the specification of the present application, the term “in plan view” means that the wiring substrate 2 is seen through from the direction normal to the upper surface 2a of the wiring board 2 or its lower surface 2b, the surface 3a of the peripheral circuit chip 3 or its back surface 3b, or the surface 4a of the logic chip 4 or its back surface 4b.

The wiring substrate 2 is an interposer for electrically connecting the peripheral circuit chip 3 and the logic chip 4 mounted on the upper surface 2a side and an unillustrated mounting substrate with each other, and has a plurality of wiring layers (four layers in the example shown in FIG. 4) that electrically connect the upper surface 2a side and the lower surface 2b side with each other. Each wiring layer includes a plurality of wirings 2d and insulating layers 2e that insulate between the wirings 2d and between the adjacent wiring layers respectively. Here, the wiring substrate 2 of the present embodiment 1 has the three insulating layers 2e of which the central insulating layer 2e is a core layer (core material). A so-called coreless substrate having no insulating layer 2e serving as a core may however be used. Further, the wirings 2d include wirings 2d1 formed over the upper or lower surface of the insulating layer 2e, and via wirings 2d2 that serve as interlayer conductive paths, which are formed so as to penetrate the insulating layers 2e in the thickness direction thereof.

Further, a plurality of bonding leads (terminals, chip mounting surface side terminals, electrodes) 2f that serve as terminals electrically connected with the peripheral circuit chip 3 are formed in the upper surface 2a of the wiring substrate 2. The bonding leads 2f are respectively terminals electrically connected via wires 7 with surface electrodes (terminals, electrode pads, bonding pads) 3ap formed over the surface 3a of the peripheral circuit chip 3. On the other hand, a plurality of the lands 2g are formed in the lower surface 2b of the wiring substrate 2. A plurality of the solder balls 6 that serve as terminals for electrically connecting with the unillustrated mounting substrate, i.e., external connecting terminals of the semiconductor device 1 are bonded to the lands 2g respectively. The bonding leads 2f and the lands 2g are respectively electrically connected with each other through the wirings 2d. Incidentally, since the wirings 2d connected with the bonding leads 2f and the lands 2g are formed integrally with the bonding leads 2f and the lands 2g, the bonding leads 2f and the lands 2g are shown as a part of the wirings 2d in FIG. 4.

The upper surface 2a of the wiring substrate 2 is covered with an insulating film (solder resist film) 2h inclusive of the bonding leads 2f. Openings are formed in the insulating film 2h. At least some (parts bonded to the peripheral circuit chip 3, bonding regions) of the bonding leads 2f are exposed from the insulating film 2h at the openings. Further, the lower surface 2b of the wiring substrate 2 is covered with an insulting film (solder resist film) 2k inclusive of the lands 2g. Openings are formed in the insulating film 2k. At least some (parts bonded to the solder balls 6) of the lands 2g are exposed from the insulating film 2k at the openings.

Further, the solder balls (external terminals, electrodes, external electrodes) 6 respectively bonded to the lands 2g at the lower surface 2b of the wiring substrate 2 as shown in FIG. 4 are arranged in a matrix state (array form, matrix form) as shown in FIG. 2. Although not shown in FIG. 2, the lands 2g (refer to FIG. 4) to which the solder balls 6 are bonded, are also arranged in a matrix state (array form, matrix form). Thus, the semiconductor device in which the external terminals (solder balls 6, lands 2g) are arranged on the mounting surface side of the wiring substrate 2 in a matrix form is called an area array type semiconductor device. The area array type semiconductor device is preferred in that since the mounting surface (lower surface 2b) side of the wiring substrate 2 can be utilized effectively as an arrangement space for the external terminals, an increase in the mounting area of the semiconductor device can be suppressed even if the number of the external terminals increases. That is, the semiconductor device in which the number of the external terminals increases with high functionalization and high integration can be mounted with space-saving.

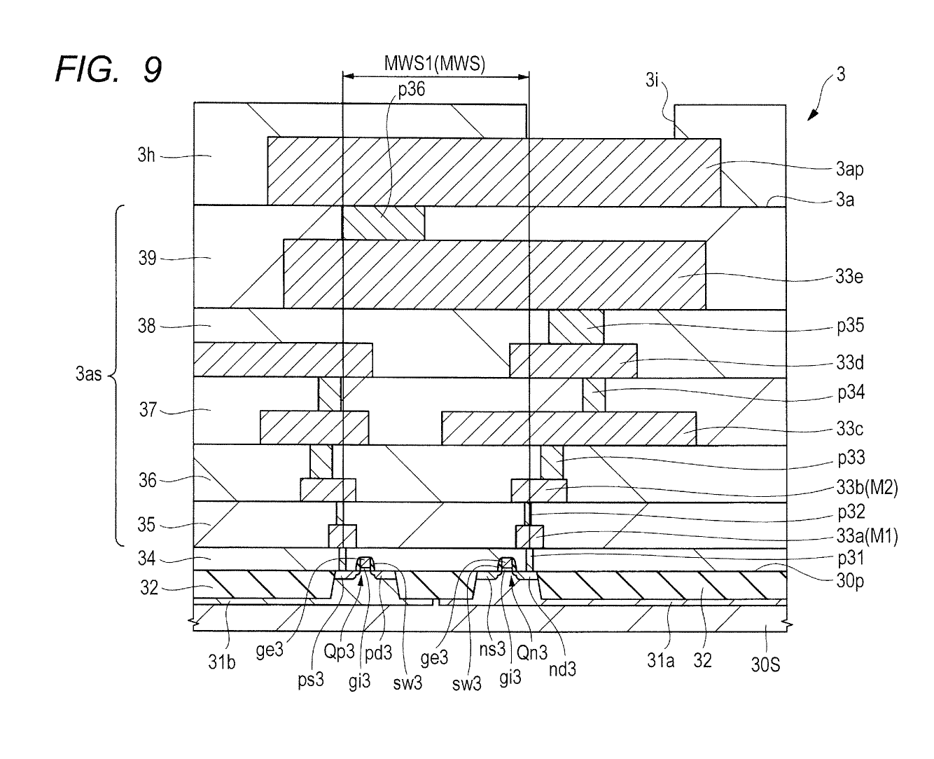

The semiconductor device 1 is equipped with the peripheral circuit chip 3 and the logic chip 4 as a plurality of semiconductor chips mounted over the wiring substrate 2. In the example shown in FIG. 4, the peripheral circuit chip 3 is mounted over the wiring substrate 2, and the logic chip 4 is mounted over the peripheral circuit chip 3. The logic chip 4 is electrically connected with the wiring substrate 2 through the peripheral circuit chip 3. Further, as will be described later using FIGS. 9 through 12, a plurality of semiconductor elements such as MISFETs (Metal insulator semiconductor field effect transistors), etc. are formed in the peripheral circuit chip 3 and the logic chip 4.

The peripheral circuit chip 3 has the surface (main surface, upper surface) 3a, the back surface (main surface, lower surface) 3b opposite to the surface 3a, and side surfaces 3c positioned between the surface 3a and the back surface 3b. The peripheral circuit chip 3 has an outer shape square in plan view as shown in FIG. 3. Further, the peripheral circuit chip 3 has surface electrodes (terminals, electrode pads, bonding pads) 3ap formed over the surface 3a. Incidentally, of the surface electrodes 3ap of the peripheral circuit chip 3, those electrically connected with the bonding leads 2f of the wiring substrate 2 are taken to be surface electrodes (electrode pads for the base material) 3ap1, and those electrically connected with the surface electrodes (terminals, electrode pads, bonding pads) 4ap of the logic chip 4 are taken to be surface electrodes (electrode pads for the chip) 3ap2.

The logic chip 4 has the surface (main surface, upper surface) 4a, the back surface (main surface, lower surface) 4b opposite to the surface 4a, and side surfaces 4c positioned between the surface 4a and the back surface 4b. The logic chip 4 has an outer shape square in plan view as shown in FIG. 3. Further, the logic chip 4 has the surface electrodes (terminals, electrode pads, bonding pads) 4ap formed over the surface 4a.

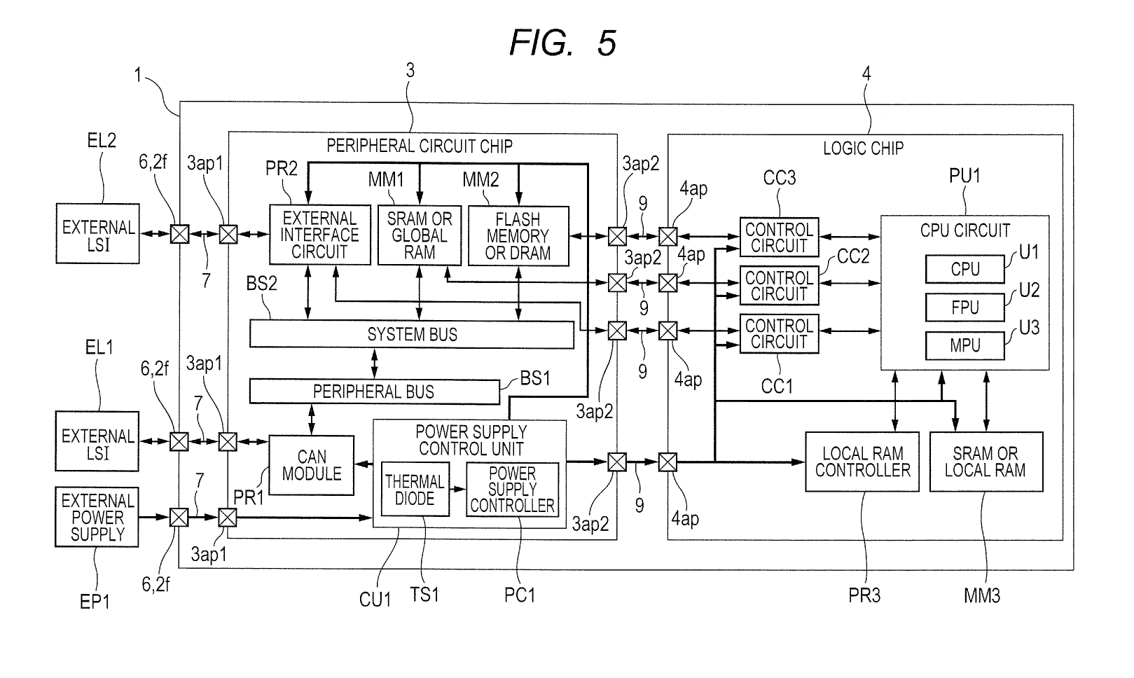

As will be described later using FIG. 5, a peripheral circuit such as a CAN (Controller area network) module PR1, a memory MM1 such as a SRAM (Static random access memory), a power supply controller PC1, and a thermal diode (temperature sensor) TS1 are formed in the peripheral circuit chip (semiconductor chip) 3. That is, the peripheral circuit chip 3 is a semiconductor chip formed with peripheral circuits.

Further, a CPU (Central processing unit) circuit PU1, a peripheral circuit such as a local RAM controller PR3, and a memory MM3 such as a SRAM are formed in the logic chip (semiconductor chip) 4. That is, the logic chip 4 is a semiconductor chip formed with a CPU that is a logic circuit, i.e., a central processing unit as a logic circuit.

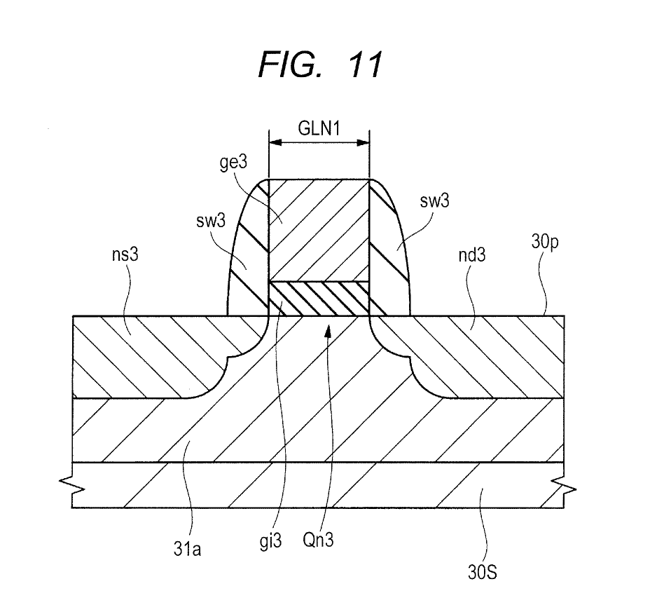

The respective circuits included in the peripheral circuit chip 3 are formed on the surface 3a side of the peripheral circuit chip 3. Described specifically, as will be mentioned later using FIGS. 9 and 11, the peripheral circuit chip 3 is provided with a semiconductor substrate 30S (refer to FIG. 9 to be described later) comprised of silicon (Si), for example. For example, a plurality of semiconductor elements (refer to FIG. 9 to be described later) such as MISFETs are formed over a main surface (element forming surface) 30p (refer to FIG. 9 to be described later) of the semiconductor substrate 30S. A wiring layer 3as in which a plurality of wirings and an insulating film that insulates between the wirings are laminated is formed over the main surface (surface 3a side) of the semiconductor substrate 30S. The wiring layer 3as is shown in FIG. 4. The wirings of the wiring layer 3as are respectively electrically connected with the semiconductor elements to configure each circuit. A plurality of surface electrodes 3ap formed over the surface 3a (refer to FIG. 4) of the peripheral circuit chip 3 are electrically connected with their corresponding semiconductor elements through the wiring layer 3as provided between the semiconductor substrate 30S and the surface 3a to configure a part of each circuit.

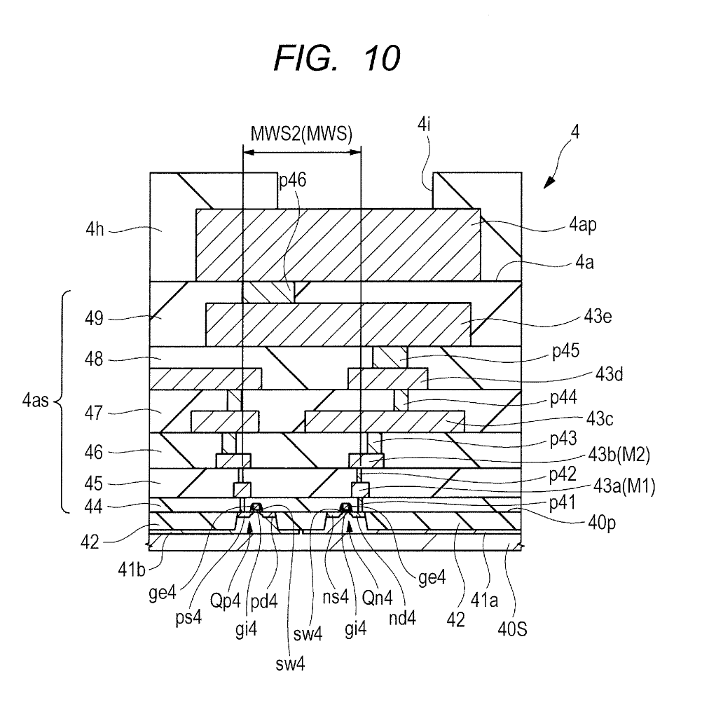

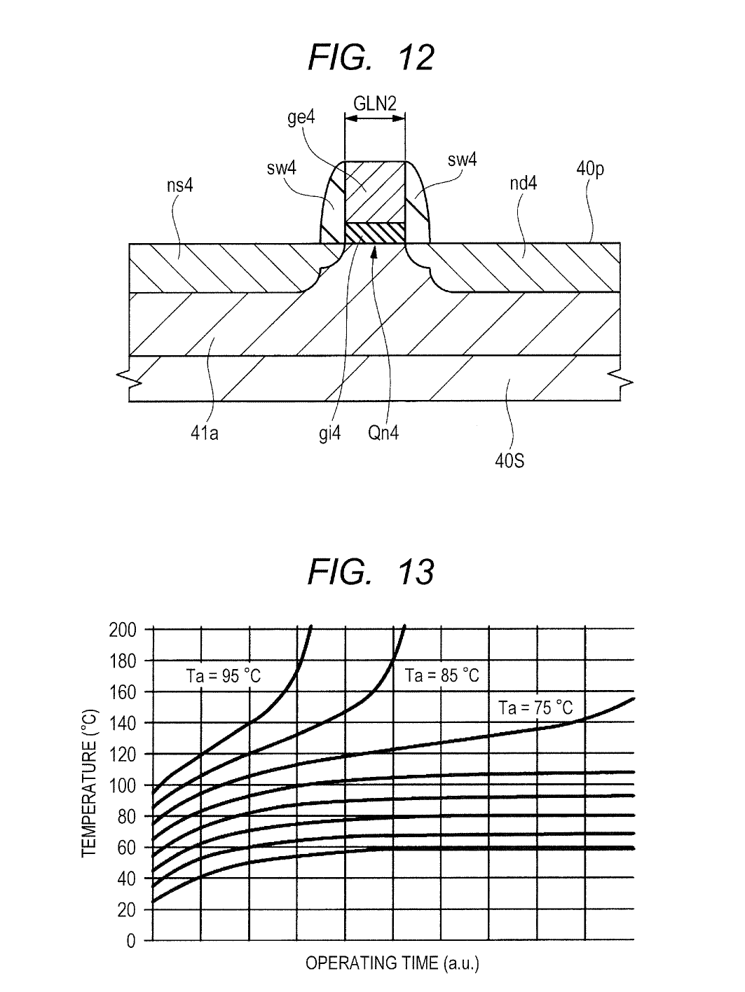

The respective circuits included in the logic chip 4 are formed on the surface 4a side of the logic chip 4. Described specifically, as will be mentioned later using FIGS. 10 and 12, the logic chip 4 is provided with a semiconductor substrate 40S (refer to FIG. 10 to be described later) comprised of silicon (Si), for example. For example, a plurality of semiconductor elements (refer to FIG. 10 to be described later) such as MISFETs are formed over a main surface (element forming surface) 40p (refer to FIG. 10 to be described later) of the semiconductor substrate 40S. A wiring layer 4as in which a plurality of wirings and an insulating film that insulates between the wirings are laminated is formed over the main surface (surface 4a side) of the semiconductor substrate 40S. The wiring layer 4as is shown in FIG. 4. The wirings of the wiring layer 4as are respectively electrically connected with the semiconductor elements to configure each circuit. A plurality of surface electrodes 4ap formed over the surface 4a (refer to FIG. 4) of the logic chip 4 are electrically connected with their corresponding semiconductor elements through the wiring layer 4as provided between the semiconductor substrate 40S and the surface 4a to configure a part of each circuit.

The peripheral circuit chip 3 is mounted over the wiring substrate 2 such that the back surface 3b of the peripheral circuit chip 3 is opposite to the upper surface 2a of the wiring substrate 2. The peripheral circuit chip 3 is mounted over its corresponding chip mounting region (chip mounting part) 2p1 that is a schedule region to mount the peripheral circuit chip 3, of the upper surface 2a of the wiring substrate 2. The peripheral circuit chip 3 and the wiring substrate 2 are connected by the wires (conductive members) 7. Described specifically, the surface electrodes (electrode pads for the base material) 3ap1 of the peripheral circuit chip 3 and the bonding leads 2f of the wiring substrate 2 are electrically connected with each other via the wires 7. Therefore, the back surface 3b of the peripheral circuit chip 3 and the upper surface 2a of the wiring substrate 2 are bonded to each other through a die bond material (adhesive material) 8.

The logic chip 4 is mounted over the peripheral circuit chip 3 such that the surface 4a of the logic chip 4 is opposite to the surface 3a of the peripheral circuit chip 3. The logic chip 4 is mounted over its corresponding chip mounting region (chip mounting part) 3p1 that is a schedule region to mount the logic chip 4, of the surface 3a of the peripheral circuit chip 3. The logic chip 4 and the peripheral circuit chip 3 are flip-chip bonded. Described specifically, the surface electrodes (terminals, electrode pads, bonding pads) 3ap2 of the peripheral circuit chip 3 and the surface electrodes (terminals, electrode pads, bonding pads) 4ap of the logic chip 4 are connected by flip-chip bonding as shown below, for example.

At junction parts between the surface electrodes 4ap of the logic chip 4 and the surface electrodes 3ap2 of the peripheral circuit chip 3, for example, the surface electrodes 4ap thereof and the surface electrodes 3ap2 thereof are respectively electrically connected through projection electrodes (conductive members, columnar electrodes, bumps) 9 being metal members comprised principally of copper (Cu), each of which is formed in a columnar shape (e.g., cylindrical shape). For example, a nickel (Ni) film and a solder (e.g., SnAg) film are laminated over the tips of the projection electrodes 9 formed over the surface electrodes 4ap of the logic chip 4, and the solder films at the tips thereof are bonded to the surface electrodes 3ap2 of the peripheral circuit chip 3, thereby making it possible to electrically connect the surface electrodes 4ap of the logic chip 4 and the surface electrodes 3ap2 of the peripheral circuit chip 3. Various modifications can however be applied as the materials that configure the bonding materials formed at the tips of the projection electrodes 9 within the range that meets a demand for electrical characteristics or a demand for bonding strength.

In the present embodiment 1, one semiconductor chip has been divided into the logic chip 4 formed with the CPU and the peripheral circuit chip 3 formed with the peripheral circuits. Since it is necessary to electrically connect between the CPU and the peripheral circuits by a large number of wirings, the number of the surface electrodes 4ap that electrically connect the logic chip 4 and the peripheral circuit chip 3 is larger than the number of the surface electrodes that electrically connect between the semiconductor chips where the plural semiconductor chips are laminated in the related art. Described specifically, the surface electrodes 4ap can be arranged in plan view in the following manner, for example.

For example, the logic chip 4 is taken to have a square shape of which the length of one side is 1.22 mm. The surface electrodes 4ap arranged in a matrix state (array form, matrix form) in the longitudinal and transverse directions in plan view are taken to be formed over the surface 4a. At this time, in plan view, 48 surface electrodes 4ap are arranged in the longitudinal and transverse directions at intervals of 25.4 μm, thus resulting in the arrangement of 2304 surface electrodes 4ap in matrix form. Alternatively, in plan view, 59 surface electrodes 4ap are arranged in the longitudinal and transverse directions at intervals of 20.6₁1m, thus resulting in the arrangement of 3481 surface electrodes 4ap in matrix form. As a further alternative, in plan view, 84 surface electrodes 4ap are arranged in the longitudinal and transverse directions at intervals of 14.6 μm, thus resulting in the arrangement of 7056 surface electrodes 4ap in matrix form.

As shown in FIG. 4, an adhesive material (sealing member, resin) NCL1 is formed between the logic chip 4 and the peripheral circuit chip 3, i.e., at the junction parts between the surface electrodes 4ap of the logic chip 4 and the surface electrodes 3ap2 of the peripheral circuit chip 3. The adhesive material NCL1 is arranged so as to block space between the surface 4a of the logic chip 4 and the surface 3a of the peripheral circuit chip 3. The adhesive material NCL1 is an adhesive material that bonds and fixes the peripheral circuit chip 3 onto the wiring substrate 2.

As will be described in a manufacturing method of a semiconductor device to be described later, even when the number of the surface electrodes 4ap is large, the adhesive material NCL1 can reliably be arranged between the logic chip 4 and the peripheral circuit chip 3 by a method for applying the adhesive material NCL1 on the surface 3a of the peripheral circuit chip 3 before a process of electrically connecting the peripheral circuit chip 3 and the logic chip 4.

Further, the semiconductor device 1 is provided with a sealing body (sealing member, resin) 5 that seals the peripheral circuit chip 3 and the logic chip 4. In other words, the sealing body 5 seals the peripheral circuit chip 3, the logic chip 4, the wires 7 and the adhesive material NCL1.

The sealing body 5 has an upper surface 5a, a lower surface (surface, back surface) 5b (refer to FIG. 4) located opposite to the upper surface 5a, and side surfaces 5c positioned between the upper surface 5a and the lower surface 5b. The sealing body 5 has an outer shape square in plan view. In the example shown in FIGS. 1 and 4, the plane size (dimensions as seen in plan view from the upper surface 5a side, outer size of the upper surface 5a) of the sealing body 5 is the same as the plane size of the wiring substrate 2. The side surfaces 5c of the sealing body 5 are continuous to the side surfaces 2c of the wiring substrate 2. Further, in the example shown in FIG. 1, as a plane dimension (size in plan view) of the sealing body 5, the length of one side is about 14 mm, for example, and the sealing body 5 has a square shape in plan view.

The sealing body 5 is a resin body that protects the peripheral circuit chip 3 and the logic chip 4. Damage on the thin peripheral circuit chip 3 and logic chip 4 can be suppressed by forming the sealing body 5 while being made in close contact with the peripheral circuit chip 3 and the logic chip 4. Further, in terms of improving a function as a protection member, the sealing body 5 is comprised of the following materials, for example. Since the sealing body 5 requires the easiness for making it in close contact with the wiring substrate 2, the peripheral circuit chip 3 and the logic chip 4, and its certain hardness after their sealing, the sealing body 5 may preferably contain a thermosetting resin such as an epoxy resin, for example. Further, in order to improve the function of the sealing body 5 after curing, for example, filler particles such as silica (silicon dioxide: SiO₂) are preferably mixed in the resin material. For example, in terms of suppressing damage on the peripheral circuit chip 3 and the logic chip 4 due to thermal deformation after the formation of the sealing body 5, it is preferable to cause the linear expansion coefficient of each of the peripheral circuit chip 3 and the logic chip 4 and the linear expansion coefficient of the sealing body 5 to approach each other by adjusting the mixing ratio of the filter particles.

<Circuit Configuration of Semiconductor Device>

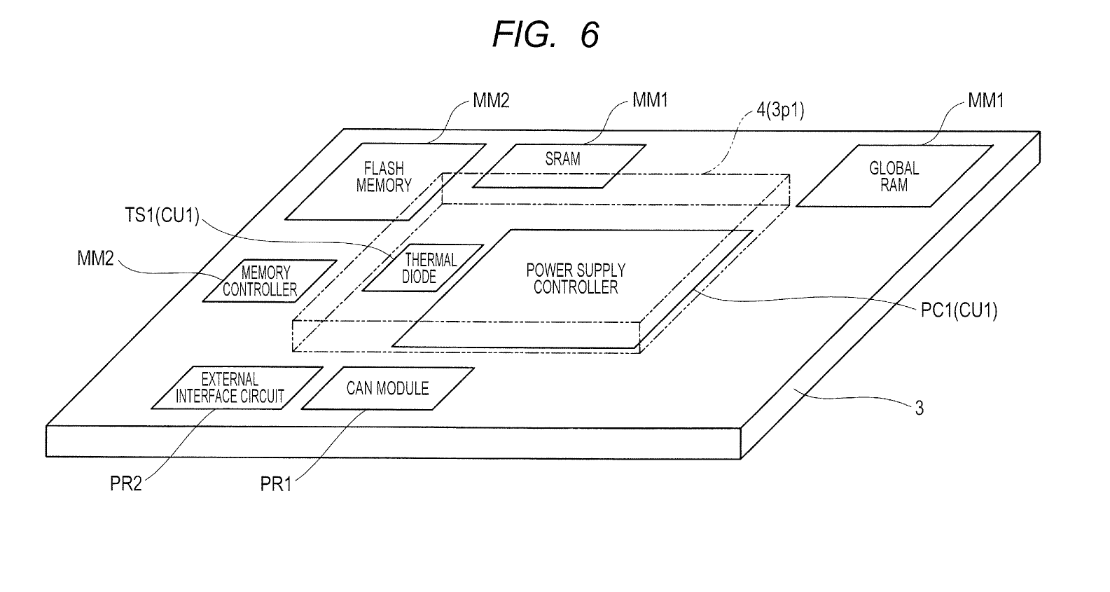

A circuit configuration example of the semiconductor device 1 will next be described using FIGS. 5 and 6. FIG. 5 is a block diagram showing the circuit configuration example of the semiconductor device of the embodiment 1. FIG. 6 is a perspective diagram typically showing a circuit arrangement in the semiconductor device of the embodiment 1. Incidentally, in FIG. 6, a memory controller (not shown in FIG. 5) that controls a memory MM2 is illustrated with a symbol MM2 attached thereto.

As described above, in the present embodiment 1, one semiconductor chip mounted over the wiring substrate 2 is divided into the logic chip 4 formed with the CPU, and the peripheral circuit chip 3 formed with the peripheral circuits.

As shown in FIG. 5, the peripheral circuit chip 3 has a CAN (Controller area network) module (peripheral circuit) PR1, and an external interface circuit (peripheral circuit, interface) PR2. Further, the peripheral circuit chip 3 has a memory (RAM) MM1 comprised of a SRAM (Static random access memory) or a global RAM (Random access memory) or the like, and the memory MM2 comprised of a flash memory or a DRAM (Dynamic random access memory) or the like. Furthermore, the peripheral circuit chip 3 has the power supply controller PC1 and the thermal diode (temperature sensor) TS1. Incidentally, the power supply controller PC1 and the thermal diode TS1 configure a power supply control unit CU1 that controls the supply of a power supply (drive power supply, current, voltage) for driving the semiconductor device.

As shown in FIG. 5, the logic chip 4 has a CPU (Central processing unit) circuit (CPU) PU1, and a local RAM controller (peripheral circuit) PR3. Further, the logic chip 4 has a memory (RAM) MM3 comprised of a SRAM or a local RAM or the like. Furthermore, the logic chip 4 has control circuits CC1, CC2 and CC3.

The CAN module (peripheral circuit) PR1 is connected, inside the peripheral circuit chip 3, with the external interface circuit PR2, the memory MM1 and the memory MM2 through a peripheral bus BS1 and a system bus BS2. Further, the CAN module PR1 is connected with an external LSI (Large scale integrated circuit) EL1 through the surface electrode 3ap1, the wire 7, the bonding lead 2f and the solder ball 6. The CAN module is a module (peripheral circuit) that makes a serial communication with the external LSI. Incidentally, CAN is an abbreviation of Controller area network and means a protocol for performing communication between electronic modules by a common bus line.

The external interface circuit (peripheral circuit, interface) PR2 is connected with an external LSI EL2 through the surface electrode 3ap1, the wire 7, the bonding lead 2f, and the solder ball 6. Further, the external interface circuit PR2 is connected with the control circuit CC1 formed within the logic chip 4 through the surface electrode 3ap2, the projection electrode 9 and the surface electrode 4ap. The external interface circuit PR2 is a module (peripheral circuit, interface) that connects the external LSI EL2 and the semiconductor device 1. Incidentally, the control circuit CC1 is a control circuit connected with the CPU circuit PU1 and for causing the CPU circuit PU1 to control the external interface circuit PR2.

The memory (RAM) MM1 is comprised of the SRAM or global RAM or the like as described above. The memory (RAM) MM1 is connected with the CAN module PR1 through the system bus BS2 and the peripheral bus BS1 and connected with the control circuit CC2 formed within the logic chip 4 through the surface electrode 3ap2, the projection electrode 9 and the surface electrode 4ap. The control circuit CC2 is a control circuit connected with the CPU circuit PU1 and for causing the CPU circuit PU1 to control the memory MM1.

As described above, the memory (RAM) MM2 is comprised of the flash memory or DRAM or the like. The memory (RAM) MM2 is connected with the CAN module PR1 through the system bus BS2 and the peripheral bus BS1 and connected with the control circuit CC3 formed within the logic chip 4 through the surface electrode 3ap2, the projection electrode 9 and the surface electrode 4ap. The control circuit CC3 is a control circuit connected with the CPU circuit PU1 and for causing the CPU circuit PU1 to control the memory MM2.

As described above, the power control unit CU1 includes the power supply controller PC1 and the thermal diode (temperature sensor) TS1. The power supply control unit CU1 including the power supply controller PC1 and the thermal diode (temperature sensor) TS1 is connected with an external power supply EP1 through the surface electrode 3ap1, the wire 7, the bonding lead 2f and the solder ball 6. A power supply (drive power supply, current, voltage) from the external power supply EP1 is electrically connected with the power supply controller PC1 and supplied to the CPU circuit PU1 of the logic chip 4 through a power supply wire of the wires 7, a power supply wiring of the wiring layer 3as formed inside the peripheral circuit chip 3, and a power supply projection electrode of the projection electrodes 9.

The power supply control unit CU1 is connected with the respective circuits of the CAN module PR1, the external interface circuit PR2, the memory MM1 and the memory MM2, which are formed within the peripheral circuit chip 3, and controls the supply of a power supply (drive power supply, current, voltage) from the external power supply EP1 to the respective circuits. Further, the power supply control unit CU1 is connected via the surface electrode 3ap2, the projection electrode 9 and the surface electrode 4ap with the respective circuits of the CPU circuit PU1, the local RAM controller PR3, the memory MM3 and the control circuits CC1, CC2 and CC3, which are formed within the logic chip 4, and controls the supply of the power supply from the external power supply EP1 to the respective circuits.

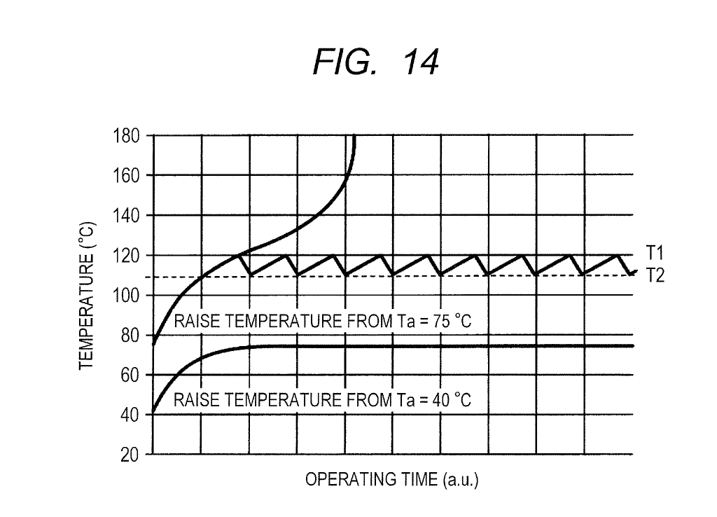

The thermal diode (temperature sensor) TS1 senses (detects) the temperature of the logic chip 4. Based on the temperature sensed (detected) by the thermal diode (temperature sensor) TS1, the power supply controller PC1 controls the supply of the power supply (drive power supply, current, voltage) from the external power supply EP1 to the CPU circuit PU1 formed within the logic chip 4. Thus, it is possible to prevent the temperature of the logic chip 4 from continuing to rise, as will be described later using FIG. 14, for example. Incidentally, various temperature sensors can be used in place of the thermal diode.

The CPU circuit (CPU) PU1 has a central processing unit (CPU) U1, a floating point processing unit (FPU) U2, and a microprocessor (MPU) U3.

The local RAM controller (peripheral circuit) PR3 is connected with the CPU circuit (CPU) PU1. The local RAM controller PR3 is a module (peripheral circuit) that controls the memory MM3 connected with the CPU circuit (CPU) PU1. Incidentally, when an instruction cache is formed within the logic chip 4, the local RAM controller PR3 is operated as an instruction cache controller (ICC) that controls the instruction cache.

As described above, the memory (RAM) MM3 is comprised of the SRAM or the local RAM or the like. The memory (RAM) MM3 is connected with the CPU circuit (CPU) PU1.

In the peripheral circuit chip 3, the CAN module (peripheral circuit) PR1, the external interface circuit (peripheral circuit, interface) PR2, the memory (RAM) MM1, and the memory MM2 are respectively manufactured based on a relatively rough process rule RL1, i.e., a low-end process (legacy process). Further, in the peripheral circuit chip 3, the power supply controller PC1 and the thermal diode (temperature sensor) TS1 are respectively manufactured based on the relatively rough process rule RL1, i.e., the low-end process (legacy process).

On the other hand, in the logic chip 4, the CPU circuit (CPU) PU1, the local RAM controller (peripheral circuit) PR3 and the memory (RAM) MM3 are respectively manufactured based on a process rule RL2 finer (smaller) than the process rule RL1, i.e., a high-end process (advanced process). Further, in the logic chip 4, the control circuits CC1, CC2 and CC3 are respectively manufactured based on the process rule RL2 finer (smaller) than the process rule RL1, i.e., the high-end process (advanced process).

Thus, of the circuits that configure the system, only the parts that need a high operating speed or high integration can be manufactured based on the relatively fine process rule RL2, i.e., the high-end process. Further, of the circuits that configure the system, the parts other than the parts that need the high operating speed or high integration can be manufactured based on the process rule RL1 not finer than the process rule RL2, i.e., the low-end process. Accordingly, of the circuits that configure the system, the circuits manufactured based on the fine process rule RL2, which are parts large in heating value, can be reduced in ratio. It is therefore possible to reduce the amount of heat generated by the semiconductor device and suppress the temperature of the semiconductor device from continuing to rise.

Since the SRAM is a circuit used to originally store data, it needs not to have an operating speed equivalent to the operating speed of the CPU. It is considered that it is sufficient for the SRAM to be manufactured based on the relatively unfine process rule, i.e., the low-end process. The memory MM3 comprised of the SRAM or the local RAM or the like is however preferably operated at the same speed as the operating speed of the CPU circuit PU1 because it is a memory for the CPU circuit PU1. Thus, the memory MM3 comprised of the SRAM or the local RAM or the like is preferably manufactured based on the relatively fine process rule, i.e., the high-end process although the memory MM3 is comprised of the same structure as that of the memory MM1 comprised of the SRAM or the global RAM. At this time, the memory MM1 comprised of the SRAM or the global RAM or the like is not operated as the same speed as the CPU circuit PU1, but the memory MM3 comprised of the SRAM or the local RAM or the like is operated as the same speed as the CPU circuit PU1.

In order to increase the storage capacity stored in the flash memory, the outer size of a region in which the memory MM2 comprised of the flash memory is formed is larger than a region in which another circuit is formed. There is therefore a possibility that the outer size of the logic chip 4 large in heating value will increase where the memory MM2 comprised of the flash memory is formed in the logic chip 4. Accordingly, it is preferable that the memory MM2 comprised of the flash memory is not formed in the logic chip 4 but in the peripheral circuit chip 3.

Further, it is desirable that circuit specifications of the storage capacity of the memory MM2 comprised of the flash memory, etc. can easily be modified in design according to the purpose or applications for which the semiconductor device is used. Therefore, when the memory MM2 comprised of the flash memory is formed in the logic chip 4, a mask with layout patterns being changed is required to be newly provided each time a design change is performed on the capacity according to the purpose or the applications for which the semiconductor device is used, i.e., according to the customers or needs.

On the other hand, in order to reduce the manufacturing cost by, for example, the use of the same mask and the like, the logic chip 4 is desirably used in common without being changed according to the purpose or applications for which the semiconductor device is used. Accordingly, the memory MM2 comprised of the flash memory in which a design change is easily performed on its circuit specifications according to the purpose or applications in which the semiconductor device is used, is preferably formed in the peripheral circuit chip 3 without being formed in the logic chip 4.

When the flash memory is not formed in the logic chip 4, the mask with the layout patterns being changed is not required to be newly provided as a mask for manufacturing the logic chip 4 even when a design change is made to the capacity of the flash memory according to the purpose or applications for which the semiconductor device is used, i.e., according to the customers or needs. Thus, since the mask used in the manufacture of the logic chip 4 and high in price can be used in common between manufacturing processes for manufacturing a plurality of types of semiconductor devices, the manufacturing cost of the semiconductor device can be reduced.

The outer size (occupation area) of the memory MM2 of the flash memory may be made larger than the outer size (occupation area) of each of the CAN module PR1, the current controller PC1, the thermal diode (temperature sensor) TS1, the memory MM1 such as the SRAM, the memory MM3 such as the SRAM, the CPU circuit PU1 and the local RAM controller PR3. It is thus possible to increase the capacity of the flash memory according to the purpose or applications for which the semiconductor device is used, i.e., according to the customers or needs.

The external interface circuit (peripheral circuit, interface) PR2 is also considered to be manufactured based on the relatively fine process rule, i.e., by the high-end process. Since, however, the external interface circuit PR2 is a circuit that connects the external LSI EL2 and the semiconductor device 1, a high voltage is applied to the external interface circuit PR2. That is, the value of the voltage applied (required for) to the external interface circuit PR2 is larger than the value of the voltage applied (required for) to each of the CAN module PR1, the thermal diode (temperature sensor) TS1, the memory MM1 such as the SRAM, the memory MM3 such as the SRAM, the CPU circuit PU1, and the local RAM controller PR3. Therefore, there is a fear that when the CPU circuit PU1 is formed in the vicinity of the external interface circuit PR2, a leak current increases in each MISFET included in the CPU circuit PU1, and the amount of heat generated in the CPU circuit PU1 increases. Accordingly, the external interface circuit PR2 is preferably formed in the peripheral circuit chip 3 close to the external LSI EL2.

In the semiconductor device of the present embodiment 1, the power supply (drive power supply, current, voltage) supplied from the external power supply EP1 is first supplied to the respective circuits formed in the peripheral circuit chip 3 and the respective circuits formed in the logic chip 4 (semiconductor chip, advanced process product, upper stage side) through the power supply control unit CU1 formed in the peripheral circuit chip (semiconductor chip, legacy process product, lower stage side). At this time, when the thermal diode TS1 formed in the power supply control unit CU1 senses (detects) that the amount of heat (self-heating amount) generated in the logic chip 4 has exceeded a predetermined upper limit value, the thermal diode TS1 gives an instruction to the power supply controller PC1 formed in the power supply control unit CU1 to control (cut off) the supply of a power supply to the logic chip 4.

Incidentally, in order to make it easier for the thermal diode (temperature sensor) TS1 to sense the amount of heat generated in each circuit formed in the logic chip 4, the outer size (occupation area) of the power supply control unit CU1 formed in the peripheral circuit chip 3 is substantially the same size as the outer size (occupation area) of the logic chip 4 in the present embodiment 1. Further, the logic chip 4 is mounted over the peripheral circuit chip 3 such that each of the circuits formed in the logic chip 4 overlaps with the power supply controller PC1 in plan view, in other words, the power supply control unit CU1 is covered with the logic chip 4. In other words, each of the power supply controller PC1 and the thermal diode TS1 is formed in its corresponding region superposed on the logic chip 4, i.e., its corresponding chip mounting region (chip mounting part) 3p1 that is a schedule region to mount the logic chip 4, of the surface 3a of the peripheral circuit chip 3. Thus, since the distance between the thermal diode TS1 and the logic chip 4 is shortened, it is possible to make it easier for the thermal diode (temperature sensor) TS1 to sense (detect) the amount of heat generated in each circuit formed in the logic chip 4 as described above.

<Operation as Microcomputer>

In the present embodiment 1, the peripheral circuit chip 3 and the logic chip 4 are operated as one microcomputer by combining the peripheral circuit chip 3 and the logic chip 4. For example, since the power supply control unit CU1 is not formed in the logic chip 4, the logic chip 4 single body cannot be operated as the microcomputer. Alternatively, since the peripheral circuits such as the external interface circuit PR2, etc. are not formed in the logic chip 4, it is not possible for the logic chip 4 single body to connect with the external LSI EL2 and operate as the microcomputer. Further, alternatively, since the CPU circuit PU1 is not formed in the peripheral circuit chip 3, for example, the peripheral circuit chip 3 single body cannot be operated as the microcomputer.

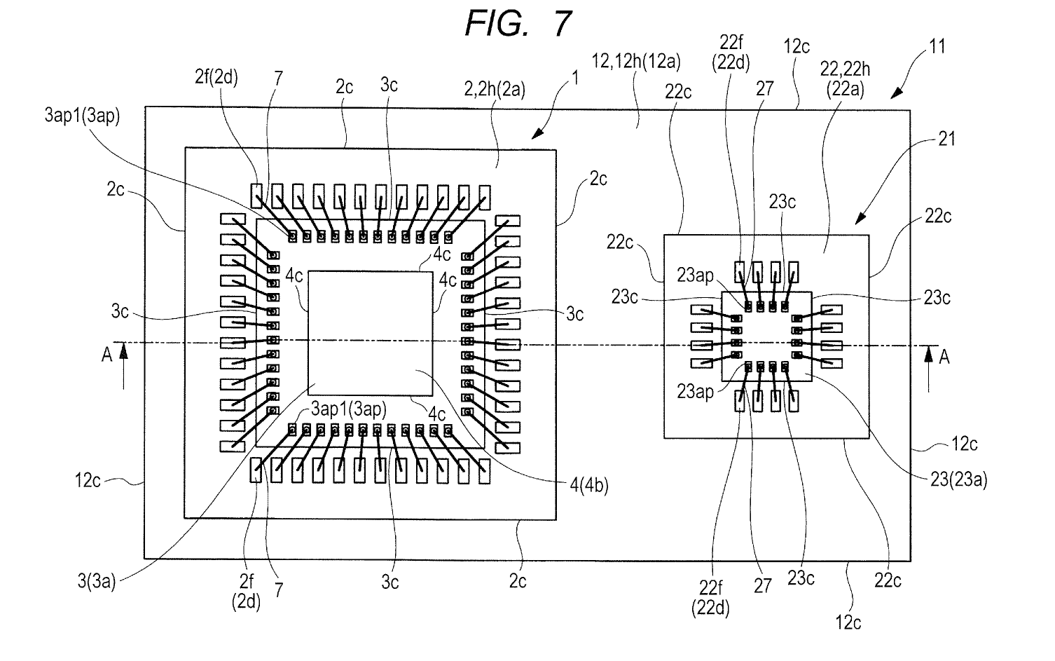

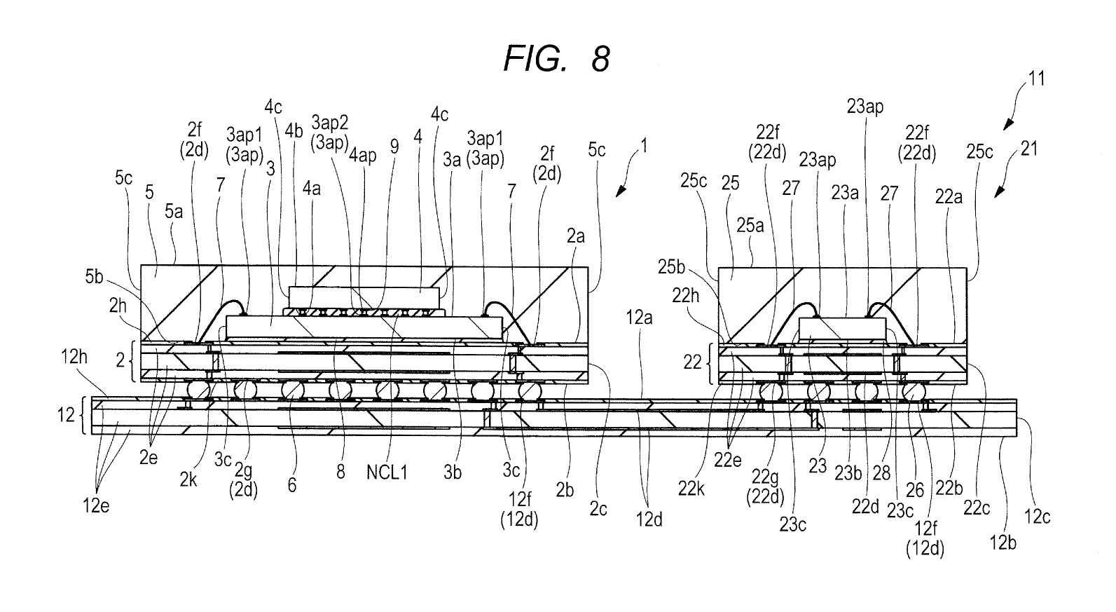

One system (semiconductor system) can be constructed by mounting the semiconductor device (semiconductor package, logic device) 1 of the present embodiment 1 having such a configuration over the wiring substrate (motherboard) mounted with the memory device and combining the semiconductor device and the memory device. This example will be described using FIGS. 7 and 8.

FIG. 7 is a perspective plan diagram of the system equipped with the semiconductor device of the embodiment 1 and the memory device. FIG. 7 shows the internal structure of the semiconductor device over the wiring substrate in the removed state of the sealing body. FIG. 8 is a sectional diagram of the system equipped with the semiconductor device of the embodiment 1 and the memory device. FIG. 8 is a sectional diagram taken along line A-A of FIG. 7.

As shown in FIGS. 7 and 8, the system (semiconductor system) 11 has a motherboard (wiring substrate) 12, a memory device 21 and a semiconductor device 1. The semiconductor device 1 is the semiconductor device 1 described using FIGS. 1 to 6.

The motherboard (wiring substrate) 12 has an upper surface (surface, main surface) 12a with the semiconductor device 1 and the memory device 21 mounted thereover, a lower surface (surface, main surface) 12b opposite to the upper surface 2a, and side surfaces 12c arranged between the upper surface 12a and the lower surface 12b. The motherboard 12 has an outer shape square in plan view as shown in FIGS. 7 and 8.

The motherboard (wiring substrate) 12 has a plurality of wiring layers (three layers in the example shown in FIG. 8) that electrically connect the upper surface 12a side and the lower surface 12b side with each other. The respective wiring layers are respectively formed with insulating layers 12e that insulate a plurality of wirings 12d, between the wirings 12d and between the adjacent wiring layers.

A plurality of bonding leads (terminals, electrodes) 12f, which are terminals electrically connected with the semiconductor device 1 and the memory device 21, are formed in the upper surface 12a of the motherboard (wiring substrate) 12. The upper surface 12a of the motherboard 12 is covered with an insulating film (solder resist film) 12h. At least some of the bonding leads 12f are exposed at openings defined in the insulating film 12h.

On the other hand, the memory device 21 is equipped with a wiring substrate 22 and a memory chip 23.

As shown in FIG. 8, the wiring substrate 22 has an upper surface (surface, main surface, chip mounting surface) 22a with the memory chip 23 mounted thereover, a lower surface (surface, main surface, mounting surface) 22b opposite to the upper surface 22a, and side surfaces 22c arranged between the upper surface 22a and the lower surface 22b. The wiring substrate 22 has an outer shape square in plan view as shown in FIGS. 7 and 8.

The wiring substrate 22 has a plurality of wiring layers (four layers in the example shown in FIG. 8) that electrically connect the upper surface 22a side and the lower surface 22b side with each other. The respective wiring layers are respectively formed with insulating layers 22e that insulate a plurality of wirings 22d, between the wirings 22d and between the adjacent wiring layers.

A plurality of bonding leads (terminals, terminals on the chip mounting surface side, electrodes) 22f, which are terminals electrically connected with the memory chip 23, are formed in the upper surface 22a of the wiring substrate 22. At least some (parts bonded to solder balls 26) of a plurality of lands 22g are exposed from an insulating film 22k at openings formed in the insulating film (solder resist film) 22k that covers the lower surface 22b of the wiring substrate 22. Further, a plurality of the solder balls (external terminals, electrodes, external electrodes) 26 bonded to the lands 22g are respectively connected with the bonding leads 12f of the motherboard (wiring substrate) 12. The upper surface 22a of the wiring substrate 22 is covered with an insulating film (solder resist film) 22h. At least some of the bonding leads 22f are exposed at openings formed in the insulating film 22h.

The memory chip 23 has a surface (main surface, upper surface) 23a, a back surface (main surface, lower surface) 23b opposite to the surface 23a, and side surfaces 23c positioned between the surface 23 and the back surface 23b. As shown in FIG. 7, the memory chip 23 has an outer shape square in plan view. Further, the memory chip 23 has surface electrodes (terminals, electrode pads, bonding pads) 23ap formed in the surface 23. Each circuit included in the memory chip 23 is formed on the surface 23a side of the memory chip 23.

The memory chip 23 is mounted over the wiring substrate 22 such that the back surface 23b of the memory chip 23 is opposed to the upper surface 22a of the wiring substrate 22. The memory chip 23 and the wiring substrate 22 are connected by wires (conductive members) 27. The back surface 23b of the memory chip 23 and the upper surface 22a of the wiring substrate 22 are bonded to each other through a die bond material (adhesive material, past material) 28.

Further, the memory device 21 includes a sealing body (sealing member, resin) 25 that seals the memory chip 23. The sealing body 25 has an upper surface (plane, surface) 25a, a lower surface (surface, back surface) 25b positioned opposite to the upper surface 25a, and side surfaces 25c positioned between the upper surface 25a and the lower surface 25b. The memory device 21 has an outer shape square in plan view.

Next, as one example of the operation where the semiconductor device 1 of the present embodiment 1 is systemized as the system 11, description will be made about the operation where the semiconductor device 1 reads data stored in the memory device 21 externally attached to the semiconductor device 1.

First, the CPU circuit PU1 formed in the logic chip 4 gives an instruction for transmitting a control signal to the memory device 21 as the external LSI EL2 to the control circuit CC1 electrically connected with the external interface circuit PR2 formed in the peripheral circuit chip 3. Then, the control circuit CC1 transmits a control signal to the memory device 21 as the external LSI EL2 through the external interface circuit PR2. Thereafter, the memory device 21 as the external LSI EL2 having received the control signal therein outputs the corresponding data.

Thus, the semiconductor device (semiconductor package, logic device) 1 of the present embodiment 1 performs control processing of the external LSI which has been carried out by one semiconductor chip (logic chip), using the two semiconductor chips of the peripheral circuit chip 3 and the logic chip 4.

Incidentally, the system 11 mounted with the semiconductor device 1 of the present embodiment 1 and the memory device 21 is different in structure from a semiconductor device in which a semiconductor chip formed with a CPU and a memory chip formed separately from the semiconductor chip are laminated over a wiring substrate to be formed as a single semiconductor package (SiP).

<Semiconductor Chip>

The minimum wiring width of each of the peripheral circuit chip (semiconductor chip) 3 and the logic chip (semiconductor chip) 4 will next be described using FIGS. 9 to 12. FIG. 9 is a sectional diagram showing an example of a structure of a wiring layer in a peripheral circuit chip of the semiconductor device of the embodiment 1. FIG. 10 is a sectional diagram illustrating an example of a structure of a wiring layer in a logic chip of the semiconductor device of the embodiment 1. FIG. 11 is a sectional diagram showing an example of a structure of a MISFET in the peripheral circuit chip of the semiconductor device of the embodiment 1. FIG. 12 is a sectional diagram showing an example of a structure of a MISFET in the logic chip of the semiconductor device of the embodiment 1.

As shown in FIGS. 9 and 11, in the peripheral circuit chip 3, a p-type well (active region) 31a, an n-type well (active region) 31b, an element isolation trench 32 embedded with an element isolation insulating film comprised of a silicon oxide film or the like are formed on the main surface 30p side of a semiconductor substrate 30S comprised of p-type single crystal silicon, for example. An n channel type MISFET (transistor) Qn3 is formed in the p-type well 31a, and a p channel type MISFET (transistor) Qp3 is formed in the n-type well 31b.

The n channel type MISFET Qn3 and the p channel type MISFET Qp3 are respectively transistors which configure each of the CAN module PR1, the power supply controller PC1, the thermal diode TS1 and the memory MM1.

As shown in FIGS. 9 and 11, the n channel type MISFET Qn3 has a source region ns3 and a drain region nd3 formed in the p-type well 31a defined by the element isolation trench 32, and a gate electrode ge3 formed over the p-type well 31a through a gate insulating film gi3 interposed therebetween. Each side surface of the gate electrode ge3 of the n channel type MISFET Qn3 is covered with a sidewall sw3. The source region ns3, drain region nd3 and gate electrode ge3 of the n channel type MISFET Qn3 are electrically connected with other semiconductor elements or wirings through a wiring layer 3as to be described later.

On the other hand, the p channel type MISFET Qp3 has a source region ps3 and a drain region pd3 formed in the n-type well 31b defined by the element isolation trench 32, and a gate electrode ge3 formed over the n-type well 31b through a gate insulating film gi3 interposed therebetween. Each side surface of the gate electrode ge3 of the p channel type MISFET Qp3 is covered with a sidewall sw3. The source region ps3, drain region pd3 and gate electrode ge3 of the p channel type MISFET Qp3 are electrically connected with other semiconductor elements or wirings through the wiring layer 3as to be described later.

Incidentally, semiconductor elements such as a resistance element, a capacitance element, etc. are formed over an actual semiconductor substrate 30S.

The wiring layer 3as having a multilayer wiring structure is formed above the n channel type MISFET Qn3 and the p channel type MISFET Qp3 by laminating wirings each comprised of a metal film connecting between the semiconductor elements on each other. As one example of the wiring layer 3as, five layer wirings comprised of a metal film, which are formed mainly of aluminum (Al), i.e., a first layer wiring 33a, a second layer wiring 33b, a third layer wiring 33c, a fourth layer wiring 33d and a fifth layer wiring 33e are shown in FIG. 9.

First, an interlayer insulating film 34 is formed over the main surface 30p of the semiconductor substrate 30S so as to cover the n channel type MISFET Qn3 and the p channel type MISFET Qp3. A metal plug p31, which penetrates through the interlayer insulating film 34 to reach the source region ns3 or drain region nd3 of the n channel type MISFET Qn3 or the source region ps3 or drain region pd3 of the p channel type MISFET Qp3, is formed in the interlayer insulating film 34. The metal plug p31 is electrically connected with the source region ns3 or drain region nd3 of the n channel type MISFET Qn3 or the source region ps3 or drain region pd3 of the p channel MISFET Qp3. The first layer wiring 33a is formed over the interlayer insulating film 34. The first layer wiring 33a is electrically connected with the metal plug p31. An interlayer insulating film 35 is formed over the interlayer insulating film 34 inclusive of the surface of the first layer wiring 33a.

A metal plug p32 that penetrates through the interlayer insulating film 35 to reach the first layer wiring 33a is formed in the interlayer insulating film 35. The metal plug p32 is electrically connected with the first layer wiring 33a. The second layer wiring 33b is formed over the interlayer insulating film 35. The second layer wiring 33b is electrically connected with the metal plug p32. An interlayer insulating film 36 is formed over the interlayer insulating film 35 inclusive of the surface of the second layer wiring 33b.

A metal plug p33 that penetrates through the interlayer insulating film 36 to reach the second layer wiring 33b is formed in the interlayer insulating film 36. The metal plug p33 is electrically connected with the second layer wiring 33b. The third layer wiring 33c is formed over the interlayer insulating film 36. The third layer wiring 33c is electrically connected with the metal plug p33. An interlayer insulating film 37 is formed over the interlayer insulating film 36 inclusive of the surface of the third layer wiring 33c.

Similarly, a metal plug p34 that penetrates through the interlayer insulating film 37 to reach the third layer wiring 33c and is thereby electrically connected with the third layer wiring 33c is formed in the interlayer insulating film 37. The fourth layer wiring 33d electrically connected with the metal plug p34 is formed over the interlayer insulating film 37. An interlayer insulating film 38 is formed over the interlayer insulating film 37 inclusive of the surface of the fourth layer wiring 33d.

Further, a metal plug p35 that penetrates through the interlayer insulating film 38 to reach the fourth layer wiring 33d and is thereby electrically connected with the fourth layer wiring 33d is formed in the interlayer insulating film 38. The fifth layer wiring 33e electrically connected with the metal plug p35 is formed over the interlayer insulating film 38. An interlayer insulating film 39 is formed over the interlayer insulating film 38 inclusive of the surface of the fifth layer wiring 33e. A metal plug p36 that penetrates through the interlayer insulating film 38 to reach the fifth layer wiring 33e is formed in the interlayer insulating film 39.

Incidentally, the metal plugs p31, p32, p33, p34, p35 and p36 are respectively comprised of a tungsten (W) film, for example.

A surface electrode (terminal, electrode pad, bonding pad) 3ap comprised of aluminum (Al), for example, is formed over the interlayer insulating film 39. The surface electrode 3ap is electrically connected with the metal plug p36. As shown in FIG. 9, a single layer film such as a silicon oxide film, a silicon nitride film or the like, or a surface protection film 3h comprised of these two layer films may be formed as a final passivation film over the interlayer insulating film 39 inclusive of the surface of the surface electrode 3ap. At this time, the surface electrode 3ap is exposed at the bottom of a pad opening 3i formed in the surface protection film 3h.

Incidentally, in the specification of the present application, as shown in FIG. 9, the surface 3a of the peripheral circuit chip (semiconductor chip) 3 means the upper surface of the wiring layer 3as having the multilayer wiring structure, i.e., the upper surface of the interlayer insulating film 39. At this time, the surface electrode 3ap is formed over the surface 3a of the peripheral circuit chip 3.

Incidentally, a rewiring (not shown) may be formed between the fifth layer wiring 33e and the surface electrode 3ap. The rewiring electrically connects the fifth layer wiring 33e and the surface electrode 3ap with each other. Thus, the surface electrode 3ap can be formed in a position apart from the metal plug p36 in plan view.

As with the peripheral circuit chip shown in FIGS. 9 and 11 even in the logic chip 4 shown in FIGS. 10 and 12, a p-type well (active region) 41a, an n-type well (active region) 41b, and an element isolation trench 42 embedded with an element isolation insulating film comprised of a silicon oxide film or the like are formed on the main surface 40p side of a semiconductor substrate 40S comprised of p-type single crystal silicon, for example. An n channel type MISFET (transistor) Qn4 is formed in the p-type well 41a, and a p channel type MISFET (transistor) Qp4 is formed in the n-type well 41b.

The n channel type MISFET Qn4 and the p channel type MISFET Qp4 are respectively transistors which respectively configure the CAP circuit PU1, the local RAM controller PR3 and the memory MM3.

As shown in FIGS. 10 and 12, the n channel type MISFET Qn4 has a source region ns4 and a drain region nd4 formed in the p-type well 41a as the active region defined by the element isolation trench 42, and a gate electrode ge4 formed over the p-type well 41a through a gate insulating film gi4 interposed therebetween. Each side surface of the gate electrode ge4 of the n channel type MISFET Qn4 is covered with a sidewall sw4. The source region ns4, drain region nd4 and gate electrode ge4 of then channel type MISFET Qn4 are electrically connected with other semiconductor elements or wirings through a wiring layer 4as to be described later.

The p channel type MISFET Qp4 has a source region ps4 and a drain region pd4 formed in the n-type well 41b as the active region defined by the element isolation trench 42, and a gate electrode ge4 formed over the n-type well 41b through a gate insulating film gi4 interposed therebetween. Each side surface of the gate electrode ge4 of the p channel type MISFET Qp4 is covered with a sidewall sw4. The source region ps4, drain region pd4 and gate electrode ge4 of the p channel type MISFET Qp4 are electrically connected with other semiconductor elements or wirings through the wiring layer 4as to be described later.

Incidentally, semiconductor elements such as a resistance element, a capacitance element, etc. are formed over an actual semiconductor substrate 40S.

The wiring layer 4as having a multilayer wiring structure is formed above the n channel type MISFET Qn4 and the p channel type MISFET Qp4 by laminating wirings each comprised of a metal film connecting between the semiconductor elements on each other. As one example of the wiring layer 4as, five layer wirings comprised of a metal film, which are formed mainly of aluminum (Al), i.e., a first layer wiring 43a, a second layer wiring 43b, a third layer wiring 43c, a fourth layer wiring 43d and a fifth layer wiring 43e are shown in FIG. 10.

First, an interlayer insulating film 44 is formed over the main surface 40p of the semiconductor substrate 40S so as to cover the n channel type MISFET Qn4 and the p channel type MISFET Qp4. A metal plug p41, which penetrates through the interlayer insulating film 44 to reach the source region ns4 or drain region nd4 of the n channel type MISFET Qn4 or the source region ps4 or drain region pd4 of the p channel type MISFET Qp4, is formed in the interlayer insulating film 44. The metal plug p41 is electrically connected with the source region ns4 or drain region nd4 of the n channel type MISFET Qn4 or the source region ps4 or drain region pd4 of the p channel MISFET Qp4. The first layer wiring 43a is formed over the interlayer insulating film 44. The first layer wiring 43a is electrically connected with the metal plug p41. An interlayer insulating film 45 is formed over the interlayer insulating film 44 inclusive of the surface of the first layer wiring 43a.

A metal plug p42 that penetrates through the interlayer insulating film 45 to reach the first layer wiring 43a is formed in the interlayer insulating film 45. The metal plug p42 is electrically connected with the first layer wiring 43a. The second layer wiring 43b is formed over the interlayer insulating film 45. The second layer wiring 43b is electrically connected with the metal plug p42. An interlayer insulating film 46 is formed over the interlayer insulating film 45 inclusive of the surface of the second layer wiring 43b.

A metal plug p43 that penetrates through the interlayer insulating film 46 to reach the second layer wiring 43b is formed in the interlayer insulating film 46. The metal plug p43 is electrically connected with the second layer wiring 43b. The third layer wiring 43c is formed over the interlayer insulating film 46. The third layer wiring 43c is electrically connected with the metal plug p43. An interlayer insulating film 47 is formed over the interlayer insulating film 46 inclusive of the surface of the third layer wiring 43c.

Similarly, a metal plug p44 that penetrates through the interlayer insulating film 47 to reach the third layer wiring 43c and is thereby electrically connected with the third layer wiring 43c is formed in the interlayer insulating film 47. The fourth layer wiring 43d electrically connected with the metal plug p44 is formed over the interlayer insulating film 47. An interlayer insulating film 48 is formed over the interlayer insulating film 47 inclusive of the surface of the fourth layer wiring 43d.

Further, a metal plug p45 that penetrates through the interlayer insulating film 48 to reach the fourth layer wiring 43d and is thereby electrically connected with the fourth layer wiring 43d is formed in the interlayer insulating film 48. The fifth layer wiring 43e electrically connected with the metal plug p45 is formed over the interlayer insulating film 48. An interlayer insulating film 49 is formed over the interlayer insulating film 48 inclusive of the surface of the fifth layer wiring 43e. A metal plug p46 that penetrates through the interlayer insulating film 48 to reach the fifth layer wiring 43e is formed in the interlayer insulating film 49.

Incidentally, the metal plugs p41, p42, p43, p44, p45 and p46 are respectively comprised of a tungsten (W) film, for example.

A surface electrode (terminal, electrode pad, bonding pad) 4ap comprised of aluminum (Al), for example, is formed over the interlayer insulating film 49. The surface electrode 4ap is electrically connected with the metal plug p46. As shown in FIG. 10, a single layer film such as a silicon oxide film, a silicon nitride film or the like, or a surface protection film 4h comprised of these two layer films may be formed as a final passivation film over the interlayer insulating film 49 inclusive of the surface of the surface electrode 4ap. At this time, the surface electrode 4ap is exposed at the bottom of a pad opening 4i formed in the surface protection film 4h.

Incidentally, in the specification of the present application, as shown in FIG. 10, the surface 4a of the logic chip (semiconductor chip) 4 means the upper surface of the wiring layer 4as having the multilayer wiring structure, i.e., the upper surface of the interlayer insulating film 49. At this time, the surface electrode 4ap is formed over the surface 4a of the logic chip 4.

Incidentally, a rewiring (not shown) may be formed between the fifth layer wiring 43e and the surface electrode 4ap. The rewiring electrically connects the fifth layer wiring 43e and the surface electrode 4ap with each other. Thus, the surface electrode 4ap can be formed in a position apart from the metal plug p46 in plan view.

In the present embodiment 1, each semiconductor element is manufactured based on the relatively rough process rule RL1, i.e., the low-end process (legacy process) in the peripheral circuit chip 3. Further, in the logic chip 4, each semiconductor element is manufactured based on the process rule RL2 finer (smaller) than the process rule RL1, i.e., the high-end process (advanced process).

Incidentally, although there is no absolute boundary like a certain manufacturing process is either the high-end process or the low-end process, for example, a manufacturing process where the process rule is 55 nm or more can be taken as the low-end process, and a manufacturing process where the process rule is less than 55 nm can be taken as the high-end process.

In the peripheral circuit chip 3, the gate insulating film gi3 of each of the MISFETs Qn3 and Qp3 is preferably comprised of a silicon oxide film, a silicon nitride film or a silicon oxynitride film. The gate electrode ge3 of each of the MISFETs Qn3 and Qp3 is comprised of polysilicon (polycrystalline silicon). The operating speed of each circuit such as the memory MM1 comprised of the SRAM may be smaller than that of each circuit such as the CPU circuit PU1. Thus, since a material containing silicon and high in affinity with the semiconductor substrate 30S can be used as a material for the gate insulating film gi3 and the gate electrode ge3 of each of the MISFETs Qn3 and Qp3, the number of manufacturing processes can be reduced and the manufacturing cost can be reduced.

On the other hand, in the logic chip 4, the gate insulating film gi4 of each of the MISFETs Qn4 and Qp4 is preferably comprised of a so-called high dielectric constant (High-k) film higher in permittivity than the silicon nitride film, such as an insulating film containing hafnium like hafnium oxide (HfO₂) film or the like. Further, the gate electrode ge4 of each of the MISFETs Qn4 and Qp4 is comprised of a metal material such as titanium nitride (TiN) or the like, for example. There is a fear that when each MISFET is miniaturized and the thickness of the gate insulating film is made small, a leak current flowing through the gate insulating film will increase. Since, however, the leak current can be reduced by using the gate insulating film gi4 and gate electrode ge4 each comprised of the above-described material even when the MISFETs Qn4 and Qp4 are miniaturized, the amount of heat generated in the logic chip 4 can be reduced.

As described above, in the present embodiment 1, the peripheral circuit chip 3 is manufactured based on the relatively rough process rule RL1, and the logic chip 4 is manufactured based on the process rule RL2 finer (smaller) than the process rule RL1. Therefore, when the minimum wiring space MWS in the wiring layer 3as of the peripheral circuit chip 3 is taken to be a minimum wiring space MWS1, and the minimum wiring space MWS in the wiring layer 4as of the logic chip 4 is taken to be a minimum wiring space MWS2, the minimum wiring space MWS1 in the wiring layer 3as of the peripheral circuit chip 3 is larger than the minimum wiring space MSW2 in the wiring layer 4as of the logic chip 4. In other words, the minimum wiring space MWS2 in the wiring layer 4as of the logic chip 4 is smaller than the minimum wiring space MWS1 in the wiring layer 3as of the peripheral circuit chip 3.

In the wring layer in which the plural wirings are laminated over the main surface of the semiconductor substrate, normally, the wirings located on the side (lower layer) close to the main surface of the semiconductor substrate becomes thinner in film thickness, and the wiring space is small. In such a case, in each semiconductor chip, the minimum value of the distance between the centers of the first layer wirings adjacent to each other is defined as the minimum wiring space MWS. In other words, in the peripheral circuit chip 3, the minimum wiring space MWS1 is the minimum value of the distance between the centers of the first layer wirings 33a each being the wiring closest to the main surface 30p in the wiring layer 3as formed over the main surface 30p of the semiconductor substrate 30S. Further, in the logic chip 4, the minimum wiring space MWS2 is the minimum value of the distance between the centers of the first layer wirings 43a each being the wiring closest to the main surface 40p in the wiring layer 4as formed over the main surface 40p of the semiconductor substrate 40S.

Incidentally, in the wiring layer in which the plural wirings are laminated over the main surface of the semiconductor substrate, when the wiring space between the wirings in the layer other than the first layer wiring become minimum, the minimum value of the distance between the centers of the wirings of the layer minimal in the wiring space becomes the minimum wiring space MWS.

The first layer wiring 33a in the peripheral circuit chip 3, and the first layer wiring 43a in the logic chip 4 are collectively called a first layer wiring M1. The second layer wiring 33b in the peripheral circuit chip 3, and the second layer wiring 43b in the logic chip 4 are collectively called a second layer wiring M2. Further, the process rule RL1 and the process rule RL2 are collectively called a process rule RL.

Consider where the process rule RL is 65 nm, for example. In this case, in the wirings of the second layer wiring M2 or more wiring layers, the minimum wire width is 100 nm, for example, and the minimum space width is 100 nm, for example. The minimum value of the distance between the centers of the adjacent wirings at this time is 200 nm. On the other hand, the ratio of the minimum wire width for the first layer wiring M1 to the minimum wire width for each wiring in the second layer or more wiring layers is 90%. The ratio of the minimum space width in the first layer wiring M1 to the minimum space width for each wiring in the second layer or more wiring layers is 90%. Thus, when the process rule RL is 65 nm, the minimum wiring space MWS corresponding to the distance between the centers of the first layer wirings M1 adjacent to each other is 180 nm.

Next, for example, the minimum wire width and the minimum space width for each wiring of the second layer or more wiring layers where the process rule RL is 55 nm is reduced by 90% relative to the minimum wire width and the minimum space width for each wiring of the second layer or more wiring layers where the process rule RL is 65 nm. Accordingly, in the wirings of the second layer or more wiring layers, the minimum wire width is 90 nm, for example, and the minimum space width is 90 nm, for example. The minimum value of the distance between the centers of the adjacent wirings at this time is 180 nm. On the other hand, the ratio of the minimum wire width in the first layer wiring M1 to the minimum wire width for each wiring of the second layer or more wiring layers is 90%. The ratio of the minimum space width for the first layer wiring M1 to the minimum space width for each wiring of the second layer or more wiring layers is 90%. Thus, when the process rule RL is 55 nm, the minimum wiring space MWS corresponding to the distance between the centers of the first layer wirings M1 adjacent to each other is 162 nm.

Further, when the process rule RL is 40 nm, for example, i.e., when it is less than 55 nm, the minimum wiring space MWS corresponding to the distance between the centers of the first layer wirings M1 adjacent to each other is small as compared with the case where the process rule RL is 55 nm, for example. Accordingly, when the process rule RL is 40 nm, for example, i.e., when it is less than 55 nm, the minimum wiring space MWS corresponding to the distance between the centers of the first layer wirings M1 adjacent to each other is less than 162 nm.

The operating speed of the CPU in the CPU circuit PU1 of the logic chip 4 is defined as a clock frequency of the CPU. Further, when the operating speed of the CPU, i.e., its clock frequency is heightened to, for example, about 400 Hz or higher, the process rule RL2 at the time of manufacture of the logic chip 4 is preferably less than 55 nm. Accordingly, as described above, preferably, the minimum wiring space MWS2 at the first layer wiring 43a is less than 162 nm in the logic chip 4. On the other hand, the process rule RL1 at the time of manufacture of the peripheral circuit chip 3 is preferably greater than or equal to 55 nm. Thus, preferably, the minimum wiring space MSW1 at the first layer wiring 33a is greater than or equal to 162 nm in the peripheral circuit chip 3.

Incidentally, when the process rule RL2 at the time of manufacture of the logic chip 4 is smaller than the process rule RL1 at the time of manufacture of the peripheral circuit chip 3, the minimum value of a gate length GLN2 of the n channel type MISFET Qn4 of the logic chip 4 shown in FIG. 12 is smaller than the minimum value of a gate length GLN1 of the n channel type MISFET Qn3 of the peripheral circuit chip 3 shown in FIG. 11. Although illustration is omitted, the minimum value of a gate length of the p channel type MISFET Qp4 of the logic chip 4 is smaller than that of a gate length of the p channel type MISFET Qp3 of the peripheral circuit chip 3.

<Rise in Temperature of Semiconductor Chip>

Description will next be made using FIG. 13 about that with micronization of the process rule at the time of manufacture of the semiconductor device, the temperature of the semiconductor chip becomes easier to continue to more rise, and a rise in the temperature of the semiconductor chip can be prevented or suppressed according to the present embodiment 1.

A case where the peripheral circuit chip and the logic chip are integrated as one semiconductor chip will hereinafter be called a comparative example.

FIG. 13 is a graph showing a result obtained by simulating a relation between the operating time and temperature of a semiconductor chip in the comparative example. In FIG. 13, the horizontal axis indicates the operating time of the semiconductor chip, and the vertical axis indicates the temperature of the semiconductor chip. In FIG. 13, there is shown a relation between the operating time and temperature of the semiconductor chip where its ambient temperature (environmental temperature) is at each of 25° C., 35° C., 45° C., 55° C., 65° C., 75° C., 85° C. and 95° C.

Incidentally, the result shown in FIG. 13 is a result of execution of a simulation under the condition that the process rule at the time of manufacture of the semiconductor chip is 40 nm, the clock frequency of the CPU, i.e., its operating frequency is 400 MHz, and the number of cores in the CPU is one.

When the ambient temperature (environmental temperature) Ta is at 25° C. to 65° C. as shown in FIG. 13, the temperature of the semiconductor chip rises after its operation start. This is because current leaks through a location or path insulated and where it should not be made to originally flow on an electronic circuit of the semiconductor chip, i.e., the leak current is generated. This is also because the semiconductor chip itself generates heat when the leak current is generated. Since, however, the amount of heat generated by the semiconductor device itself, and the amount of heat radiated around from the semiconductor device are balanced with the lapse of the operating time of the semiconductor chip, the increasing speed of the temperature of the semiconductor chip is gradually reduced. Accordingly, the temperature of the semiconductor chip approaches a constant temperature with the lapse of the operating time of the semiconductor chip.

On the other hand, even when the ambient temperature (environmental temperature) Ta is at 75° C., 85° C. and 95° C., the temperature of the semiconductor chip rises after the start of its operation. This is because the leak current is generated as with the case where the ambient temperature Ta is at 25° C. to 65° C., and the semiconductor chip itself generates heat when the leak current is generated. When, however, the ambient temperature (environmental temperature) Ta is at 75° C., 85° C. and 95° C., the amount of heat generated by the semiconductor chip itself is large as compared with the case where the ambient temperature Ta is at 25° C. to 65° C. Therefore, the temperature of the semiconductor chip continues to rise after the start of its operation. Thus, the semiconductor chip may possibly not be operated normally when the temperature of the semiconductor chip continues to rise in this manner. That is, there is an increased potential for the semiconductor chip not to operate normally with a rise in the ambient temperature (environmental temperature) Ta.

Though illustration is omitted, a simulation similar to the above was conducted even when the process rule at the time of manufacture of the semiconductor device was 90 nm, 65 nm and 28 nm. From the result, the inventors of the present application have predicted that with micronization of the process rule at the time of manufacture of the semiconductor device from 90 nm to 65 nm, 40 nm and 28 nm, the above leak current more increases, and further the temperature of the semiconductor device continues to more increase.

Further, according to the examinations of the inventors of the present application, the inventors have found out that the factors that cause the above problems reside even in the following points.

One semiconductor chip having a CPU is formed, inclusive of the above CPU, with a plurality of circuits such as a local RAM controller, a memory such as a RAM and a flash memory or the like, a CAN module, an external interface circuit, and power supply controller, etc.

Further, in order to realize high integration, speed-up or low power consumption or the like of the semiconductor device, at least the CPU of the above circuits is required to be manufactured based on a relatively fine (small) process rule, i.e., a high-end process (advanced process). However, of those other than the CPU in the above circuits, there also exist the circuits that can be manufactured based on a process rule not finer (rougher) than a process rule in a high-end process, i.e., by a low-end process (legacy process).

It is however difficult to manufacture one semiconductor chip by a plurality of manufacturing processes different in process rule from each other.

It is therefore considered that the circuits other than the CPU in the above circuits and capable of being manufactured by the so-called low-end process are manufactured based on the same process rule as the process rule at the time of manufacture of the CPU, i.e., the high-end process. However, the inventors of the present application have found that manufacturing all circuits included in the semiconductor chip by the high-end process as a measure taken against the manufacture of the circuits by the plural manufacturing processes different from each other being difficult is one factor that causes the above problem of the leak current.

Thus, in the present embodiment 1, the peripheral circuit chip 3 and the logic chip 4 are divided to be formed as separate semiconductor chips. While the logic chip 4 including the CPU circuit PU1 is manufactured based on the fine process rule RL2 that is less than 55 nm, for example, the peripheral circuit chip 3 including the peripheral circuit such as the CAN module PR1 and the power control unit CU1 is manufactured based on the process rule RL1 not finer than the process rule RL2, i.e., the legacy process. Thus, of the circuits included in the entire semiconductor chip, the circuits other than the circuits required to miniaturize the CPU or the like operated at high speed can be formed in the peripheral circuit chip 3 without their miniaturization. In the circuits formed in the peripheral circuit chip 3, the leak current can be prevented or suppressed from flowing. Since the ratio of the circuits manufactured based on the fine process rule RL2 in the circuits included in the entire semiconductor chip can be reduced, a total amount of leak current flowing therethrough can be reduced for the semiconductor chip as a whole. Therefore, the amount of heat generated by the leak current itself can be reduced as compared with the case where the peripheral circuit chip 3 and the logic chip 4 are integrated and the integrated entire semiconductor chip is manufactured based on the fine process rule RL2 that is less than 55 nm, for example. Consequently, the temperature of the entire semiconductor chip can be prevented from continuing to rise, and the semiconductor chip can normally be operated at a higher temperature while ensuring the operating speed of the CPU. Thus, the semiconductor device can easily be highly integrated and easily speeded up, thereby enabling the semiconductor device to be easily reduced in power consumption.

<Power Shutdown with Rise in Temperature of Semiconductor Chip>

Description will next be made about execution of power shutdown with a rise in the temperature of the semiconductor chip using FIG. 14.

FIG. 14 is a graph showing a relation between the operating time and temperature of the semiconductor chip where power shutdown accompanying the temperature rise of the semiconductor chip is performed in the comparative example. A result of execution of a simulation where the ambient temperature Ta is at 75° C. is shown in FIG. 14. A result where the temperature rises (is raised) from 40° C. and 75° C. without power shutdown, i.e., where the ambient temperature Ta is at 40° C. and 75° C. in FIG. 13 is superposably shown in FIG. 14.

When the temperature of the semiconductor chip is raised to a prescribed temperature T1 where power shutdown is conducted with the rise in the temperature of the semiconductor chip, the supply of power to the CPU is cut off to stop the operation of the CPU. Consequently, the temperature of the semiconductor chip is gradually reduced. Thereafter, when the temperature of the semiconductor chip is at the prescribed temperature and lowered to a temperature T2 lower than the temperature T1, the supply of power to the CPU is resumed to restart the operation of the CPU. After that, the control of cutting off the supply of power when the temperature of the semiconductor chip is raised to the temperature T1, and resuming the supply of power when the temperature of the semiconductor chip is lowered to the temperature T2 is repeated. It is thus possible to prevent the temperature of the semiconductor chip from continuing to rise.

In the present embodiment 1 as described above, the amount of heat generated by the leak current can be reduced as compared with the case (comparative example) where the peripheral circuit chip 3 and the logic chip 4 are integrated. Further, in the present embodiment 1, when the temperature of the logic chip 4, i.e., the temperature sensed by the thermal diode TS1 is raised to the prescribed temperature T1, the supply of the power from the external power supply EP1 to the CPU circuit PU1 is cut off by the power control unit CU1 to stop the operation of the CPU. Thereafter, when the temperature of the logic chip 4 is at the prescribed temperature and lowered to the temperature T2 and lowered to the temperature T2 lower than the above temperature T1, the supply of the power from the external power supply EP1 to the CPU circuit PU1 is resumed by the power supply control unit CU1 to resume the operation of the CPU circuit PU1. After that, the control of cutting off the supply of the power from the external power supply EP1 to the CPU circuit PU1 by the power supply control unit CU1 when the temperature of the logic chip 4 is raised to the temperature T1, and resuming the supply of the power from the external power supply EP1 to the CPU circuit PU1 by the power supply control unit CU1 when the temperature of the logic chip 4 is lowered to the temperature T2 is repeated. It is thus possible to prevent the temperature of the logic chip 4 from continuing to rise. By performing the control of shutting off the power supply with the rise in the temperature of the logic chip 4 in this way, the temperature of each of the logic chip 4 and the peripheral circuit chip 3 can be prevented from continuing to rise.

Further, in the present embodiment 1 as described above, preferably, the logic chip 4 can be arranged over the region formed with the power supply control unit CU1, of the surface 3a of the peripheral circuit chip 3. Thus, the logic chip 4 can be arranged directly on the thermal diode (temperature sensor) TS1 included in the power supply control unit CU1, and the temperature of the logic chip 4 can be sensed (detected) with high accuracy. Accordingly, it is possible to more reliably prevent the temperature of the logic chip 4 from continuing to rise.

<Manufacturing Method of Semiconductor Device>

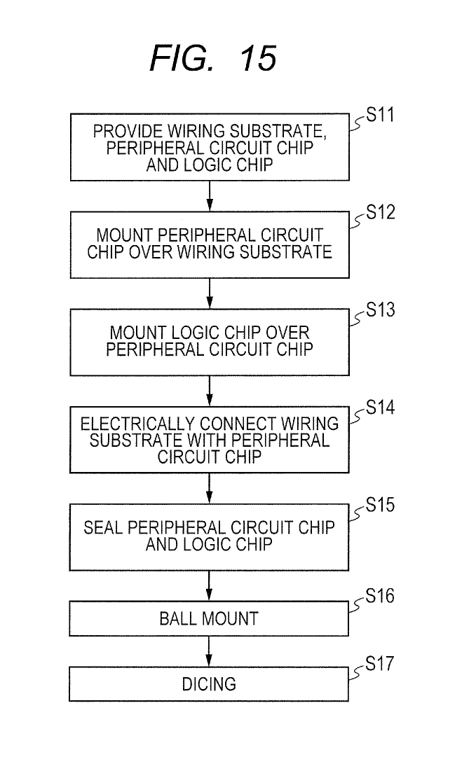

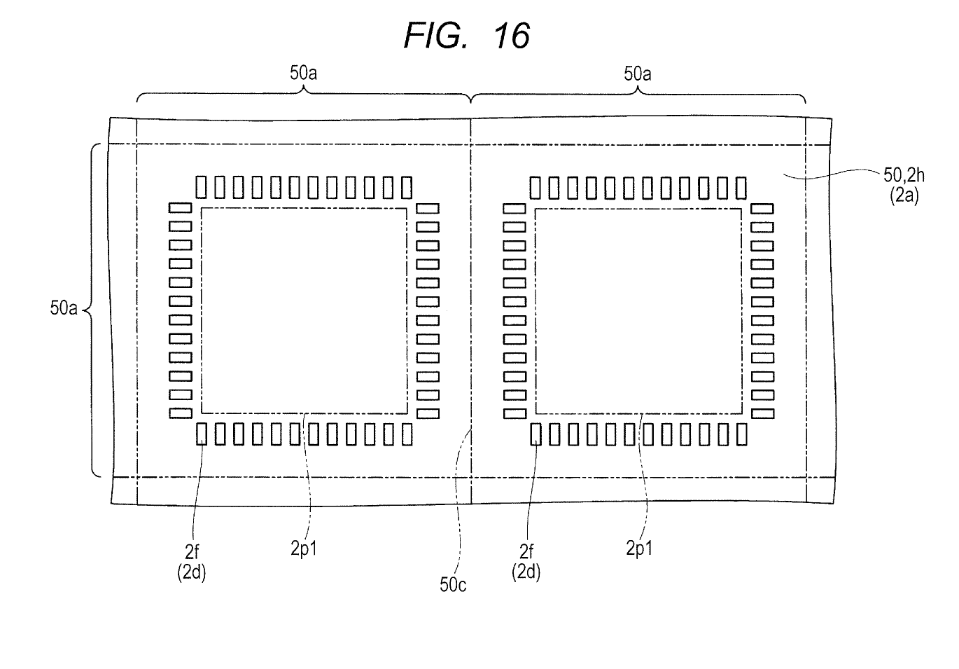

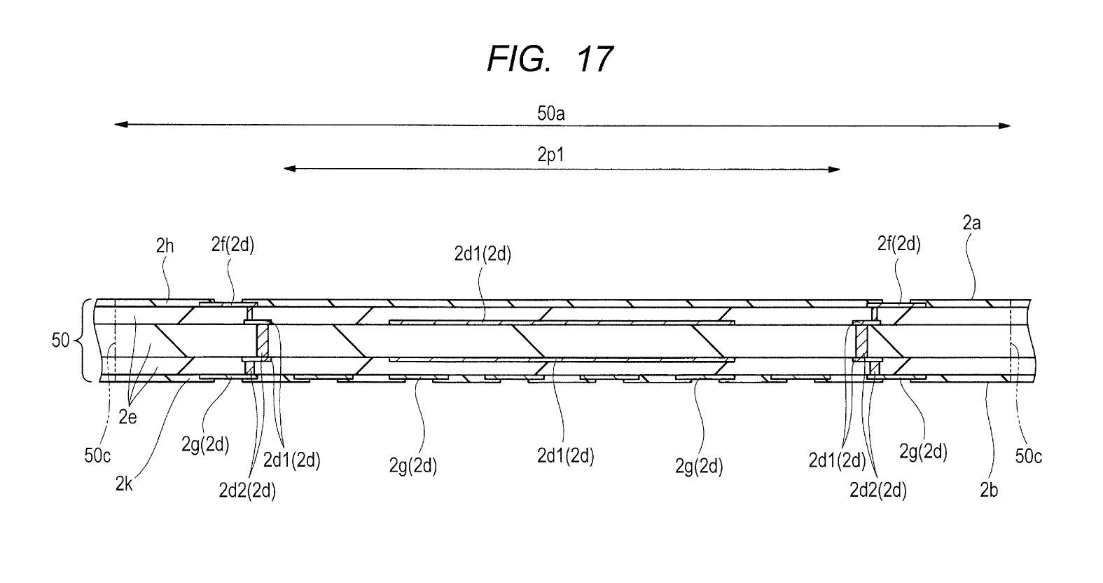

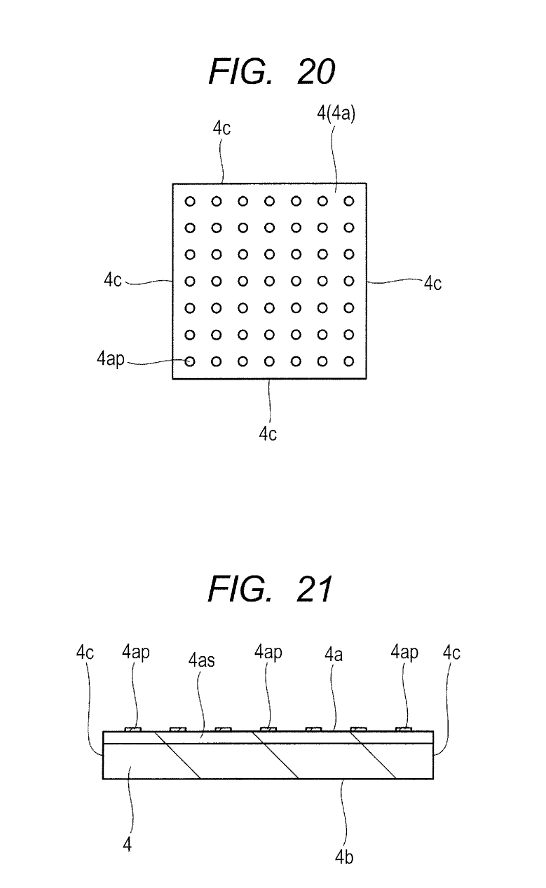

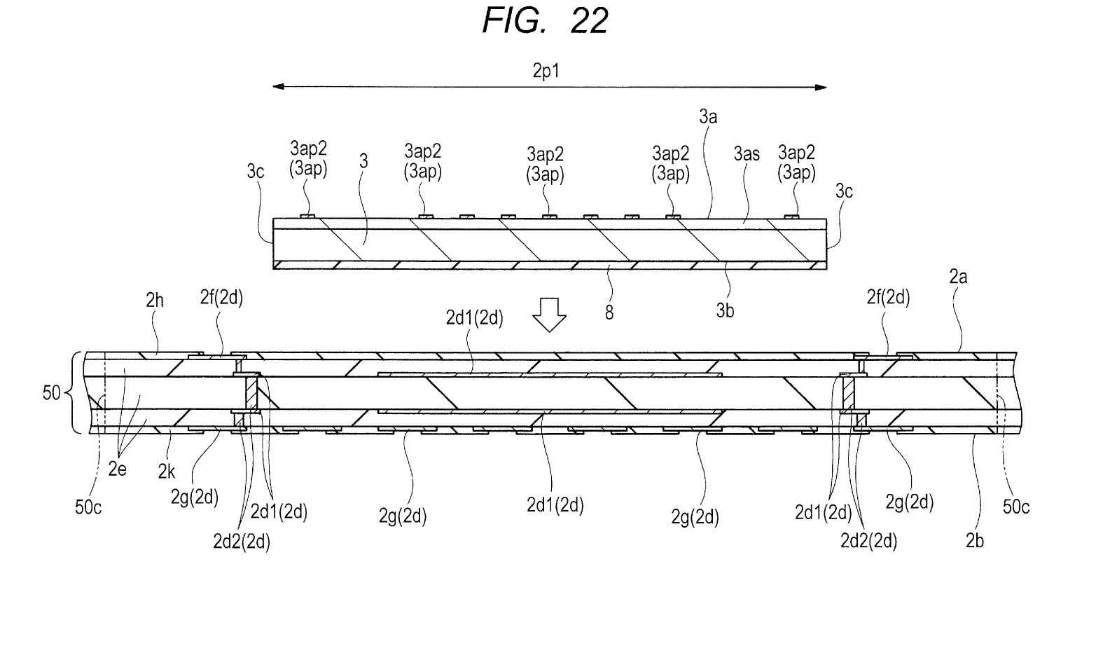

A manufacturing process of the semiconductor device of the present embodiment 1 will next be described. The semiconductor device 1 is manufactured along a flow shown in FIG. 15. FIG. 15 is a manufacturing process flow diagram showing a part of the manufacturing process of the semiconductor device of the embodiment 1. FIGS. 16 through 28 are diagrams showing manufacturing steps of the semiconductor device of the embodiment 1. FIGS. 16, 18 and 20 are plan diagrams showing the manufacturing steps of the semiconductor device of the embodiment 1. FIG. 17, FIG. 19 and FIGS. 21 through 28 are sectional diagrams showing the manufacturing steps of the semiconductor device of the embodiment 1. FIG. 16 is a plan diagram showing an overall structure of a wiring substrate 50. FIG. 17 is a sectional diagram of one device region 50a shown in FIG. 16. FIGS. 22 through 28 are sectional diagrams of the one device region 50a shown in FIG. 16. Further, FIG. 17, FIG. 19 and FIGS. 21 through 28 are sectional diagrams taken along line A-A of FIG. 3, i.e., sectional diagrams corresponding to the cross-section shown in FIG. 4. Incidentally, although the number of terminals is shown in FIGS. 16 through 28 with being reduced for the purpose of making it easier to see them, the number of the terminals (bonding leads 2f, lands 2g, solder balls 6 and surface electrodes 3ap and 4ap, etc.) is not limited to the form shown in FIGS. 16 through 28.

<Providing Step>

A wiring substrate (base material) 50, a peripheral circuit chip (semiconductor chip) 3 and a logic chip (semiconductor chip) 4 are first provided (Step S11 of FIG. 15).

In this Step S11, the wiring substrate 50 shown in FIGS. 16 and 17 is first provided.

As shown in FIG. 16, the wiring substrate 50 is provided with a plurality of device regions 50a. Each of the device regions 50a corresponds to the wiring substrate 2 shown in FIGS. 1 through 4. The wiring substrate 50 is a so-called multipiece substrate having a plurality of device regions 50a and dicing lines (dicing regions) 50c between the device regions 50a. Thus, the use of the multipiece substrate provided with the device regions 50a enables an improvement in manufacturing efficiency.

As shown in FIGS. 16 and 17, in each device region 50a, the wiring substrate 50 has an upper surface 2a, a lower surface 2b opposite to the upper surface 2a, and a plurality of wiring layers (four layers in the example shown in FIG. 17) that electrically connect the upper surface 2a side and the lower surface 2b side with each other. Each wiring layer includes a plurality of wirings 2d and insulating layers (core layers) 2e that insulate between the wirings 2d and between the adjacent wiring layers respectively. Further, the wirings 2d include wirings 2d1 formed over the upper or lower surface of the insulating layer 2e, and via wirings 2d2 that serve as interlayer conductive paths, which are formed so as to penetrate the insulating layers 2e in the thickness direction thereof.

Further, as shown in FIG. 16, the upper surface 2a of the wiring substrate 50 includes a chip mounting region (chip mounting part) 2p1 that is a schedule region to mount the peripheral circuit chip 3. The chip mounting region 2p1 exists in the central part of the device region 50a at the upper surface 2a. Incidentally, in FIG. 16, the outer periphery of the device region 50a, and the outer periphery of the chip mounting region 2p1 are indicated by two-dot chain lines respectively.

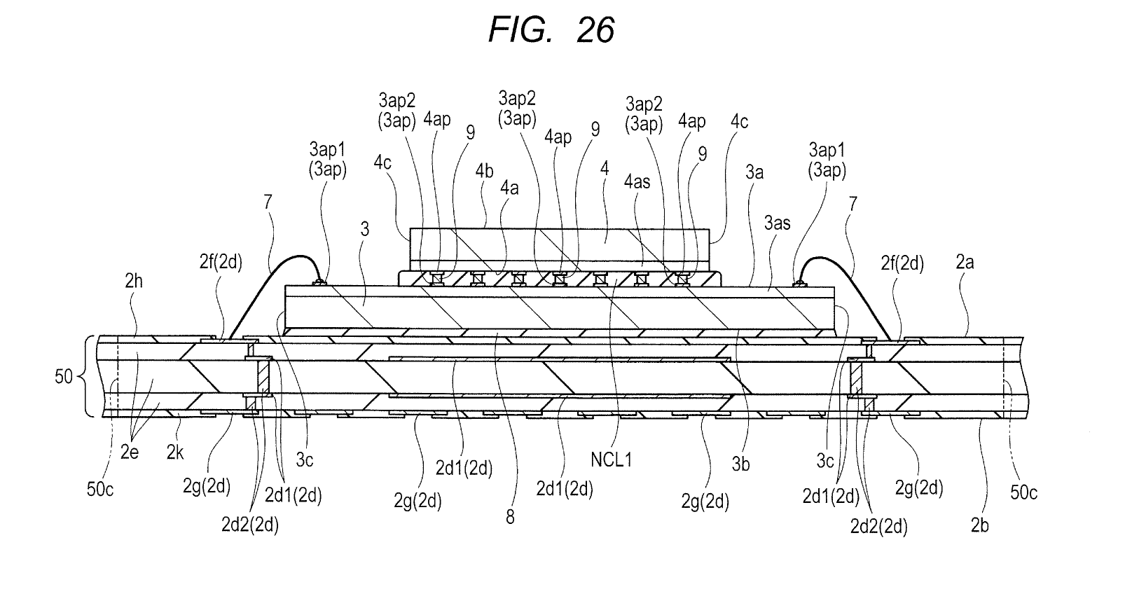

A plurality of bonding leads (terminals, chip mounting surface side terminals, electrodes) 2f are formed in the upper surface 2a of the wiring substrate 50. The bonding leads 2f are respectively terminals electrically connected via wires 7 with surface electrodes 3ap1 formed over a surface 3a of the peripheral circuit chip 3 as will be described using FIG. 26 to be described later. On the other hand, a plurality of lands 2g are formed in the lower surface 2b of the wiring substrate 50.

The upper surface 2a of the wiring substrate 50 is covered with an insulating film (solder resist film) 2h inclusive of the bonding leads 2f. Openings are formed in the insulating film 2h. At least some (parts bonded to the peripheral circuit chip 3, bonding regions) of the bonding leads 2f are exposed from the insulating film 2h at the openings. Further, the lower surface 2b of the wiring substrate 50 is covered with an insulting film (solder resist film) 2k inclusive of the lands 2g. Openings are formed in the insulating film 2k. At least some (parts bonded to the solder balls 6) of the lands 2g are exposed from the insulating film 2k at the openings.

Further, as shown in FIG. 17, the bonding leads 2f and the lands 2g are respectively electrically connected with each other via the wirings 2d. Conductor patterns such as the wirings 2d, the bonding leads 2f and the lands 2g are formed of, for example, a metal material with copper (Cu) as a main component. Further, the wirings 2d, the bonding leads 2f and the lands 2g can be formed by, for example, an electro-plating method. Furthermore, as shown in FIG. 17, the wiring substrate 50 having the four (four layers in FIG. 17) or more wiring layers can be formed by, for example, a build-up method.

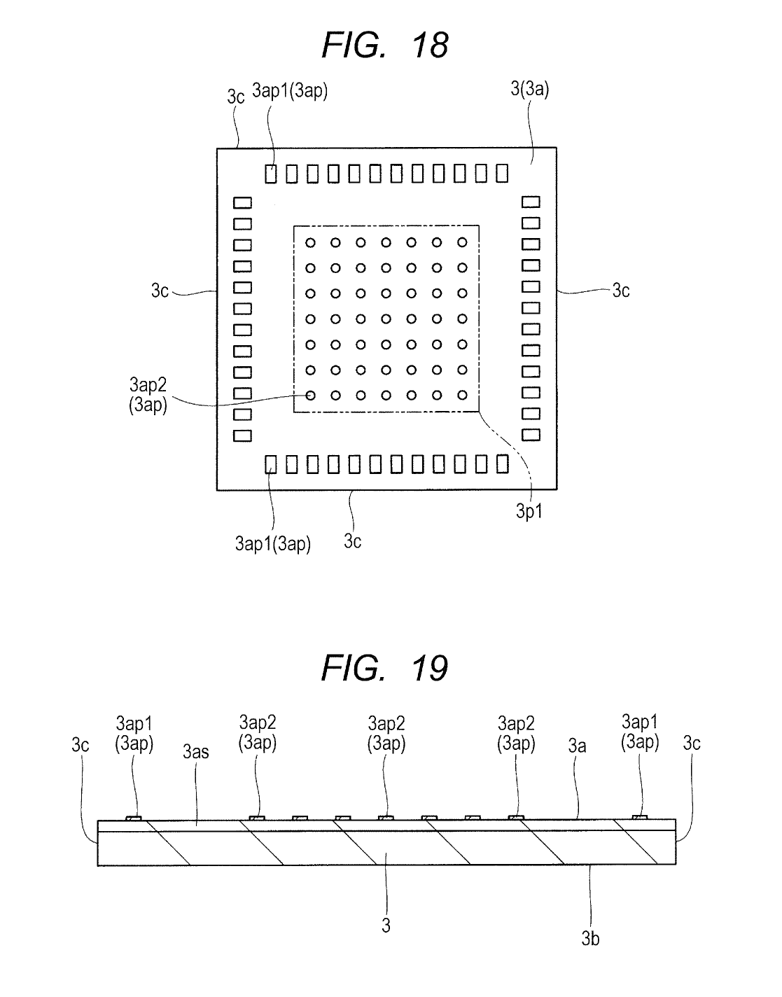

Further, in Step S11, such a peripheral circuit chip 3 as shown in FIGS. 18 and 19 is provided. As shown in FIGS. 18 and 19, the peripheral circuit chip 3 includes a surface (main surface, upper surface) 3a, aback surface (main surface, lower surface) 3b opposite to the surface 3a, and side surfaces 3c positioned between the surface 3a and the back surface 3b. The peripheral circuit chip 3 has an outer shape square in plan view as shown in FIGS. 18 and 19. Further, the peripheral circuit chip 3 has a plurality of surface electrodes (terminals, electrode pads, bonding pads) 3ap formed over the surface 3a. Of the surface electrodes 3ap, those electrically connected with the bonding leads 2f of the wiring substrate 50 are taken to be surface electrodes (electrode pads for base material) 3ap1, and those electrically connected with the surface electrodes 4ap of the logic chip 4 are taken to be surface electrodes (electrode pads for the chip) 3ap2. Further, a wiring layer 3as is formed on the surface 3a side of the peripheral circuit chip 3.

As described using FIG. 5, the peripheral circuit such as the CAN module PR1, the memory MM1 such as the SRAM, the power supply controller PC1, and the thermal diode (temperature sensor) TS1 are formed in the peripheral circuit chip 3.

Further, as shown in FIG. 18, the surface 3a of the peripheral circuit chip 3 includes a chip mounting region (chip mounting part) 3p1 that is a schedule region to mount the logic chip 4. In FIG. 18, the outer periphery of the chip mounting region 3p1 is indicated by a two-dot chain line. The chip mounting region 3p1 exists in the central part of the peripheral circuit chip 3 at the surface 3a. In the present embodiment 1, the logic chip 4 is mounted over the peripheral circuit chip 3 by a so-called facedown mounting method that faces the surface 4a side of the logic chip 4 to the surface 3a of the peripheral circuit chip 3. Thus, of the surface electrodes 3ap, the surface electrodes 3ap2 electrically connected with the surface electrodes 4ap of the logic chip 4 are formed inside the chip mounting region 3p1.

Further, in Step S11, such a logic chip 4 as shown in FIGS. 20 and 21 is provided. As shown in FIGS. 20 and 21, the logic chip 4 includes a surface (main surface, upper surface) 4a, a back surface (main surface, lower surface) 4b opposite to the surface 4a, and side surfaces 4c positioned between the surface 4a and the back surface 4b. The logic chip 4 has an outer shape square in plan view as shown in FIGS. 20 and 21. Further, the logic chip 4 has a plurality of surface electrodes (terminals, electrode pads, bonding pads) 4ap formed over the surface 4a. A wiring layer 4as is formed on the surface 4a side of the logic chip 4.

As described using FIG. 5, the CPU circuit (CPU) PU1, the local RAM controller (peripheral circuit) PR3 and the memory MM3 are formed in the logic chip 4.

Incidentally, in Step S11, a step of providing the wiring substrate 50, a step of providing the peripheral circuit chip 3, and a step of providing the logic chip 4 can be carried out even in any order. The logic chip 4 may be provided before execution of a step (Step S13) of mounting the logic chip 4. Thus, the logic chip 4 can be provided after Step S12 and before Step S13 without providing the logic chip 4 in Step S11.

<Peripheral Circuit Chip Mounting Step>

Next, the peripheral circuit chip (semiconductor chip) 3 is mounted over the wiring substrate (base material) 50 (Step S12 of FIG. 15). In this Step S12, the peripheral circuit chip 3 is mounted over the wiring substrate 50 such that the back surface 3b of the peripheral circuit chip 3 faces to the upper surface 2a of the wiring substrate 50.

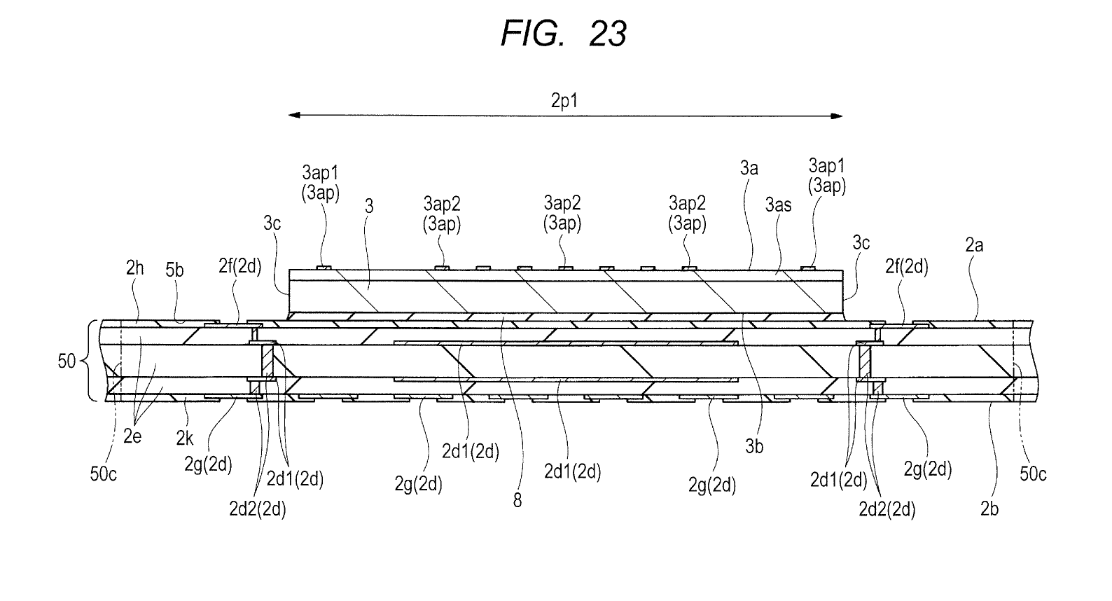

First, as shown in FIG. 22, a die bond material (adhesive material, past material) 8 that is an epoxy based thermosetting resin, for example, is applied onto the back surface 3b of the peripheral circuit chip 3. Further, the peripheral circuit chip 3 of which the back surface 3b is coated with the die bond material 8 is mounted over the wiring substrate 50. Described specifically, the peripheral circuit chip 3 is mounted over the chip mounting region 2p1 of the upper surface 2a of the wiring substrate 50 such that the back surface 3b faces to the upper surface 2a of the wiring substrate 50. At this time, the back surface 3b of the peripheral circuit chip 3 is bonded to the upper surface 2a of the wiring substrate 50 through the die bond material 8. For example, heat treatment is then applied after its bonding to cure the die bond material 8. Thus, as shown in FIG. 23, the peripheral circuit chip 3 is fixed onto the wiring substrate 50 through the die bond material 8.

<Logic Chip Mounting Step>

The logic chip (semiconductor chip) 4 is mounted over the peripheral circuit chip (semiconductor chip) 3 (Step S13 of FIG. 15). In this Step S13, the logic chip 4 is mounted over the peripheral circuit chip 3 by the so-called facedown mounting method such that the surface 4a of the logic chip 4 faces to the surface 3a of the peripheral circuit chip 3. Further, according to Step S13, the logic chip 4 and the peripheral circuit chip 3 are electrically connected with each other. Described specifically, the surface electrodes 4ap formed over the surface 4a of the logic chip 4, and the surface electrodes 3ap2 being the electrode pads for a semiconductor chip, of the surface electrodes 3ap formed over the surface 3a of the peripheral circuit chip 3 are respectively electrically connected through projection electrodes (conductive members, columnar electrodes, bumps) 9.

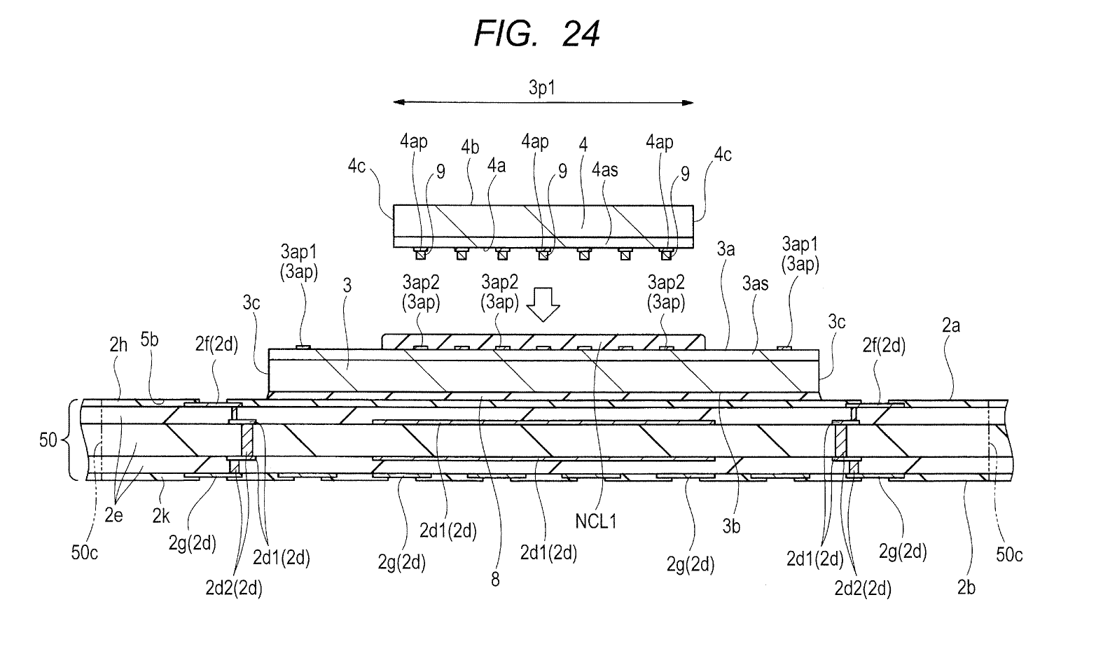

First, as shown in FIG. 24, the projection electrodes 9 are formed over the surfaces of the surface electrodes 4ap formed in the logic chip 4. For example, a solder film (not shown) is formed over the surfaces of the projection electrodes 9. Incidentally, a solder film (not shown) corresponding to a bonding material for electrically connecting with the projection electrodes 9 shown in FIG. 24 may be formed at a bonding portion of each surface electrode 3ap2 formed in the peripheral circuit chip 3.

When the logic chip 4 is mounted over the peripheral circuit chip 3 by the facedown mounting method (flip chip connection method), for example, a method (post-injection method) of sealing between the logic chip 4 and the peripheral circuit chip 3 with a resin after the logic chip 4 and the peripheral circuit chip 3 are electrically connected with each other may be conducted. In this case, the resin is supplied from a nozzle arranged near a space between the logic chip 4 and the peripheral circuit chip 3 and embedded into the space using a capillary phenomenon.

On the other hand, in the example described in the present embodiment 1, before the logic chip 4 is mounted over the peripheral circuit chip 3, the logic chip 4 is mounted thereover by a method (pre-application method) of arranging an adhesive material NCL1 in the chip mounting region 3p1 and pressing the logic chip 4 thereagainst from above the adhesive material NCL1 to electrically connect with the peripheral circuit chip 3. The adhesive material NCL1 is in a soft state before the curing as long as it is before execution of the heat treatment. Therefore, when the logic chip 4 is arranged over the adhesive material NCL1, the projection electrodes 9 are embedded into the adhesive material NCL1.

In the case of the above post-injection method, a processing time (time taken to inject the resin) for one device region 50a becomes long because the resin is filled into the space using the capillary phenomenon. On the other hand, in the case of the above pre-application method, the adhesive material NCL1 has already been embedded between the logic chip 4 and the peripheral circuit chip 3 when the tip (solder film formed at the tip of each projection electrode 9) of each projection electrode 9 of the logic chip 4 and its corresponding surface electrode 3ap2 of the peripheral circuit chip 3 are brought into contact with each other. Thus, as compared with the above post-injection method, the present pre-application method is preferable in that the processing time for one device region 50a is shortened and the manufacturing efficiency can be improved.

However, as a modification for the present embodiment 1, the post-injection method can be applied with the order of the step of arranging the adhesive material NCL1 and the step of arranging the logic chip 4 being reserved. Since the difference in processing time becomes small when, for example, product forming regions to be formed in bloc are small, it is possible to suppress deterioration in manufacturing efficiency even when the post-injection method is used.

Further, the adhesive material NCL1 used in the pre-application method is comprised of a material (e.g., resin material) having an insulation property (non-conductivity). In this case, the adhesive material NCL1 is arranged at the bonding portions of the tips of the projection electrodes 9 of the logic chip 4 and the surface electrodes 3ap2 of the peripheral circuit chip 3 to thereby make it possible to electrically insulate between a plurality of conductive members (surface electrodes 4ap, projection electrodes 9 and surface electrodes 3ap2) provided at the bonding portions.

Further, the adhesive material NCL1 is comprised of a resin material of which the hardness is made to be hard (high) by applying energy thereto. In the present embodiment 1, it includes, for example, a thermosetting resin. The adhesive material NCL1 before its curing is soft and deformed by pressing the logic chip 4 thereagainst.

Further, the adhesive material NCL1 before the curing is roughly divided into two types shown below from a difference in handling method. One of them is called NOP (Non-conductive paste) and comprised of a paste-like resin (insulating material paste). In this case, the paste-like resin is applied to the chip mounting region 3p1 from an unillustrated nozzle. The other thereof is called NCF (Non-conductive film) and comprised of a resin (insulating material film) formed in a film shape in advance. In this case, the resin formed in the film shape is conveyed and attached to the chip mounting region 3p1 as keeping a film state. Since a bonding step is unnecessary like the non-conductive film (NCF) when the non-conductive paste (NCP) is used, it is possible to reduce stress applied to the semiconductor chip or the like as compared with the case where the non-conductive film is used. On the other hand, since the non-conductive film (NCF) has a shape that is apt to be held as compared with the non-conductive paste (NCP) when the non-conductive film (NCF) is used, it is easy to control the range in which the adhesive material NCL1 is arranged, and its thickness.

In the example shown in FIG. 24, there is shown an example in which the adhesive material NCL1 corresponding to the non-conductive film (NCF) is arranged over the chip mounting region 3p1 (refer to FIG. 18) and bonded to the upper surface 3a of the peripheral circuit chip 3 in close contact therewith. However, though illustration is omitted, the non-conductive paste (NCP) can also be used as a modification.

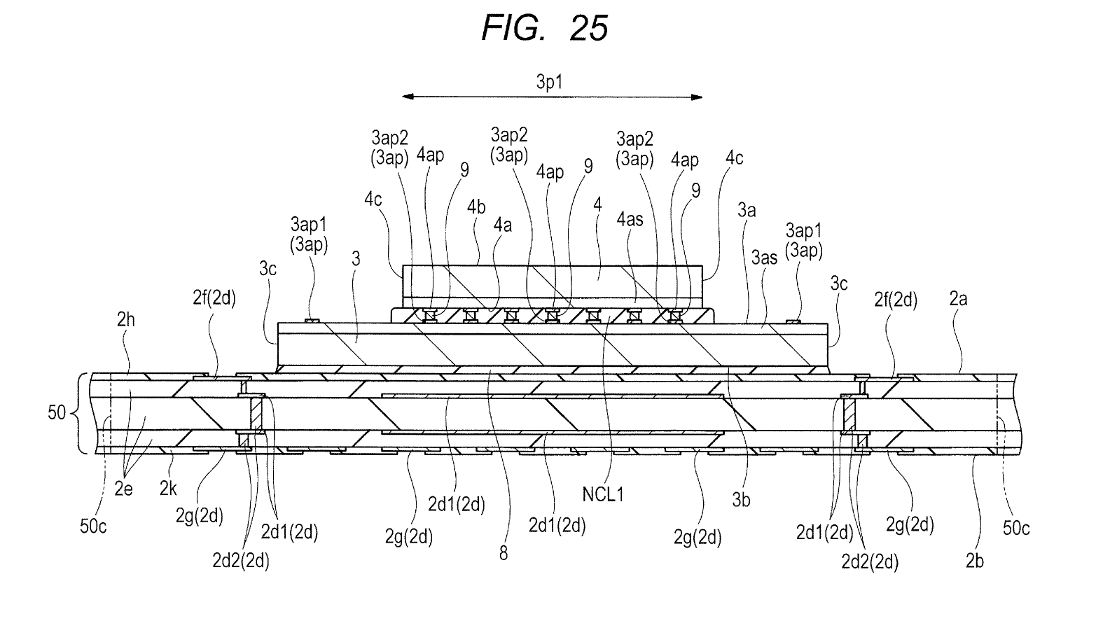

Next, as shown in FIGS. 24 and 25, the logic chip 4 is arranged over the chip mounting region (chip mounting part) 3p1 (refer to FIG. 18) of the peripheral circuit chip 3. As described above, each of the surface electrodes 4ap of the logic chip 4 includes the projection electrode 9. A solder film (not shown) is formed at the tip of the projection electrode 9. Though illustration is omitted, a solder film as a bonding material can also be formed even over the surface electrodes 3ap2 of the peripheral circuit chip 3. In this case, the logic chip 4 is arranged over the peripheral circuit chip 3 such that the surface electrodes 3ap2 of the peripheral circuit chip 3 respectively face to the surface electrodes 4ap of the logic chip 4.

Next, an unillustrated heating jig is pressed against the back surface 4b side of the logic chip 4, and the logic chip 4 is pressed to the peripheral circuit chip 3. Since the adhesive material NCL1 is in a soft state before its curing before execution of the heat treatment, the adhesive material NCL1 shown in FIG. 25 is pushed and widened between the surface 3a of the peripheral circuit chip 3 and the surface 4a of the logic chip 4 when the logic chip 4 is pushed by the heating jig. Further, the solder film formed at the tip of each of the projection electrodes 9 formed over the surface electrodes 4ap of the logic chip 4 is brought into contact with the surface electrode 3ap2 of the peripheral circuit chip 3.

Next, the logic chip 4 and the peripheral circuit chip 3 are heated by the heating jig in the state in which the logic chip 4 has been pressed against the unillustrated heating jig. At the bonding portion of the logic chip 4 and the peripheral circuit chip 3, the solder film formed at the tip of each projection electrode 9 is fused to be bonded to each of the surface electrodes 3ap2 of the peripheral circuit chip 3. Thus, as shown in FIG. 25, the surface electrodes 4ap of the logic chip 4 and the surface electrodes 3ap2 of the peripheral circuit chip 3 are respectively electrically connected through the projection electrodes 9 (conductive members, columnar electrodes, bumps).

Further, the adhesive material NCL1 is cured by heating the adhesive material NCL1. It is thus possible to obtain the adhesive material NCL1 cured in the state of having sealed the space between the logic chip 4 and the peripheral circuit chip 3. That is, the adhesive material NCL1 is a sealing member that seals between the peripheral circuit chip 3 and the logic chip 4.

<Peripheral Circuit Chip Connection Step>

Next, the wiring substrate 50 and the peripheral circuit chip 3 are electrically connected with each other (Step S14 of FIG. 15). In this Step S14, as shown in FIG. 26, a plurality of surface electrodes 3ap1 corresponding to electrode pads for the base material, of the surface electrodes 3ap of the peripheral circuit chip 3, and a plurality of bonding leads 2f of the wiring substrate 50 are connected using wires (conductive members) 7 (wire bonding).

Thus, the wiring substrate 50 and the peripheral circuit chip 3 are electrically connected with each other, and the wiring substrate 50 and the logic chip 4 are electrically connected with each other through the peripheral circuit chip 3.

<Sealing Step>

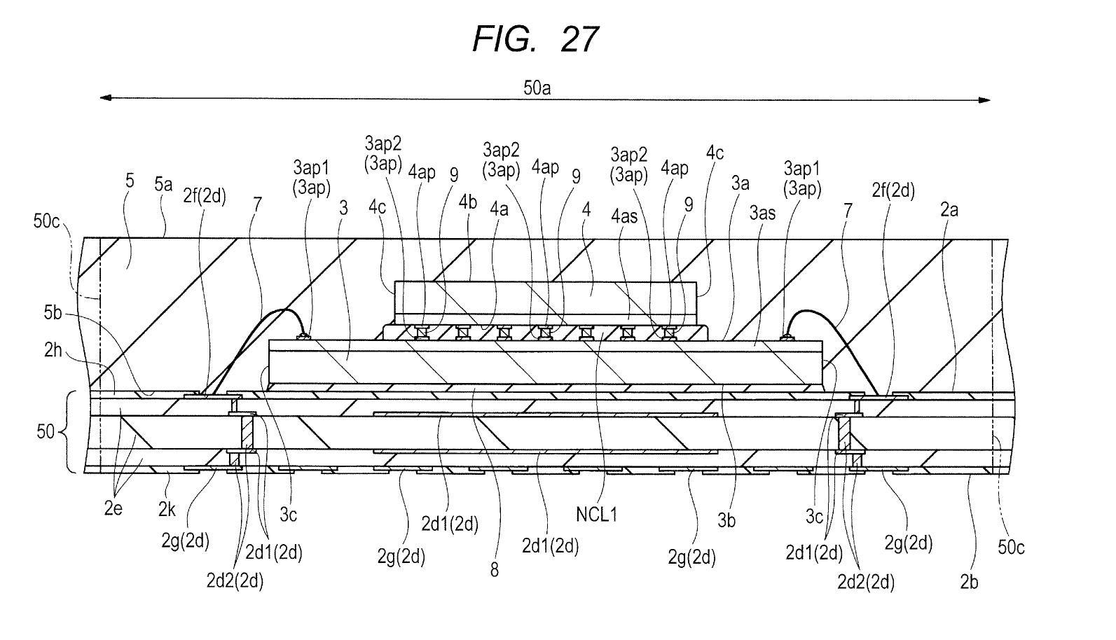

Next, the peripheral circuit chip and the logic chip are sealed (Step S15 of FIG. 15). In this Step S15, as shown in FIG. 27, the upper surface 2a of the wiring substrate 50, the peripheral circuit chip 3 and the logic chip 4 are sealed with a resin to form a sealing body 5.

In the present embodiment 1, the sealing body 5 can be formed by a so-called transfer mold method of press-fitting a heated and softened resin into an unillustrated molding die, for example, and thereafter thermosetting the resin. Since the sealing body 5 formed by the transfer mold method is high in durability as compared with one obtained by curing a liquid resin, it is suitable as a protection member. Further, for example, filler particles such as silica (silicon dioxide: SiO₂) particles, etc. are mixed in a thermosetting resin, thereby making it possible to improve the function of the sealing body 5, like such as enabling an improvement in resistance to warpage and deformation, for example.

<Ball Mount Step>

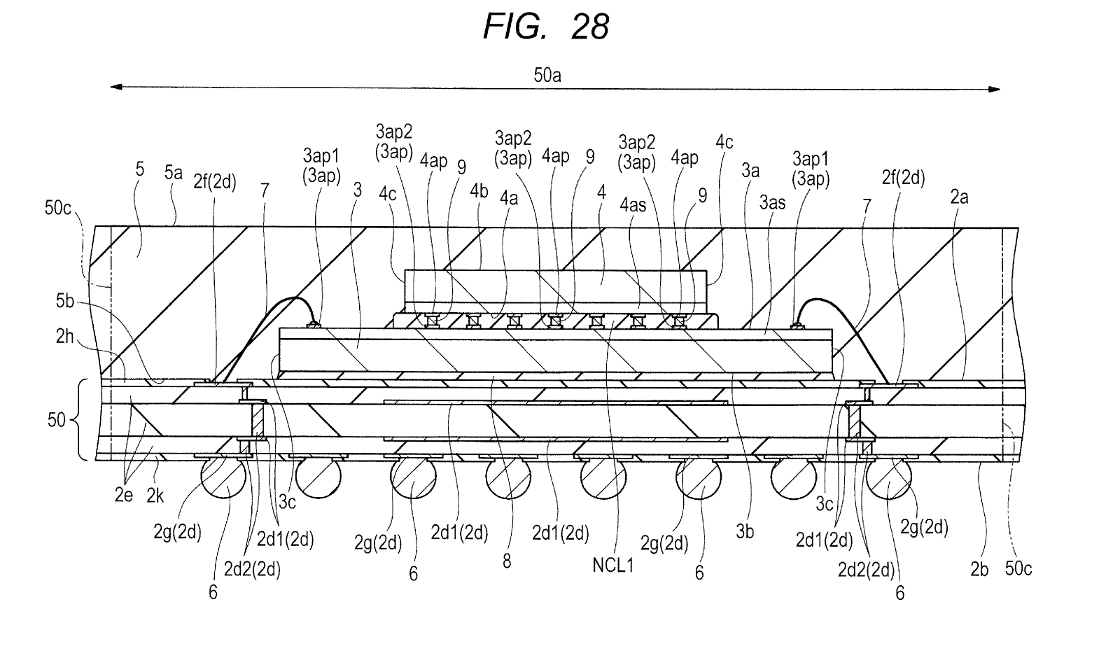

Next, a ball mount step is performed (Step S16 of FIG. 15). In this Step S16, as shown in FIG. 28, a plurality of solder balls 6 that serve as external terminals are bonded to their corresponding lands 2g formed in the lower surface 2b of the wiring substrate 50.

For example, after the wiring substrate 50 is inverted upside down, the solder balls 6 are respectively arranged over the lands 2g exposed at the lower surface 2b of the wiring substrate 50 and thereafter heated to thereby bond the solder balls 6 to the lands 2g. Thus, the solder balls 6 are electrically connected with the peripheral circuit chip 3 and the logic chip 4 through the wiring substrate 50.

The technology described in the present embodiment 1 is however not applied only to a so-called BGA (Ball grid array) type semiconductor device in which the solder balls 6 are bonded in an array form. For example, as a modification for the present embodiment 1, the technology can be applied to a so-called LGA (Land grid array) type semiconductor device shipped in a state in which the lands 2g are exposed without forming the solder balls 6, or solder paste is applied onto the land 2g thinner than the solder balls 6. The ball mount step can be omitted in the case of the LGA type semiconductor device.

<Dicing Step>

Next, a dicing step is performed (Step S17 of FIG. 15). In this Step S17, the wiring substrate 50 shown in FIG. 28 is divided for every device region 50a (refer to FIGS. 16 and 17). Described specifically, the wiring substrate 50 and the sealing body 5 are cut along the dicing lines (dicing regions) 50c to obtain a plurality of individualized semiconductor devices 1 (refer to FIG. 4).

Although the cutting method used upon execution of this dicing step is not limited in particular, cutting work is performed to the wiring substrate 50 and the sealing body 5 bonded and fixed to a tape material (dicing tape) from the lower surface 2b side of the wiring substrate 50 to enable them to be cut using, for example, a dicing blade (rotating blade).

However, the technology described in the present embodiment 1 is not applied only to the case where the wiring substrate 50 as the multipiece substrate equipped with the device regions 50a is used. The technology can be applied to, for example, the semiconductor device in which the peripheral circuit chip 3 and the logic chip 4 are laminated over the wiring substrate 2 (refer to FIG. 4) equivalent to one semiconductor device. In this case, the dicing step can be omitted.

According to the above individual steps, the semiconductor device 1 described using FIGS. 1 through 12 is obtained. Thereafter, necessary inspections and tests such as an external inspection, an electric test, etc. are performed on the semiconductor device, which is followed by being shipped or mounted to an unillustrated mounting substrate.

<Modifications of Manufacturing Method of Semiconductor Device>

Incidentally, as modifications of the manufacturing method of the semiconductor device of the present embodiment 1, various changes shown below are possible.

Description has been made about that in the logic chip mounting step (Step S13), the logic chip 4 is mounted over the peripheral circuit chip 3 through the film-like adhesive material, i.e., the adhesive material NCL1 as the insulating material film (NCF). As mentioned above in the logic chip mounting step (Step S13), however, the logic chip 4 may be mounted over the peripheral circuit chip 3 through the paste-like adhesive material, i.e., the adhesive material NCL1 as the insulating material paste (NCP) instead of the film-like adhesive material.

Further, voids (cavities) are apt to occur in the adhesive material NCL1 between the peripheral circuit chip 3 and the logic chip 4. Therefore, in the logic chip mounting step (Step S13), the projection electrodes 9 and the surface electrodes 3ap2 are only bonded to each other, and the bonding portion between the peripheral circuit chip 3 and the logic chip 4 including the projection electrodes 9 and the surface electrodes 3ap2 may not be sealed (protected) with the adhesive material NCL1.

Description has been made about that in the peripheral circuit chip connection step (Step S14), the logic chip 4 is mounted over the peripheral circuit chip 3, and the peripheral circuit chip 3 and the logic chip 4 are flip-chip bonded, followed by electrically connecting between the wiring substrate 50 and the peripheral circuit chip 3 via the wires 7. However, after the peripheral circuit chip 3 is mounted over the wiring substrate 50, the wiring substrate 50 and the peripheral circuit chip 3 may electrically be connected via the wires 7 before the logic chip 4 is mounted over the peripheral circuit chip 3.

Description has been made about the method (pre-application method) in which in the logic chip mounting step (Step S13), the adhesive material NCL1 is arranged in the chip mounting region 3p1 before the logic chip 4 is mounted over the peripheral circuit chip 3, and the logic chip 4 is pressed thereagainst from above the adhesive material NCL1 to electrically connect with the peripheral circuit chip 3. However, as mentioned above in the logic chip mounting step (Step S13), the method (post-injection method) of electrically connecting the logic chip 4 and the peripheral circuit chip 3 with each other and thereafter sealing between the logic chip 4 and the peripheral circuit chip 3 with the resin may be conducted. Alternatively, the resin that seals between the logic chip 4 and the peripheral circuit chip 3 may be the same resin as the resin that forms the sealing body 5 by sealing between the logic chip 4 and the peripheral circuit chip 3 with the resin upon forming the sealing body 5 without sealing between the logic chip 4 and the peripheral circuit chip 3 with the resin before forming the sealing body 5.

The following may be taken instead of the providing step (Step S11) to the logic chip mounting step (Step S13). That is, before dividing the peripheral circuit chips 3 into individual pieces, a wafer formed with portions taken to be the peripheral circuit chips 3 every device region is used. The logic chip 4 is then mounted in the chip mounting region (chip mounting part) 3p1 in each device region, followed by being flip-chip bonded. After that, the wafer may be diced to be divided for every device region. Described specifically, the wafer is cut along the dicing lines and made into individual pierces. Thus, a plurality of the peripheral circuit chips 3 with the logic chips 4 being flip-chip bonded with their surfaces 3a may be obtained. The peripheral circuit chips 3 with the logic chips 4 being flip-chip bonded with the surfaces 3a thereof may be mounted over the upper surface 2a of the wiring substrate 50 in bloc.

### Embodiment 2

The above embodiment 1 has described the embodiment in which the peripheral circuit chip is connected with the wiring substrate by wire bonding, as the embodiment in which the peripheral circuit chip is connected with the wiring substrate. In the present embodiment 2, description will be made about an embodiment in which a peripheral circuit chip is flip-chip bonded with a wiring substrate. Incidentally, the present embodiment 2 will be described centering on differences from the already-described embodiment 1, and their dual description will be omitted in principle.

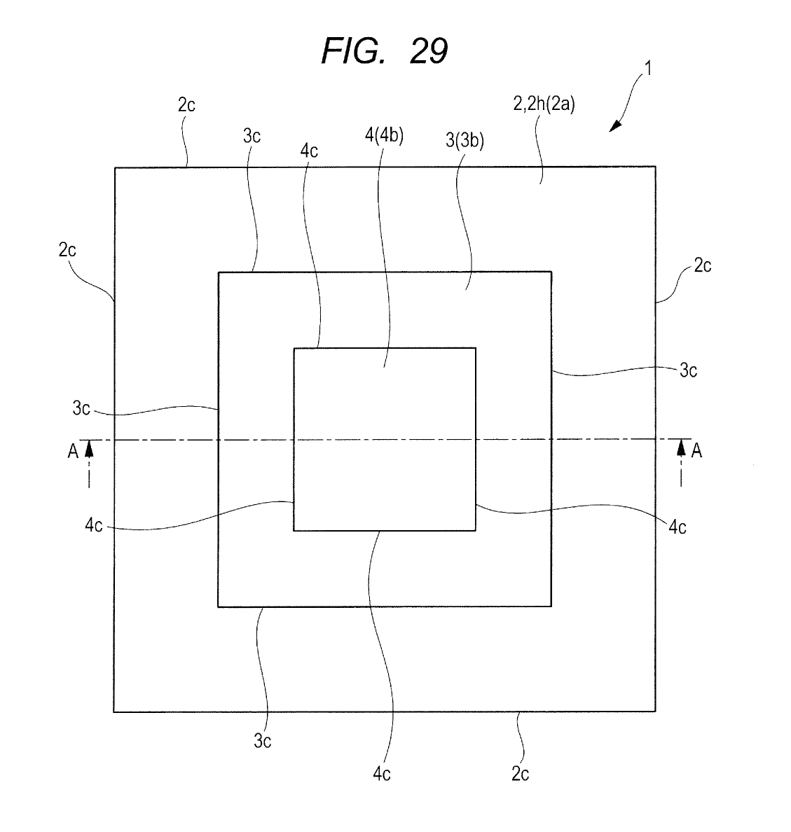

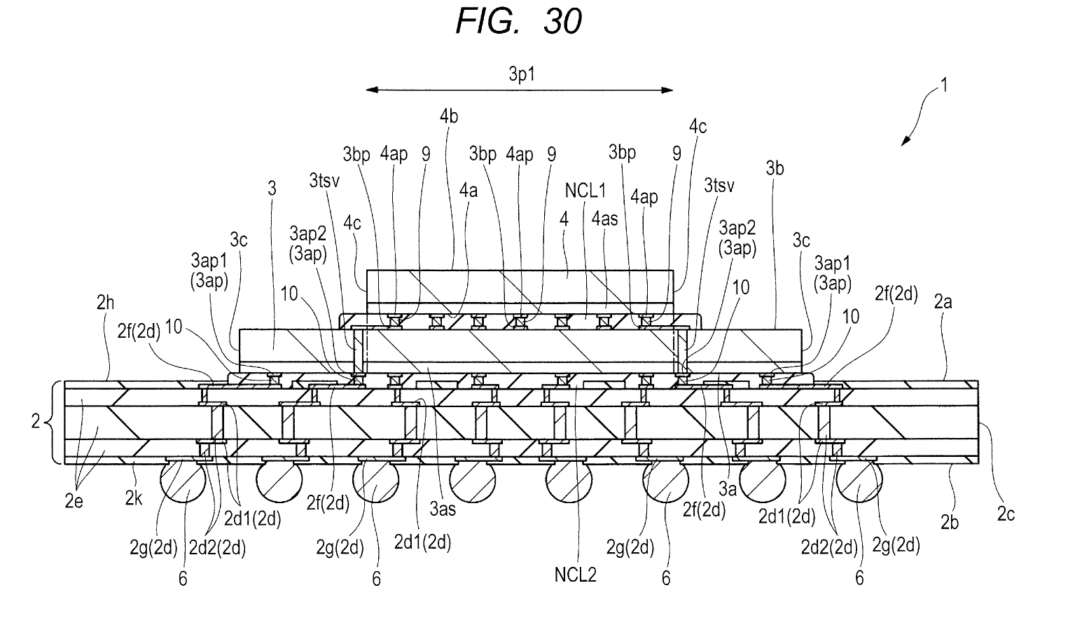

FIG. 29 is a plan diagram of a semiconductor device of the embodiment 2. FIG. 30 is a sectional diagram of the semiconductor device of the embodiment 2. FIG. 30 is a sectional diagram taken along line A-A of FIG. 29. Incidentally, though the number of terminals is shown in FIGS. 29 and 30 with being reduced for the purpose of making it easier to see them, the number of the terminals (bonding leads 2f, lands 2g, solder balls 6 and surface electrodes 3ap and 4ap, etc.) is not limited to the form shown in FIGS. 29 and 30.

The semiconductor device (semiconductor package) 1 of the present embodiment 2 is provided with a wiring substrate (base material) 2, and a peripheral circuit chip (semiconductor chip) 3 and a logic chip (semiconductor chip) 4 mounted over the wiring substrate 2. Incidentally, in the present embodiment 2, a sealing body for sealing the peripheral circuit chip 3 and the logic chip 4 needs not to be provided because all of the wiring substrate 2, the peripheral circuit chip 3 and the logic chip 4 are not connected by wires.

The wiring substrate 2 can be set as similar to the wiring substrate 2 of the embodiment 1 except that bonding leads 2f and wirings 2d are different in position in plan view.

In the present embodiment 2, the peripheral circuit chip 3 is mounted over the wiring substrate 2, and the logic chip 4 is mounted over the peripheral circuit chip 3. That is, the logic chip 4 is electrically connected with the wiring substrate 2 through the peripheral circuit chip 3.

In the present embodiment 2, the peripheral circuit chip 3 is mounted over the wiring substrate 2 such that a surface 3a of the peripheral circuit chip 3 faces to an upper surface 2a of the wiring substrate 2. The peripheral circuit chip 3 and the wiring substrate 2 are flip-chip bonded. Further, the logic chip 4 is mounted over the peripheral circuit chip 3 such that a surface 4a of the logic chip 4 faces to a back surface 3b of the peripheral circuit chip 3. The logic chip 4 and the peripheral circuit chip 3 are flip-chip bonded.

In the present embodiment 2, as a method of connecting the logic chip 4 with the wiring substrate 2, a technology is applied which forms through electrodes penetrating the peripheral circuit chip 3 in its thickness direction, and connects circuits or wirings formed in the surface of the logic chip 4, and the wiring substrate 2 through the through electrodes. The peripheral circuit chip 3 has a plurality of surface electrodes (terminals, electrode pads, bonding pads) 3ap formed over the surface 3a, and a plurality of back surface electrodes (terminals, electrode pads, bonding pads) 3bp formed over the back surface 3b. Further, the peripheral circuit chip 3 has a plurality of through electrodes 3tsv which are formed so as to penetrate from one of the surface 3a and the back surface 3b to the other thereof and electrically connect the surface electrodes 3ap and the back surface electrodes 3bp. Except for the above differences, the peripheral circuit chip 3 can be made similar to the peripheral circuit chip 3 of the embodiment 1.

A plurality of surface electrodes 3ap1 as electrode pads for the base material in the surface electrodes 3ap of the peripheral circuit chip 3, and a plurality of bonding leads 2f of the wiring substrate 2 are respectively electrically connected with each other through a plurality of projection electrodes (conductive members, columnar electrodes, bumps) 10. On the other hand, the back surface electrodes 3bp of the peripheral circuit chip 3 are respectively electrically connected with a plurality of surface electrodes 3ap2 as electrode pads for the chip in the surface electrodes 3ap of the peripheral circuit chip 3 through the through electrodes 3tsv. A plurality of surface electrodes 4ap of the logic chip 4 and the back surface electrodes 3bp of the peripheral circuit chip 3 are respectively electrically connected with each other through a plurality of projection electrodes 9. A flip-chip bonding using the projection electrodes 9 and the projection electrodes 10 can be made similar to the flip-chip bonding using the projection electrodes 9 in the embodiment 1.

An adhesive material (sealing member, resin) NCL2 is arranged between the wiring substrate 2 and the peripheral circuit chip 3. The adhesive material NCL2 is arranged so as to block space between the upper surface 2a of the wiring substrate 2 and the surface 3a of the peripheral circuit chip 3. The adhesive material NCL2 is an adhesive material that bonds and fixes the peripheral circuit chip 3 onto the wiring substrate 2. An adhesive material (sealing member, resin) NCL1 provided between the peripheral circuit chip 3 and the logic chip 4 and the adhesive material NCL2 can be made similar to the adhesive material (sealing member, resin) NCL1 provided between the peripheral circuit chip 3 and the logic chip 4 in the embodiment 1.

The logic chip 4 can be made similar to the logic chip 4 of the embodiment 1. Further, the back surface electrodes 3bp of the peripheral circuit chip 3 and the surface electrodes 4ap of the logic chip 4 are connected by flip-chip bonding, for example, as with the embodiment 1.

Preferably, the through electrodes 3tsv are formed outside the region in which the power supply control unit CU1 (refer to FIG. 5) is formed. As described above, in terms of the fact that the thermal diode (temperature sensor) TS1 senses (detects) the temperature of the logic chip 4 accurately, the power supply control unit CU1 is formed inside a chip mounting region (chip mounting part) 3p1 that is a schedule region to mount the logic chip 4, of the back surface 3b of the peripheral circuit chip 3. Thus, preferably, the through electrodes 3tsv are formed outside the chip mounting region (chip mounting part) 3p1 that is the schedule region to mount the logic chip 4 as shown in FIG. 30.

When the through electrodes 3tsv are formed near each MISFET included in the power supply controller PC1 (refer to FIG. 5) of the power supply control unit CU1, a malfunction is likely to occur electrically, for example, like such as a case where the voltage is applied to the MISFET as noise, or a leak current flows in the MISFET. On the other hand, each through electrode 3tsv is formed outside the region in which the power supply control unit CU1 is formed, thereby making it possible to form the through electrode 3tsv in a position away from the MISFET included in the power supply controller PC1 of the power supply control unit CU1. Thus, for example, the voltage as noise can be prevented or suppressed from being applied to the MISFET, and the leak current can be prevented or suppressed from flowing in the MISFET.

In the present embodiment 2, the wiring substrate 2 and the peripheral circuit chip 3 are electrically connected by flip-chip bonding instead of connection by wire. Therefore, the wiring substrate 2 and the peripheral circuit chip 3 can be connected with low resistance as compared with the wire-based connection, thus making it possible to further improve the electrical characteristics of the semiconductor device.

Since the semiconductor device of the present embodiment 2 is similar to the semiconductor device of the embodiment 1 except for the above differences, their redundant description will be omitted.

The manufacturing method of the semiconductor device of the present embodiment 2 is different from the manufacturing method of the semiconductor device of the embodiment 1 in that in the peripheral circuit chip mounting step of the manufacturing method of the semiconductor device of the embodiment 1, the peripheral circuit chip 3 is mounted over the wiring substrate 50 (refer to FIG. 17) such that the surface 3a of the peripheral circuit chip 3 faces to the upper surface 2a of the wiring substrate 2, and is flip-chip bonded therewith. Since the manufacturing method of the semiconductor device described in the embodiment 1 can be applied except for the above difference, their dual description will be omitted.

As with the embodiment 1 even in the semiconductor device of the present embodiment 2, it has an advantageous effect similar to the semiconductor device of the embodiment 1 because the semiconductor chip is divided into the peripheral circuit chip 3 and the logic chip 4. In addition to it, since the wiring substrate 2 and the peripheral circuit chip 3 are electrically connected by the flip-chip bonding as described above, the wiring substrate 2 and the peripheral circuit chip 3 can be connected with low resistance, thereby making it possible to further improve the electrical characteristics of the semiconductor device.

### Embodiment 3

The above embodiment 2 has described the embodiment in which the logic chip is arranged and laminated over the peripheral circuit chip, as the embodiment in which the peripheral circuit chip and the logic chip are laminated over the wiring substrate. In the present embodiment 3, description will be made about an embodiment in which a peripheral circuit chip is laminated over a logic chip. Incidentally, the present embodiment 3 will be described centering on differences from the already-described embodiments 2 and 1, and their redundant description will be omitted in principle.

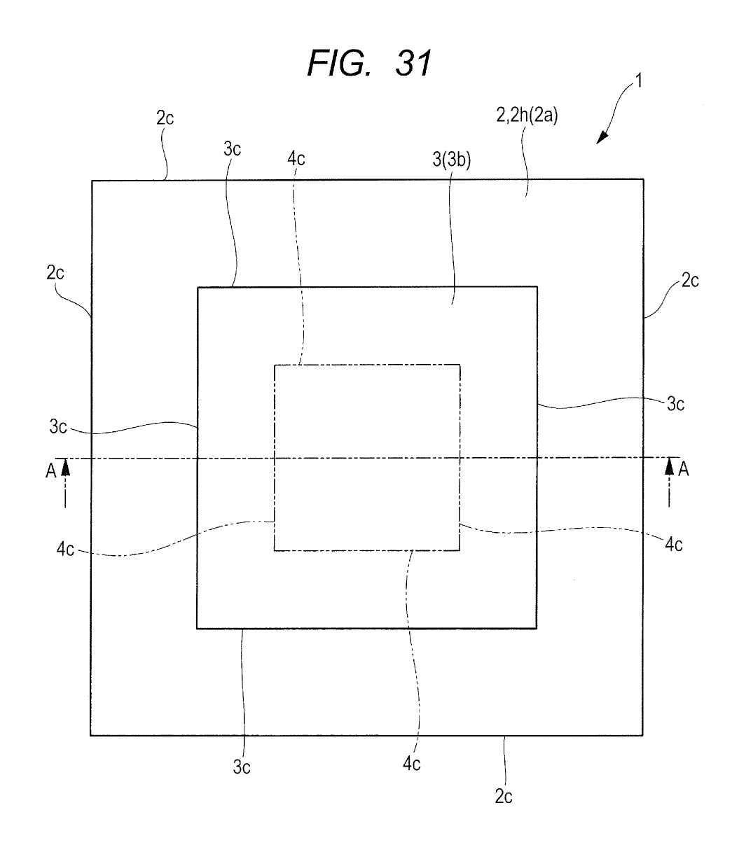

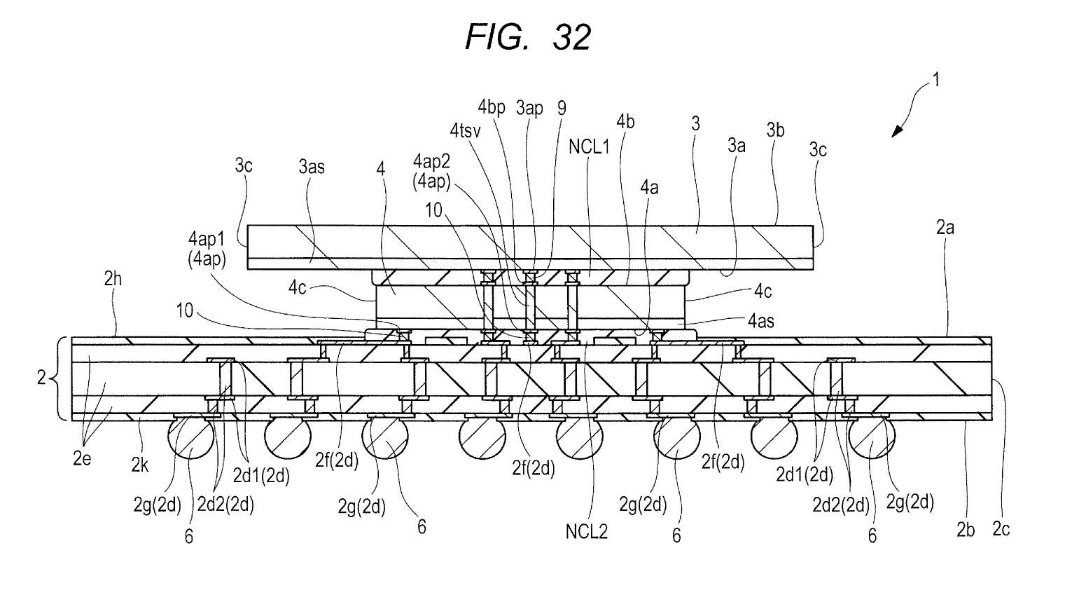

FIG. 31 is a plan diagram of a semiconductor device of the embodiment 3. FIG. 32 is a sectional diagram of the semiconductor device of the embodiment 3. FIG. 32 is a sectional diagram taken along line A-A of FIG. 31. Incidentally, though the number of terminals is shown in FIGS. 31 and 32 with being reduced for the purpose of making it easier to see them, the number of the terminals (bonding leads 2f, lands 2g, solder balls 6 and surface electrodes 3ap and 4ap, etc.) is not limited to the form shown in FIGS. 31 and 32.

The semiconductor device (semiconductor package) 1 of the present embodiment 3 is provided with a wiring substrate (base material) 2, and a peripheral circuit chip (semiconductor chip) 3 and a logic chip (semiconductor chip) 4 mounted over the wiring substrate 2. Incidentally, in the present embodiment 3, a sealing body for sealing the peripheral circuit chip 3 and the logic chip 4 needs not to be provided because all of the wiring substrate 2, the peripheral circuit chip 3 and the logic chip 4 are not connected by wires.

The wiring substrate 2 can be set as similar to the wiring substrate 2 of the embodiment 1 except that bonding leads 2f and wirings 2d are different in position in plan view.

In the present embodiment 3, the logic chip 4 is mounted over the wiring substrate 2, and the peripheral circuit chip 3 is mounted over the logic chip 4. That is, the peripheral circuit chip 3 is electrically connected with the wiring substrate 2 through the logic chip 4.

In the present embodiment 3, the logic chip 4 is mounted over the wiring substrate 2 such that a surface 4a of the logic chip 4 faces to an upper surface 2a of the wiring substrate 2. The logic chip 4 and the wiring substrate 2 are flip-chip bonded. Further, the peripheral circuit chip 3 is mounted over the logic chip 4 such that a surface 3a of the peripheral circuit chip 3 faces to a back surface 4b of the logic chip 4. The logic chip 4 and the peripheral circuit chip 3 are flip-chip bonded.

In the present embodiment 3, as a method of connecting the peripheral circuit chip 3 with the wiring substrate 2, a technology is applied which forms through electrodes penetrating the logic chip 4 in its thickness direction, and connects circuits or wirings formed in the surface of the peripheral circuit chip 3, and the wiring substrate 2 via the through electrodes. The logic chip 4 has a plurality of surface electrodes (terminals, electrode pads, bonding pads) 4ap formed over the surface 4a, and a plurality of back surface electrodes (terminals, electrode pads, bonding pads) 4bp formed over the back surface 4b. Further, the logic chip 4 has a plurality of through electrodes 4tsv which are formed so as to penetrate from one of the surface 4a and the back surface 4b to the other thereof and electrically connect the surface electrodes 4ap and the back surface electrodes 4bp. Except for the above differences, the logic chip 4 can be made similar to the logic chip 4 of the embodiment 1.

A plurality of surface electrodes 4ap1 as electrode pads for the base material in the surface electrodes 4ap of the logic chip 4, and the bonding leads 2f of the wiring substrate 2 are respectively electrically connected with each other through a plurality of projection electrodes (conductive members, columnar electrodes, bumps) 10. On the other hand, the back surface electrodes 4bp of the logic chip 4 are respectively electrically connected with a plurality of surface electrodes 4ap2 as electrode pads for the chip in the surface electrodes 4ap of the logic chip 4 through the through electrodes 4tsv. A plurality of surface electrodes 3ap of the peripheral circuit chip 3 and the back surface electrodes 4bp of the logic chip 4 are respectively electrically connected with each other through a plurality of projection electrodes 9. A flip-chip bonding using the projection electrodes 9 and the projection electrodes 10 can be made similar to the flip-chip bonding using the projection electrodes 9 in the embodiment 1.

An adhesive material (sealing member, resin) NCL2 is arranged between the wiring substrate 2 and the logic chip 4. The adhesive material NCL2 is arranged so as to block space between the upper surface 2a of the wiring substrate 2 and the surface 4a of the logic chip 4. The adhesive material NCL2 is an adhesive material that bonds and fixes the logic chip 4 onto the wiring substrate 2. An adhesive material (sealing member, resin) NCL1 provided between the peripheral circuit chip 3 and the logic chip 4 and the adhesive material NCL2 can be made similar to the adhesive material (sealing member, resin) NCL1 provided between the peripheral circuit chip 3 and the logic chip 4 in the embodiment 1.

The peripheral circuit chip 3 can be made similar to the logic chip 4 of the embodiment 1. Further, the surface electrodes 3ap of the peripheral circuit chip 3 and the back surface electrodes 4bp of the logic chip 4 are connected by flip-chip bonding, for example, as with the embodiment 1.

In the present embodiment 3, the wiring substrate 2 and the logic chip 4 are electrically connected by flip-chip bonding, and the logic chip 4 and the peripheral circuit chip 3 are electrically connected by flip-chip bonding. Therefore, the wiring substrate 2 and the peripheral circuit chip 3 can be connected with low resistance as compared with the wire-based connection, thus making it possible to further improve the electrical characteristics of the semiconductor device.

Since the semiconductor device of the present embodiment 3 is similar to the semiconductor device of the embodiment 1 except for the above differences, their redundant description will be omitted.

The manufacturing method of the semiconductor device of the present embodiment 3 is that in the manufacturing method of the semiconductor device of the above embodiment 1, the order of the peripheral circuit chip mounting step and the logic chip mounting step is replaced. Also, the manufacturing method of the semiconductor device of the present embodiment 3 is different from the manufacturing method of the semiconductor device of the embodiment 1 in that in the logic chip mounting step in the present embodiment 3, the logic chip 4 is mounted over the wiring substrate 2 such that the surface 4a of the logic chip 4 faces to the upper surface 2a of the wiring substrate 2, and is flip-chip bonded therewith. Further, the manufacturing method of the semiconductor device of the present embodiment 3 is different from the manufacturing method of the semiconductor device of the embodiment 1 in that in the peripheral circuit chip mounting step in the present embodiment 3, the peripheral circuit chip 3 is mounted over the logic chip 4 such that the surface 3a of the peripheral circuit chip 3 faces to the back surface 4b of the logic chip 4, and is flip-chip bonded therewith. Except for the above differences, the manufacturing method of the semiconductor device described in the above embodiment 1 can be applied, and dual description will therefore be omitted.

As with the embodiment 1 even in the semiconductor device of the present embodiment 3, it has an advantageous effect similar to the semiconductor device of the embodiment 1 because the semiconductor chip is divided into the peripheral circuit chip 3 and the logic chip 4. However, the semiconductor devices of the embodiments 1 and 2 are more preferable than the semiconductor device of the present embodiment 3 in that the external interface circuit and the external LSI can be connected electrically easily.

As described above, the external interface circuit PR2 (refer to FIG. 5) is formed in the peripheral circuit chip 3. Thus, in order to electrically connect the external interface circuit PR2 with the external LSI EL2 (refer to FIG. 5) there is a need to electrically connect the peripheral circuit chip 3 and the wiring substrate 2 via the through electrodes 4tsv formed in the logic chip 4 or electrically connect the peripheral circuit chip 3 and the wiring substrate 2 through the wires as shown in FIG. 32. In either case, however, it is not possible to connect the external interface circuit PR2 and the external LSI EL2 electrically easily as compared with the embodiments 1 and 2. Thus, in order to electrically and easily connect the external interface circuit PR2 and the external LSI EL2, the peripheral circuit chip 3 in the peripheral circuit chip 3 and the logic chip 4 is preferably arranged on the wiring substrate 2 side of the logic chip 4 as shown in the above embodiments 1 and 2.

### Embodiment 4

The above embodiment 1 has described the embodiment in which the peripheral circuit chip and the logic chip are laminated over the wiring substrate. The present embodiment 4 will explain an embodiment in which a peripheral circuit chip and a logic chip are arranged side by side over a wiring substrate without laminating the peripheral circuit chip and the logic chip. Incidentally, the present embodiment 4 will be described centering on differences from the already-described embodiment 1, and their redundant description will be omitted in principle.

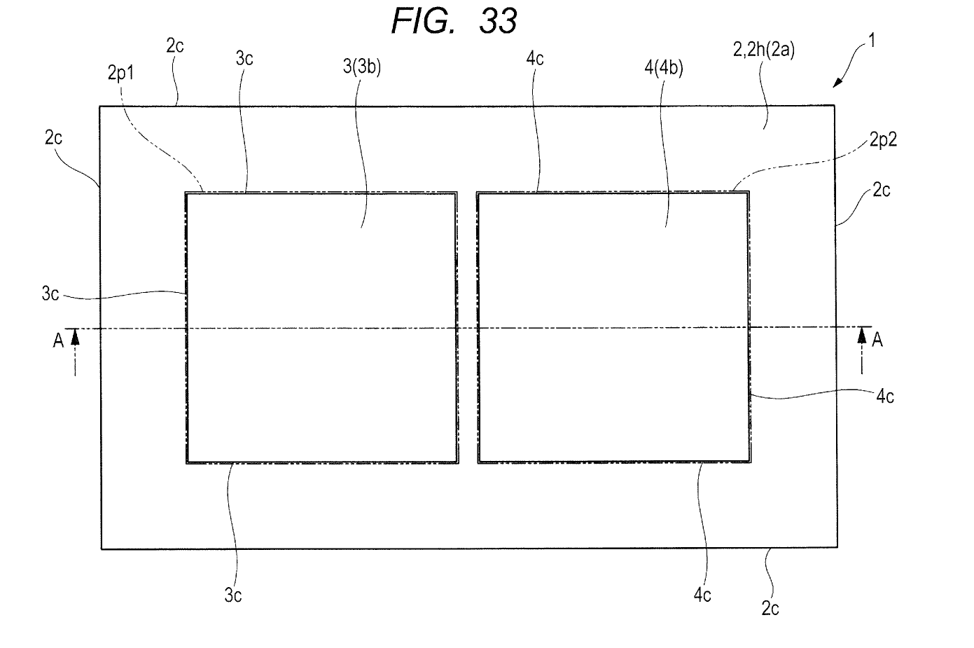

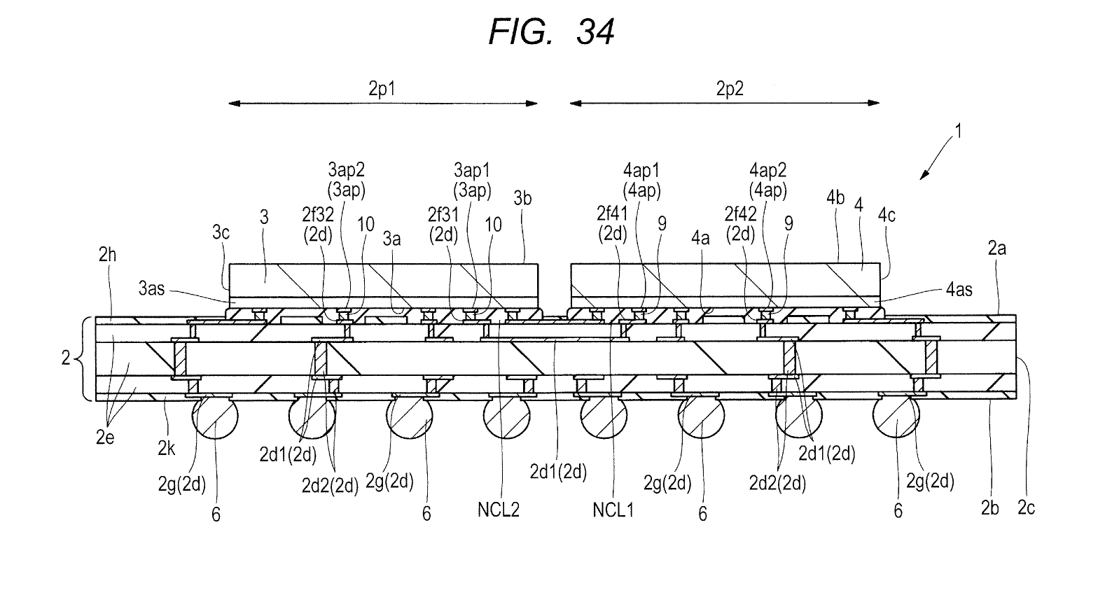

FIG. 33 is a plan diagram of a semiconductor device of the embodiment 4. FIG. 34 is a sectional diagram of the semiconductor device of the embodiment 4. FIG. 34 is a sectional diagram taken along line A-A of FIG. 33. Incidentally, though the number of terminals is shown in FIGS. 33 and 34 with being reduced for the purpose of making it easier to see them, the number of the terminals (bonding leads 2f, lands 2g, solder balls 6 and surface electrodes 3ap and 4ap, etc.) is not limited to the form shown in FIGS. 33 and 34.

The semiconductor device (semiconductor package) 1 of the present embodiment 4 is provided with a wiring substrate (base material) 2, and a peripheral circuit chip (semiconductor chip) 3 and a logic chip (semiconductor chip) 4 mounted over the wiring substrate 2. Incidentally, in the present embodiment 4, a sealing body for sealing the peripheral circuit chip 3 and the logic chip 4 needs not to be provided because all of the wiring substrate 2, the peripheral circuit chip 3 and the logic chip 4 are not connected by wires.

The wiring substrate 2 has a chip mounting region (chip mounting part) 2p2 which is provided adjacent to a chip mounting region (chip mounting part) 2p1 mounted with the peripheral circuit chip 3 and which is mounted with the logic chip 4, in addition to the chip mounting region 2p1. In addition, the wiring substrate 2 can be made similar to the wiring substrate 2 of the embodiment 1 except that bonding leads 2f and wirings 2d are different in position in plan view.

In the present embodiment 4, the peripheral circuit chip 3 and the logic chip 4 are mounted over the wiring substrate 2. Further, the logic chip 4 is electrically directly connected with the wiring substrate 2 without through the peripheral circuit chip 3.

In the present embodiment 4, the peripheral circuit chip 3 is mounted over the chip mounting region 2p1 of the wiring substrate 2 such that a surface 3a of the peripheral circuit chip 3 faces to an upper surface 2a of the wiring substrate 2. The peripheral circuit chip 3 and the wiring substrate 2 are flip-chip bonded. Further, the logic chip 4 is mounted over the chip mounting region 2p2 of the wiring substrate 2 such that a surface 4a of the logic chip 4 faces to the upper surface 2a of the wiring substrate 2. The logic chip 4 and the wiring substrate 2 are flip-chip bonded.

Bonding leads 2f31, 2f32, 2f41 and 2f42 are formed in the upper surface 2a of the wiring substrate 2 as the bonding leads 2f. Further, surface electrodes 3ap1 and 3ap2 are formed over the surface 3a of the peripheral circuit chip 3 as the surface electrodes 3ap. Surface electrodes 4ap1 and 4ap2 are formed over the surface 4a of the logic chip 4 as the surface electrodes 4ap.

The surface electrode 3ap1 formed over the surface 3a of the peripheral circuit chip 3 is connected with the bonding lead (lead for the peripheral circuit chip) 2f31 formed in the upper surface 2a of the wiring substrate 2 through a projection electrode 10, for example. Further, the surface electrode 3ap2 formed over the surface 3a of the peripheral circuit chip 3 is connected with the bonding lead (lead for the peripheral circuit chip) 2f32 formed in the upper surface 2a of the wiring substrate 2 through a projection electrode 10, for example. On the other hand, the surface electrode 4ap1 formed over the surface 4a of the logic chip 4 is electrically connected with the bonding lead (lead for the logic chip) 2f41 formed in the upper surface 2a of the wiring substrate 2 through a projection electrode 9, for example. Further, the surface electrode 4ap2 formed over the surface 4a of the logic chip 4 is electrically connected with the bonding lead (lead for the logic chip) 2f42 formed in the upper surface 2a of the wiring substrate 2 through a projection electrode 9, for example.

The bonding leads 2f31 and 2f41 formed in the upper surface 2a of the wiring substrate 2 are connected by, for example, a wiring 2d or an unillustrated rewiring. Thus, the surface electrode 3ap1 of the peripheral circuit chip 3, and the surface electrode 4ap1 of the logic chip 4 are electrically connected through the wiring substrate 2.

An adhesive material (sealing member, resin) NCL1 is arranged between the wiring substrate 2 and the logic chip 4. An adhesive material (sealing member, resin) NCL2 is arranged between the wiring substrate 2 and the peripheral circuit chip 3. The adhesive material NCL1 is arranged so as to block space between the upper surface 2a of the wiring substrate 2 and the surface 4a of the logic chip 4. The adhesive material NCL2 is arranged so as to block space between the upper surface 2a of the wiring substrate 2 and the surface 3a of the peripheral circuit chip 3. The adhesive material NCL1 is an adhesive material that bonds and fixes the logic chip 4 onto the wiring substrate 2. The adhesive material NCL2 is an adhesive material that bonds and fixes the peripheral circuit chip 3 onto the wiring substrate 2. The adhesive material NCL1 and the adhesive material NCL2 can be made similar to the adhesive material (sealing member, resin) NCL1 provided between the peripheral circuit chip 3 and the logic chip 4 in the embodiment 1.

In the present embodiment 4, since the logic chip 4 is not laminated over the peripheral circuit chip 3 and is arranged away from the peripheral circuit chip 3, the accuracy of sensing (detecting) the temperature of the logic chip 4 by the thermal diode (temperature sensor) TS1 formed in the peripheral circuit chip 3 becomes low as compared with the embodiment 1.

However, as with the embodiment 1 even in the present embodiment 4, the peripheral circuit chip 3 is manufactured based on the process rule RL1 not finer (rougher) than the process rule RL2 at the time of manufacture of the logic chip 4. Thus, the amount of heat generated by a leak current itself can be reduced as compared with the case where the peripheral circuit chip 3 and the logic chip 4 are integrated and the integrated entire semiconductor chip is manufactured based on the fine process rule RL2 that is less than 55 nm, for example. Consequently, the temperature of the entire semiconductor chip can be prevented from continuing to rise, and the semiconductor chip can normally be operated at a higher temperature while ensuring the operating speed of the CPU. Thus, the semiconductor device can easily be highly integrated and easily be speeded up, thereby enabling the semiconductor device to be easily reduced in power consumption.

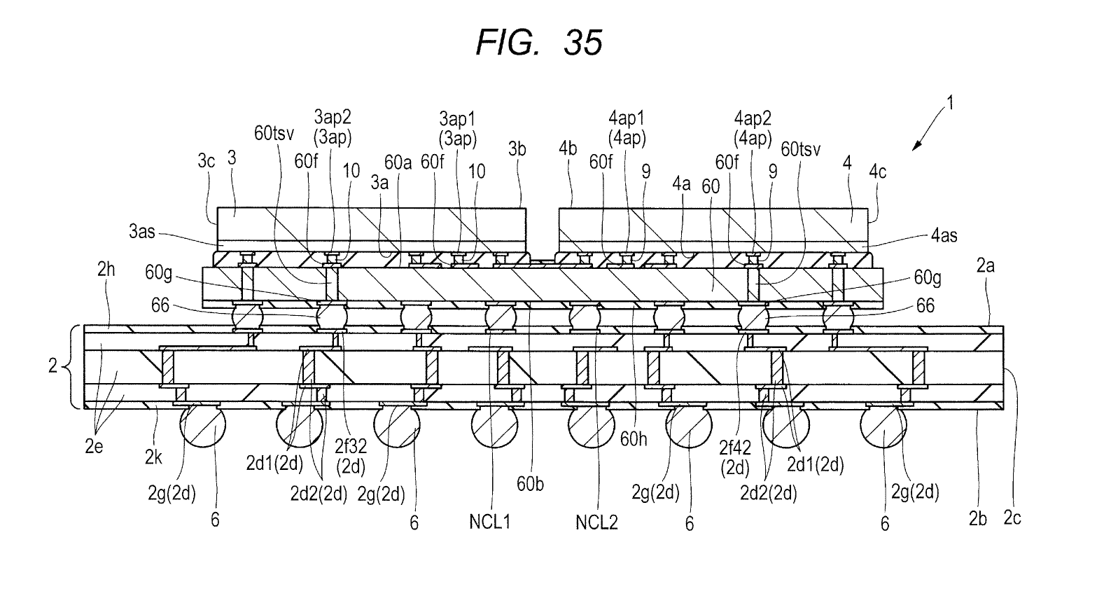

Alternatively, a wiring member (interposer) 60, which is a wiring member different from the wiring substrate 2 and is comprised of a silicon substrate, a glass substrate or an organic resin substrate, is mounted over the wiring substrate 2, and the peripheral circuit chip 3 and the logic chip 4 may be mounted over the wiring substrate 2 through the wiring member 60. Such an example is shown in FIG. 35. FIG. 35 is a sectional diagram showing a configuration of another example of the semiconductor device of the embodiment 4.

In the example shown in FIG. 35, each of surface electrodes 3ap1 of the peripheral circuit chip 3 is electrically connected with a surface electrode 4ap1 of the logic chip 4 through a projection electrode 10, a bonding pad (terminal, electrode pad) 60f formed over an upper surface 60a of the wiring member 60, and a projection electrode 9. On the other hand, each of surface electrodes 3ap2 of the peripheral circuit chip 3 is electrically connected with a bonding lead 2f32 of the wiring substrate 2 through a projection electrode 10, a bonding pad 60f formed over the upper surface 60a of the wiring member 60, a through electrode 60tsv penetrating through the wiring member 60, and a land 60g and a solder ball 66 formed over a lower surface 60b of the wiring member 60. Further, each of surface electrodes 4ap2 of the logic chip 4 is electrically connected with a bonding lead 2f42 of the wiring substrate 2 through a projection electrode 9, a bonding pad 60f, a through electrode 60tsv, a land 60g and a solder ball 66. Incidentally, an insulating film (solder resist film) 60h is formed over the lower surface 60b of the wiring member 60.

In the wiring member 60 comprised of the organic resin substrate, wirings (wiring patterns) formed over the surface of the wiring member 60 are formed by a subtractive method that is a method of removing unnecessary portions of a copper foil formed in the surface of the wiring member 60 and leaving circuits. Alternatively, the wirings (wiring patterns) formed over the surface of the wiring member 60 are formed by a semi-additive method for forming circuits by electrolytic copper plating in a state in which unnecessary portions of a seed layer formed over the surface of the wiring member 60 are coated.

On the other hand, in the wiring member 60 comprised of the silicon substrate or the glass substrate, wirings (wiring patterns) can be formed by, for example, a damascene method. It is therefore possible to reduce the line width of each formed wiring and a space width therebetween as compared with the wiring substrate or wiring member comprised of the organic resin substrate. Thus, considering that there is a need to form fine wirings in large numbers to connect between the peripheral circuit chip 3 and the logic chip 4, the wiring member comprised of the silicon substrate or the glass substrate is preferably arranged between the wiring substrate 2 comprised of the organic resin substrate, the peripheral circuit chip 3 and the logic chip 4.

(Other Modifications)

While the invention made above by the present inventors has been described specifically on the basis of the embodiments, the present invention is not limited to the embodiments referred to above. It is needless to say that various changes can be made thereto within the scope not departing from the gist thereof.

<Modification 1>

For example, in the above embodiment 1, description has been made about the embodiment as the BGA type semiconductor device in which the wiring substrate is used as the base material, and the solder balls are bonded to the back surface of the wiring substrate in an array form. The embodiment of the present invention is however not limited to the BGA type semiconductor device and the semiconductor device using the wiring substrate as the base material. Accordingly, the semiconductor device as the modification 1 can also be configured as an LGA type semiconductor device in which instead of the solder balls, electrode pads are bonded to the back surface of a wiring substrate in an array form.

Further, the semiconductor device as the modification 1 can also be configured as a semiconductor device using a lead frame as a base material in place of the wiring substrate, such as an SOP (Small outline package), an QFP (Quad flat package), an QFN (Quad flat non-leaded package), an SON (Small outline non-leaded package) or the like. At this time, instead of the bonding leads 2f (refer to FIG. 4) formed in the wiring substrate 2, leads formed in the lead frame are respectively electrically connected with the surface electrodes 3ap1 (refer to FIG. 4) of the peripheral circuit chip 3 through the wires 7 (refer to FIG. 4).

<Modification 2>

For example, the above embodiment 1 has described the embodiment in which the flash memory is formed in the peripheral circuit chip. The embodiment of the present embodiment is not limited to the case where the flash memory is formed in the peripheral circuit chip. Thus, the semiconductor device as the modification 2 can be configured as a semiconductor device equipped with a memory chip 70 formed with a flash memory in addition to the peripheral circuit chip 3 and the logic chip 4.

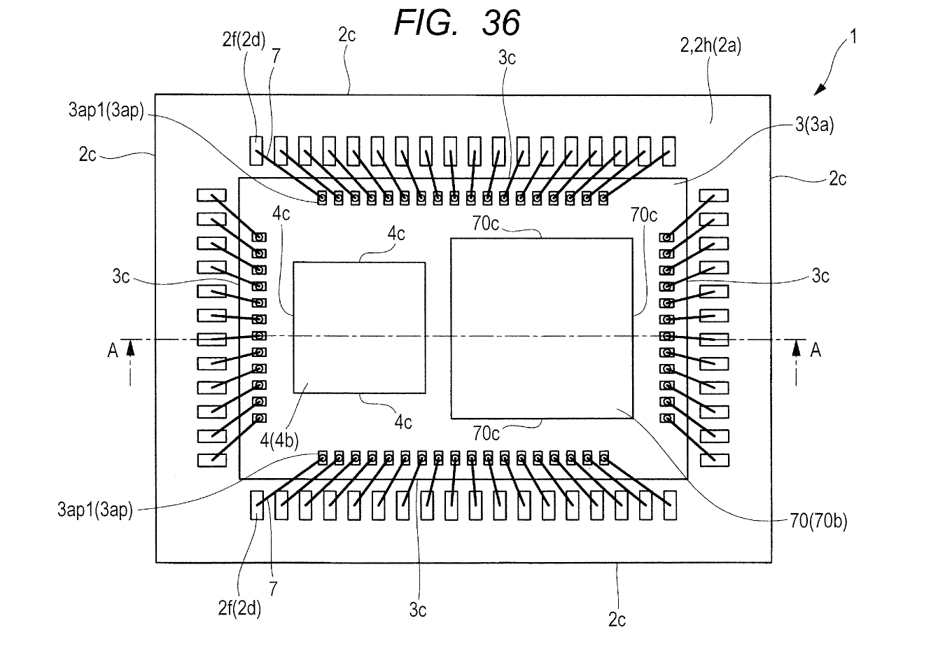

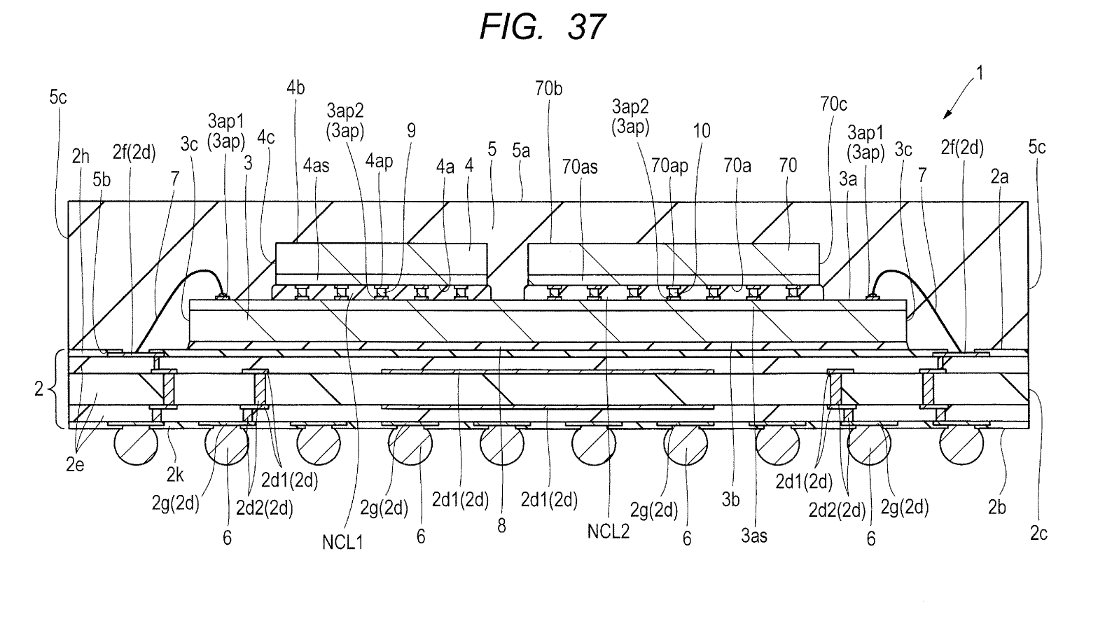

FIG. 36 is a perspective plan diagram of the semiconductor device of the modification 2. FIG. 36 illustrates an internal structure of the semiconductor device over a wiring substrate in a removed state of a sealing body. FIG. 37 is a sectional diagram of the semiconductor device of the modification 2. FIG. 37 is a sectional diagram taken along line A-A of FIG. 36. Incidentally, the number of terminals is not limited to the form shown in FIGS. 36 and 37.

As shown in FIGS. 36 and 37, the semiconductor device 1 is provided with the memory chip 70 in addition to the peripheral circuit chip 3 and the logic chip 4. The memory chip 70 has a surface (main surface, upper surface) 70a, a back surface (main surface, lower surface) 70b opposite to the surface 70a, and side surfaces 70c positioned between the surface 70a and the back surface 70b. As shown in FIG. 36, the memory chip 70 has an outer shape square in plan view. Further, the memory chip 70 has surface electrodes (terminals, electrode pads, bonding pads) 70ap formed over the surface 70a.

The memory chip 70 is mounted over the peripheral circuit chip 3 such that the surface 70a of the memory chip 70 faces to a surface 3a of the peripheral circuit chip 3. The memory chip 70 is mounted over the surface 3a of the peripheral circuit chip 3 and adjacent to the logic chip 4. Surface electrodes 70ap of the memory chip 70, and surface electrodes 3ap2 as surface electrodes 3ap of the peripheral circuit chip 3 are respectively electrically connected through projection electrodes 10. Incidentally, the memory chip 70 has a wiring layer 70as on the surface 70a side.

An adhesive material (sealing member, resin) NCL2 is arranged between the peripheral circuit chip 3 and the memory chip 70. The adhesive material NCL2 can be made similar to an adhesive material (sealing member, resin) NCL1 provided between the peripheral circuit chip 3 and the logic chip 4.

As shown in FIGS. 36 and 37, in the modification 2, the peripheral circuit chip 3 is mounted over the wiring substrate 2, and the logic chip 4 and the memory chip 70 are mounted over the peripheral circuit chip 3. In the example shown in FIG. 36, the logic chip 4 and the memory chip 70 are arranged in positions away from each other in plan view. The logic chip 4 can be made similar to the logic chip 4 in the above embodiment 1. Further, the memory chip 70 includes the flash memory. Thus, the peripheral circuit chip 3 may not be formed with the flash memory as the memory MM2 (refer to FIG. 5), but may be formed with a flash memory having a capacity smaller than the capacity of the flash memory in the embodiment 1. Further, the memory chip 70 may be formed with a memory controller that controls the flash memory formed in the memory chip 70. Alternatively, the memory controller that controls the flash memory formed in the memory chip 70 may be formed in the peripheral circuit chip 3.

In the modification 2, a mask with layout patterns being changed needs not to be newly provided as a mask for manufacturing the peripheral circuit chip 3 each time a design change is performed on the capacity of the flash memory according to the purpose or applications for which the semiconductor device is used, i.e., according to the customers or needs. Thus, since the mask for manufacturing the peripheral circuit chip 3 can be used in common between manufacturing processes for manufacturing a plurality of types of semiconductor devices, the manufacturing cost of the semiconductor device can be reduced.

<Modification 3>

For example, the above embodiment 1 has described the embodiment in which the CPU is formed in the logic chip. The embodiment of the present invention is however not limited to the case where the CPU is formed only in the logic chip. Accordingly, the semiconductor device as the modification 3 can also be configured as a semiconductor device provided with another CPU formed in the peripheral circuit chip, based on the process rule larger than the process rule at the time of manufacture of the logic chip in addition to the CPU formed in the logic chip.

Incidentally, description will be made below about an example of the semiconductor device with another CPU provided in the semiconductor device of the modification 2. The semiconductor device of the present modification can however also be configured as, for example, a semiconductor device with another CPU provided in the semiconductor device of the embodiment 1, which is not provided with the memory chip 70.

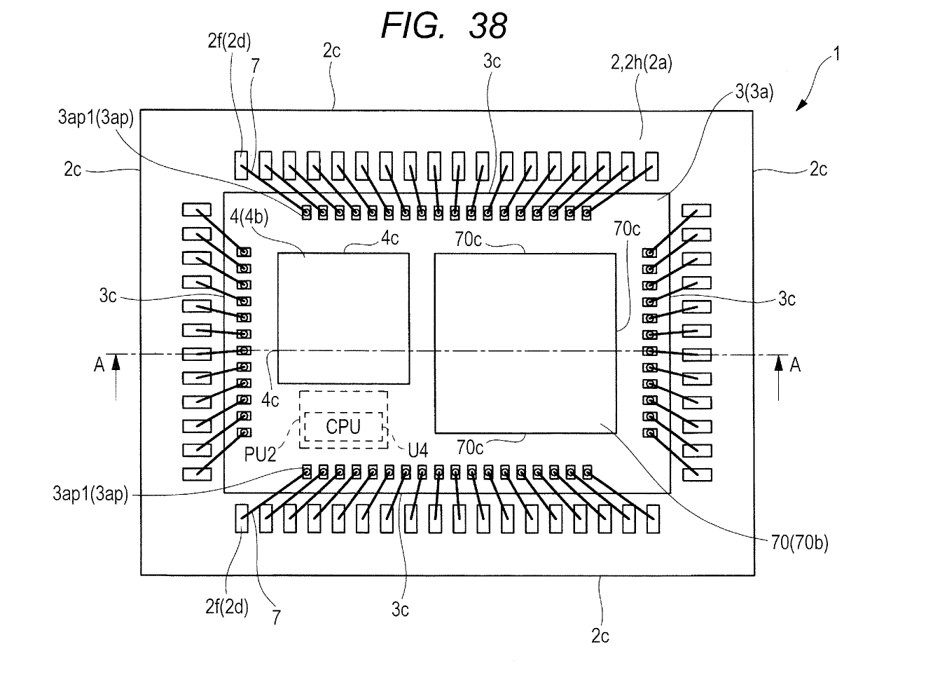

FIG. 38 is a perspective plan diagram of the semiconductor device of the modification 3. FIG. 38 shows an internal structure of the semiconductor device over a wiring substrate in a removed state of a sealing body. Incidentally, FIG. 38 shows a circuit configuration example of the semiconductor device in overlap with the perspective plan diagram. A structure of a cross-section of the semiconductor device of the modification 3, which is taken along line A-A of FIG. 38, is similar to the structure of the cross-section shown in FIG. 37.

As shown in FIG. 5, as with the peripheral circuit chip 3 of the embodiment 1, the peripheral circuit chip 3 has a CAN module (peripheral circuit) PR1, an external interface circuit (peripheral circuit, interface) PR2, a power supply controller PC1, a thermal diode (temperature sensor) TS1 and a memory MM1. Further, the logic chip 4 has a CPU circuit PU1, a local RAM controller PR3 and a memory MM3 as with the logic chip 4 of the embodiment 1.

On the other hand, in the present modification 3, the peripheral circuit chip 3 has a CPU circuit PU2 different from the CPU circuit PU1 provided in the logic chip 4. The CPU circuit PU2 has a central processing unit (CPU) U4. The central processing unit (CPU) U4 is a CPU manufactured to the peripheral circuit chip 3, based on the process rule RL1 not finer (rougher) than the process rule RL2 at the time of manufacture of the logic chip 4. Incidentally, the CPU circuit PU2 and the central processing unit (CPU) U4 are typically shown in FIG. 38 using broken lines because they are formed inside the peripheral circuit chip 3.

As with the embodiment 1 even in the present modification 3, the power supply control controller PC1 (refer to FIG. 5) included in the power supply control unit CU1 repeats the control of cutting off the supply of power to the CPU circuit PU1 of the logic chip 4 when the temperature of the logic chip 4 is raised to the temperature T1, and resuming the supply of power to the CPU circuit PU1 when the temperature of the logic chip 4 is lowered to the temperature T2.

On the other hand, in the present modification 3, the power supply controller PC1 included in the power supply control unit CU1 supplies power to the CPU circuit PU2 formed in the peripheral circuit chip 3 to operate the CPU circuit PU2 while cutting off the supply of power to the CPU circuit PU1 of the logic chip 4. The CPU circuit PU2 formed in the peripheral circuit chip 3 has a function of such an extent as to hold the required minimum function that the semiconductor device must maintain, as compared with the CPU circuit PU1 formed in the logic chip 4. Therefore, the CPU circuit PU2 is smaller in power consumption and also smaller in the amount of generated heat than the CPU circuit PU1. Thus, in the present modification 3, the CPU circuit PU2 small in power consumption and small in the amount of generated heat as compared with the CPU circuit PU1 can be operated even when the supply of power to the CPU circuit PU1 of the logic chip 4 is being cut off. It is therefore possible to prevent the temperature of the logic chip 4 from continuing to rise while maintaining the required minimum function.

<Modification 4>

Further, either one or more of the embodiment 1 to the modification 3 can be applied in combination within the scope not departing from the gist of the technical idea described in the above embodiments.

The present invention includes at least the following embodiments.

### APPENDIX 1

A manufacturing method of a semiconductor device, including the following steps:

(a) providing a base material, a first semiconductor chip having a first main surface, a plurality of first electrode pads formed over the first main surface, and a first back surface opposite to the first main surface, and a second semiconductor chip having a second main surface, a plurality of second electrode pads formed over the second main surface, and a second back surface opposite to the second main surface;

in which the first semiconductor chip includes a first peripheral circuit, a power supply controller, a temperature sensor and a first RAM,

the first peripheral circuit and the first RAM are respectively manufactured based on a first process rule,

the second semiconductor chip includes a CPU, a second peripheral circuit and a second RAM, and

the CPU, the second peripheral circuit and the second RAM are respectively manufactured based on a second process rule finer than the first process rule,

(b) mounting the first semiconductor chip over a chip mounting region of the base material;

(c) mounting the second semiconductor chip over a chip mounting region of the first semiconductor chip such that the second main surface of the second semiconductor chip faces to the first semiconductor chip; and

(d) respectively electrically connecting a plurality of electrode pads for a base material of the first electrode pads of the first semiconductor chip with a plurality of leads of the base material by a plurality of first conductive members, and respectively electrically connecting the second electrode pads of the second semiconductor chip with a plurality of electrode pads for a semiconductor chip of the first electrode pads of the first semiconductor chip by a plurality of second conductive members.

### APPENDIX 2

A semiconductor device including:

a base material;

a first semiconductor chip which has a first main surface, a plurality of first electrode pads formed over the first main surface and a first back surface opposite to the first main surface, and is mounted over a chip mounting region of the base material such that the first main surface faces to the base material;

a second semiconductor chip which has a second main surface, a plurality of second electrode pads formed over the second main surface and a second back surface opposite to the second main surface, and is mounted over the first semiconductor chip such that the second main surface faces to the first back surface of the first semiconductor chip;

a plurality of first conductive members electrically connecting a plurality of electrode pads for a base material of the first electrode pads of the first semiconductor chip with a plurality of leads of the base material, respectively;

a plurality of second conductive members electrically connecting the second electrode pads of the second semiconductor chip with a plurality of electrode pads for a semiconductor chip of the first electrode pads of the first semiconductor chip, respectively;

a first sealing member which seals between the first semiconductor chip and the second semiconductor chip; and

a second sealing member which seals between the base material and the first semiconductor chip,

in which the second semiconductor chip includes a first peripheral circuit, a power supply controller, a temperature sensor and a first RAM,

in which the first semiconductor chip includes a CPU, a second peripheral circuit and a second RAM,

in which the first peripheral circuit and the first RAM are respectively manufactured based on a first process rule,

in which the CPU, the second peripheral circuit and the second RAM are respectively manufactured based on a second process rule finer than the first process rule,

in which the first semiconductor chip has a plurality of third electrode pads formed in the first back surface, and a plurality of through electrodes which penetrate from one of the first main surface and the first back surface to the other thereof,

in which the third electrode pads are respectively electrically connected with a plurality of electrode pads for a semiconductor chip of the first electrode pads through the through electrodes, and

in which the second conductive members respectively electrically connect the third electrode pads and the second electrode pads of the second semiconductor chip.

### APPENDIX 3

A semiconductor device including:

a base material having a first surface provided with a first chip mounting region and a second chip mounting region provided adjacent to the first chip mounting region, and a second surface opposite to the first surface;

a first semiconductor chip which has a first main surface, a plurality of first electrode pads formed over the first main surface and a first back surface opposite to the first main surface, and is mounted over the first chip mounting region of the base material;

a second semiconductor chip which has a second main surface, a plurality of second electrode pads formed over the second main surface and a second back surface opposite to the second main surface, and is mounted over the second chip mounting region of the base material;

a plurality of first conductive members electrically connecting the first electrode pads of the first semiconductor chip with a plurality of first chip leads of a plurality of leads of the base material, respectively;

a plurality of second conductive members electrically connecting the second electrode pads of the second semiconductor chip with a plurality of second chip leads of the leads of the base material, respectively;

a first sealing member which seals between the base material and the first semiconductor chip; and

a second sealing member which seals between the base material and the second semiconductor chip,

in which the first semiconductor chip includes a first peripheral circuit, a power supply controller, a temperature sensor and a first RAM,

in which the second semiconductor chip includes a CPU, a second peripheral circuit and a second RAM,

in which the first peripheral circuit and the first RAM are respectively manufactured based on a first process rule, and

in which the CPU, the second peripheral circuit and the second RAM are respectively manufactured based on a second process rule finer than the first process rule.

What is claimed is:

1. A semiconductor device, comprising:
a base material;
a first semiconductor chip having a first main surface, a plurality of first electrode pads formed over the first main surface and a first back surface opposite to the first main surface, the first semiconductor chip being mounted over a chip mounting region of the base material;
a second semiconductor chip having a second main surface, a plurality of second electrode pads formed over the second main surface and a second back surface opposite to the second main surface, the second semiconductor chip being mounted over a chip mounting region of the first semiconductor chip such that the second main surface faces to the first semiconductor chip;
a plurality of first conductive members electrically connecting a plurality of electrode pads for a base material of the first electrode pads of the first semiconductor chip with a plurality of leads of the base material, respectively; and
a plurality of second conductive members electrically connecting the second electrode pads of the second semiconductor chip with a plurality of electrode pads for a semiconductor chip of the first electrode pads of the first semiconductor chip, respectively,
wherein the first semiconductor chip includes a first peripheral circuit, a power supply controller, a temperature sensor and a first RAM,
wherein the second semiconductor chip includes a CPU, a second peripheral circuit and a second RAM,
wherein the first peripheral circuit and the first RAM are respectively manufactured based on a first process rule, and
wherein the CPU, the second peripheral circuit and the second RAM are respectively manufactured based on a second process rule finer than the first process rule.

2. The semiconductor device according to claim 1, wherein a drive power supply is electrically connected with the power supply controller and supplied to the CPU of the second semiconductor chip through a power supply wiring formed in the first semiconductor chip.

3. The semiconductor device according to claim 2, wherein the power supply controller and the temperature sensor are respectively formed in a region of the first semiconductor chip, which overlaps with the second semiconductor chip.

4. The semiconductor device according to claim 1,
wherein the first semiconductor chip is further formed with a first flash memory, and
wherein an occupation area of the first flash memory is larger than an occupation area of each of the first peripheral circuit, the temperature sensor, the first RAM, the second RAM, the CPU and the second peripheral circuit.

5. The semiconductor device according to claim 1,
wherein a third semiconductor chip is mounted over the first main surface of the first semiconductor chip and adjacent to the second semiconductor chip, and
wherein the third semiconductor chip includes a second flash memory.

6. The semiconductor device according to claim 1,
wherein the second RAM comprises the same structure as the first RAM,
wherein the first RAM is not operated at the same speed as the CPU, and
wherein the second RAM is operated at the same speed as the CPU.

7. The semiconductor device according to claim 1,
wherein the first semiconductor chip is further formed with an interface for an external LSI,
wherein the interface is manufactured based on the first process rule, and
wherein a voltage value necessary for the interface is higher than a voltage value necessary for each of the first peripheral circuit, the temperature sensor, the first RAM, the second RAM, the CPU and the second peripheral circuit.

8. The semiconductor device according to claim 1,
wherein a gate insulating film of a first transistor which configures each of the first peripheral circuit, the power supply controller, the temperature sensor and the first RAM comprises a silicon oxide film or a silicon oxynitride film,
wherein a gate electrode of the first transistor comprises polysilicon,
wherein a gate insulating film of a second transistor which configures each of the CPU, the second peripheral circuit and the second RAM comprises an insulating film containing hafnium, and
wherein a gate electrode of the second transistor comprises a metal material.

9. The semiconductor device according to claim 1, further including a first sealing member which seals between the first semiconductor chip and the second semiconductor chip, and a second sealing member which seals the first semiconductor chip, the second semiconductor chip, the first conductive members and the first sealing member,
wherein the first semiconductor chip is mounted over the chip mounting region of the base material such that the first back surface of the first semiconductor chip faces to the base material,
wherein the second semiconductor chip is mounted over the chip mounting region of the first semiconductor chip such that the second main surface of the second semiconductor chip faces to the first main surface of the first semiconductor chip, and
wherein the first semiconductor chip is mounted over the chip mounting region of the base material through a first adhesive material.

10. The semiconductor device according to claim 1, including a third sealing member which seals between the base material and the first semiconductor chip,
wherein the first semiconductor chip is mounted over the chip mounting region of the base material such that the first main surface of the first semiconductor chip faces to the base material,
wherein the second semiconductor chip is mounted over the chip mounting region of the first semiconductor chip such that the second main surface of the second semiconductor chip faces to the first back surface of the first semiconductor chip,
wherein the first semiconductor chip has a plurality of third electrode pads formed in the first back surface, and a plurality of through electrodes penetrating from one of the first main surface and the first back surface to the other thereof,
wherein the third electrode pads are respectively electrically connected with a plurality of electrode pads for a semiconductor chip of the first electrode pads via the through electrodes, and
wherein the second conductive members respectively electrically connect the third electrode pads with the second electrode pads of the second semiconductor chip.

11. A semiconductor device wherein the semiconductor device according to claim 1 is mounted over a wiring substrate, and
wherein the semiconductor device mounted over the wiring substrate controls other semiconductor device mounted over the wiring substrate.

12. The semiconductor device according to claim 11, wherein other semiconductor device is a memory device.

13. A semiconductor device, comprising:
a base material;
a first semiconductor chip having a first main surface, a plurality of first electrode pads formed over the first main surface and a first back surface opposite to the first main surface, the first semiconductor chip being mounted over a chip mounting region of the base material;
a second semiconductor chip having a second main surface, a plurality of second electrode pads formed over the second main surface and a second back surface opposite to the second main surface, the second semiconductor chip being mounted over a chip mounting region of the first semiconductor chip such that the second main surface faces to the first semiconductor chip;
a plurality of first conductive members electrically connecting a plurality of electrode pads for a base material of the first electrode pads of the first semiconductor chip with a plurality of leads of the base material, respectively; and
a plurality of second conductive members electrically connecting the second electrode pads of the second semiconductor chip with a plurality of electrode pads for a semiconductor chip of the first electrode pads of the first semiconductor chip, respectively,
wherein the first semiconductor chip includes a first peripheral circuit, a power supply controller, a temperature sensor and a first RAM,
wherein the second semiconductor chip includes a CPU, a second peripheral circuit and a second RAM, and
wherein a first minimum wiring space in a wiring layer of the first semiconductor chip is larger than a second minimum wiring space in a wiring layer of the second semiconductor chip.

14. The semiconductor device according to claim 13, wherein a drive power supply is electrically connected with the power supply controller and supplied to the CPU of the second semiconductor chip through a power supply wiring formed in the first semiconductor chip.

15. The semiconductor device according to claim 14, wherein the power supply controller and the temperature sensor are respectively formed in a region of the first semiconductor chip, which overlaps with the second semiconductor chip.

16. The semiconductor device according to claim 13,
wherein the first semiconductor chip is further formed with a first flash memory, and
wherein an occupation area of the first flash memory is larger than an occupation area of each of the first peripheral circuit, the temperature sensor, the first RAM, the second RAM, the CPU and the second peripheral circuit.

17. The semiconductor device according to claim 13,
wherein a third semiconductor chip is mounted over the first main surface of the first semiconductor chip and adjacent to the second semiconductor chip, and
wherein the third semiconductor chip includes a second flash memory.

18. The semiconductor device according to claim 13,
wherein the second RAM comprises the same structure as the first RAM,
wherein the first RAM is not operated at the same speed as the CPU, and
wherein the second RAM is operated at the same speed as the CPU.

19. The semiconductor device according to claim 13,
wherein the first semiconductor chip is further formed with an interface for an external LSI, and
wherein a voltage value necessary for the interface is higher than a voltage value necessary for each of the first peripheral circuit, the temperature sensor, the first RAM, the second RAM, the CPU and the second peripheral circuit.

20. The semiconductor device according to claim 13,
wherein a gate insulating film of a first transistor which configures each of the first peripheral circuit, the power supply controller, the temperature sensor and the first RAM comprises a silicon oxide film or a silicon oxynitride film,
wherein a gate electrode of the first transistor comprises polysilicon,
wherein a gate insulating film of a second transistor which configures each of the CPU, the second peripheral circuit and the second RAM comprises an insulating film containing hafnium, and
wherein a gate electrode of the second transistor comprises a metal material.
